(19) United States
(12) Patent Application Publication
(10) Pub. No.: US 2018/0343749 A1
(43) Pub. Date: Nov. 29, 2018

(54) Multi-tier conductive circuits free of supporting substrate with intermediary devices on a plurality of tiers, detachable production platform for additive manufacturing, solder-dispensers and device-dispensers

(71) Applicant: Bo Gosta Nystedt, Monesties (FR)

(72) Inventor: Bo Gosta Nystedt, Monesties (FR)

(21) Appl. No.: 15/607,562

(22) Filed: May 29, 2017

(51) Int. Cl. H05K 3/34; H05K 13/00; H05K 3/12; H05K 13/04; B23K 35/26; H01L 25/065; H01L 23/00; H01L 23/495

(52) U.S. Cl. CPC H05K 3/3457; H05K 13/0061; H05K 3/12; H05K 13/0469; B23K 35/26; H01L 25/0657; H01L 2225/1029; H01L 24/28; H01L 23/49537; H05K 2203/0126; H01L 2924/14; H01L 2225/1047; H01L 24/27

(57) ABSTRACT

Four parts of a unity is described here, centered around the multi-tier conductive circuits. The detachable production platform is a prerequisite for manufacturing of these circuits as described. The solder-dispenser is necessary if the circuits are made of anything but magnetic metal powder, or if the means for containing solder material are made solid, and the device-dispenser replaces conventional pick-n-place machines to provide devices to a circuit much quicker and much cheaper.

The multi-tier conductive circuit that is the central idea and the final product of the presented innovations is highly flexible and highly cost efficient.

The trend of miniaturizing all kinds of electronic equipments has been the outset for these innovations and it is our firm belief that all the industry could benefit highly from such a circuit.

### CROSS-REFERENCE TO RELATED APPLICATIONS

EFS ID 26305014, Application No. 62/343,958, Confirmation Number 8325

### FEDERALLY SPONSORED RESEARCH

Not applicable.

### REFERENCE TO SEQUENCE LISTING, A TABLE, OR A COMPUTER PROGRAM LISTING COMPACT DISC APPENDIX

Not applicable.

### BACKGROUND OF THE INVENTION

With additive technology coming of age, and the miniaturizing trend simultaneously continuing, the need for flexible solutions for conductive circuits carrying devices is manifest.

At the same time conductive circuits are becoming ubiquitous—there are conductive circuits in everything from toothbrushes to hearing aids and medicines, and from smart-phones to tablets, cars, refrigerators, airplanes and spacecrafts. Devices equipped with conductive circuits are becoming widespread to a degree that is only getting higher by the minute.

Much is happening in the domain of additive manufacturing, including both miniaturization and maximization. In both these domains the traditional supporting substrate for conductive circuits are inconvenient—they take up much space and they are often too rigid.

However, there is still much focus on how to make additive manufacturing suitable for mass production.

### ADVANTAGES

Present innovations only take up the space necessary for the circuits with devices as such and they combine to create a highly flexible conductive circuit solution. They furthermore present ways of making additive manufacturing fit for mass production.

### BRIEF SUMMARY OF THE INVENTIONS

Central for the innovations presented here is the method for establishing multi-tier conductive circuits free of supporting substrate with intermediary devices attached on a plurality of tiers.

The manufacturing process for such circuits rely on an additive production unity with a detachable production platform, with the capacity of being re-inserted and firmly fixed in the exact position from where it was detached. Such a platform is part of the innovations presented here.

Production of the conductive circuits encompass application of solder material, if the technique preferred for the actual production so demands, of positioning of devices and of attaching these devices.

For these processes an innovative solder-dispenser is presented, as is also an innovative device-dispenser, both being designed specifically for each new design of a conductive circuit to fit the exact positions demanded by the circuit under construction.

Finally the procedures for establishing mass production of the multi-tier conductive circuits are summarized.

Following parts of present innovations are presented:
Production Platform for Additive Manufacturing Machines, Detachable and Re-Insertable in Exact Position
A Method for Establishing Multi-Tier Conductive Circuits Free of Supporting Substrate with Intermediary Devices Attached on a Plurality of Tiers
Solder-Dispensers
Device-Dispenser
An Outline to Indicate one Way of Organizing Mass Production

### DRAWINGS

FIGS. 1-3A

### BACKGROUND OF THIS INVENTION

Additive manufacturing has an immediate appeal by employing only the necessary resources and leaving no waste. Other advantages are the quickness of production and afford-ability of low volumes.

On the other hand mass production based on additive manufacturing is getting developed these years.

There are basically 3 methods of additive manufacturing. They are all being developed simultaneously and continually:
Solidifying objects within volume of fluid medium.
Applying softened material to a building platform by letting it pass through nozzles. May 2016 a method of combining nozzle extrusion with laser annealing was presented.
Selectively sintering powder of material in a chamber to form objects on building platform.

### Solidifying Objects within Volume of Fluid Medium

This method appears to be the first additive building method. It arose during the 70's.

With priority date in 1971 Wyn Kelly Swainson holds a patent, U.S. Pat. No. 4,041,476A, for producing three-dimensional figures by causing two radiation beams to intersect in a liquid medium encompassing two active components, thus forming the object within the three-dimensional volume of the fluid medium.

Additive Manufacturing (AM) equipment and materials were developed in the 1980s. In 1981, Hideo Kodama of Nagoya Municipal Industrial Research Institute invented two AM fabricating methods of a three-dimensional plastic model with photo-hardening polymer, where the UV exposure area is controlled by a mask pattern or the scanning fiber transmitter. In 1984, Chuck Hull of 3D Systems Corporation developed a prototype system based on this process known as stereo-lithography, in which layers are added by curing photo-polymers with ultraviolet light lasers.

The latest development in this category is the Morpheus Resin 3D printer developed by Korean engineer Seong Jin Park and his team at Owl Works, to appear on the market September 2015. As of May 2016 Owl Works announced that the project had been funded, but there were no news about the printer being available.

### Applying Softened Material to a Building Platform by Letting it Pass Through Nozzles

Fused deposition modeling (FDM) works on an “additive” principle by laying down material in layers; a plastic filament or metal wire is unwound from a coil and supplies material to produce a part. The technology was developed by S. Scott Crump in the late 1980s and was first commercialized in 1990.

Fused filament fabrication (FFF) is another term for this process.

The method that combines nozzle-extrusion with laser annealing employs high-intensity laser to heat ink with silver nano-particles to form metallic shapes—as the nano-particles are extruded from the nozzle they harden into fully formed 3D objects.

### Selectively Sintering Powder of Material in a Chamber to Form Object on Building Platform

Selective Laser Sintering (SLS) was developed and patented by Dr. Carl Deckard and Dr. Joseph Beaman at the University of Texas at Austin in the mid-1980s. A similar process was patented 115 without being commercialized by R. F. Housholder in 1979.

### State of the Art

Of the 3 main methods above, the 2 involve production platforms, FDM and SLS. Present innovation concerns additive manufacturing systems that involve such platforms. Additive manufacturing is still developing, and still new areas of production are identified in which additive manufacturing can bring advantages. This concerns products of all sizes, and in all materials, that can be treated to acquire a consistency and quality to be handled in the different types of machines for additive manufacturing.

Products are taken out of the additive manufacturing machine when the addition of layers are done.

To get a product out of the additive manufacturing machine it has to be detached from the production platform.

To reinsert a product to continue building is no option.

### Advantages

Present innovation changes this situation, creating the option to reinsert a production platform with a product to continue building.

The detachable production platform of this innovation enables procedures of arresting production at a certain stage to perform further manipulations before reinserting the product into the additive manufacturing machine to continue the layer-adding process.

With this innovation the product stays on the production platform, and this platform is detached from its base in the additive manufacturing machine.

After the intended manipulations of the product have been performed, the production platform can be reinserted and firmly attached in the exact position from which it was detached.

These two qualities, the firm attachment and the exactness, are obtained by the specific structure of this innovation.

In an alternative embodiment the production platform of this innovation is fitted with an electro-magnet. Adding electro-magnetic forces is of relevance in the processes of additive manufacturing with tiny particles of magnetic metal powder. By choosing metal with magnetic capacities working with powder of nano-particles is facilitated.

The use of the electro-magnet will support the weak fundamental gravity force of the powder particles, which will enhance both the surface quality and the density of the structures being built. And furthermore it will counteract van der Waals forces, that by making the particles agglomerate and by giving them reduced fluidity have until now made it difficult to obtain the technical parameters necessary for producing details as fine as needed in further miniaturizing of conductive circuits.

### Brief Summary of the Invention

The detachable production platform is a design that can be fitted into any additive manufacturing machine with a production platform. The detachable production platform makes it possible to perform additive manufacturing in stages. The product can stay on the platform, while various maneuvers take place—e.g. soldering. Building can continue after re-attaching the production platform in the exact position in the additive manufacturing machine, and only after building is finished will the product leave the production platform.

The detachable production platform further opens the possibility of electro-magnetically manipulating nano-size particles in additive manufacturing with metal powders, thus enabling further miniaturization.

### Detailed Description of the Invention

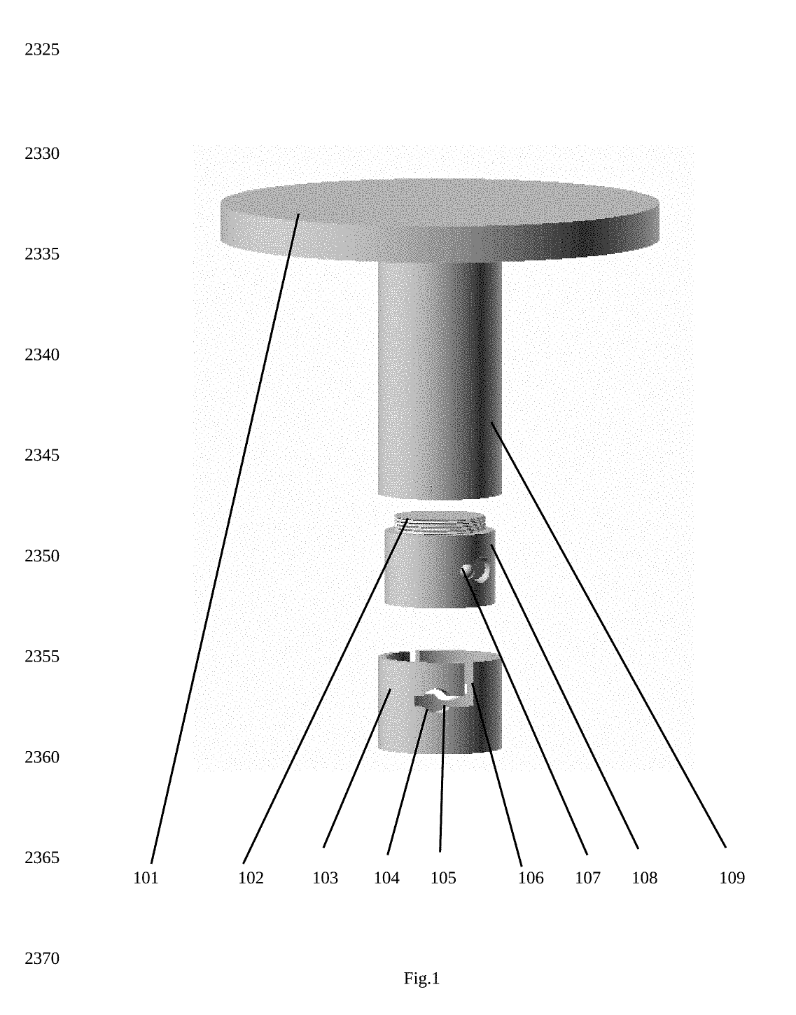

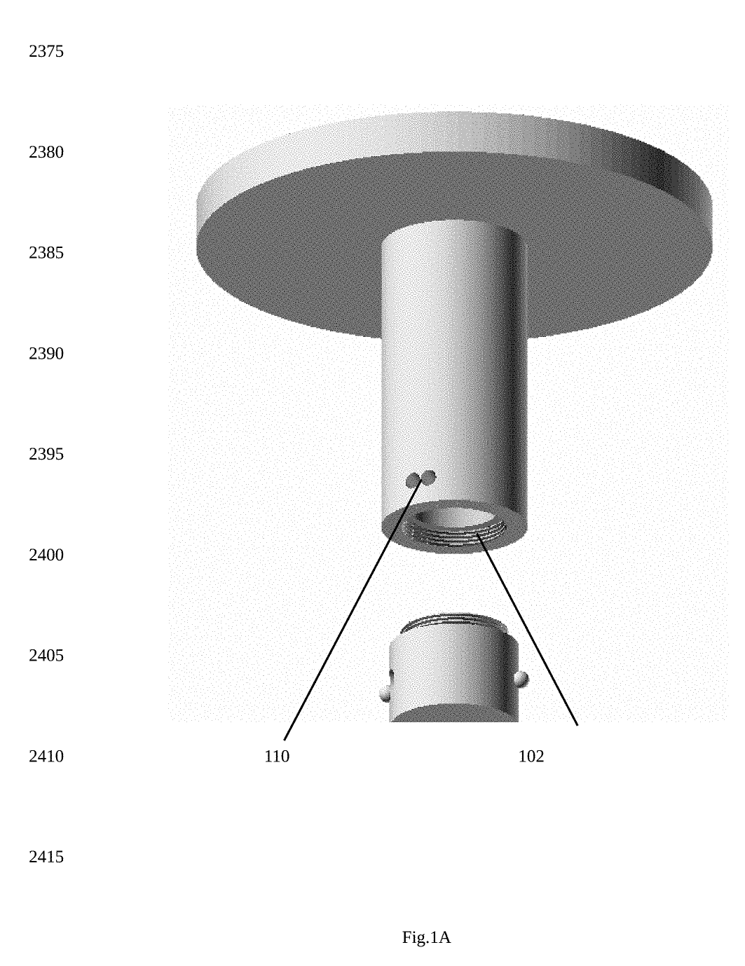

### Preferred Embodiment, FIGS. 1, 2, 3, 3A

Production platforms typically have the form of a disc carried by a column.

Additive manufacturing machines have means to gradually lower the platform as building progresses.

This happens when using the FDM technology of applying molten or softened threads of material through nozzles—as layers are deposited upon layers, making the product grow, the platform moves downward accordingly.

When the SLS technique is used, powder is being dispersed one layer at a time, and parts of the powder of each layer is being sintered by laser beams to make the product grow one layer at a time. The platform is likewise lowered accordingly.

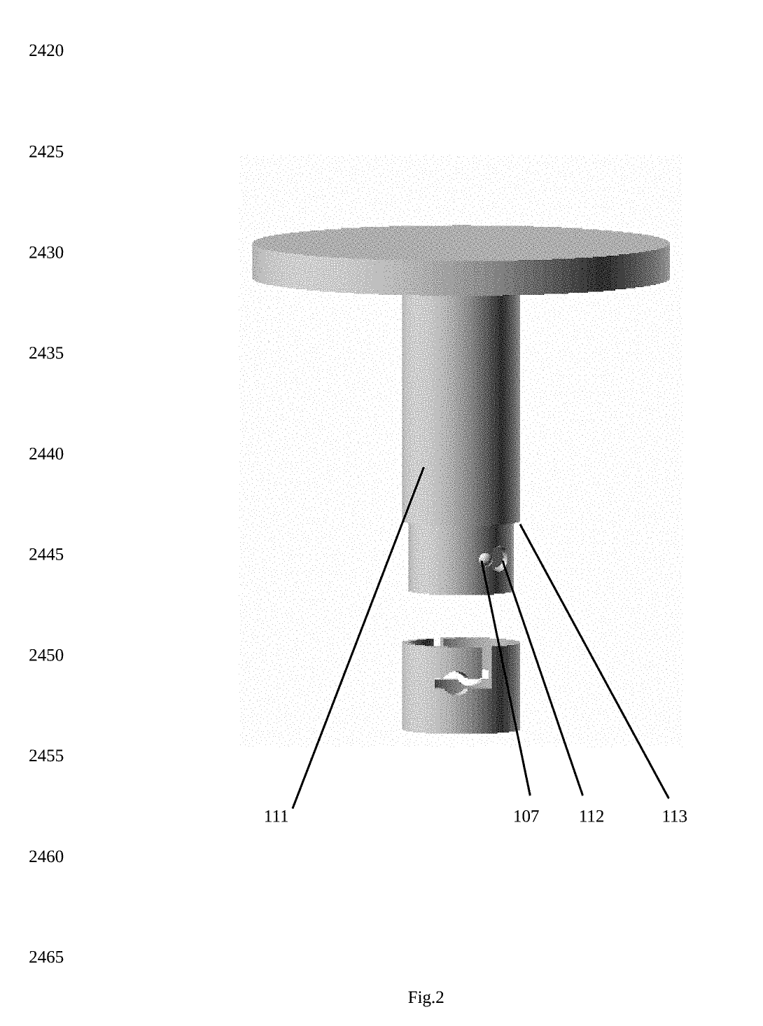

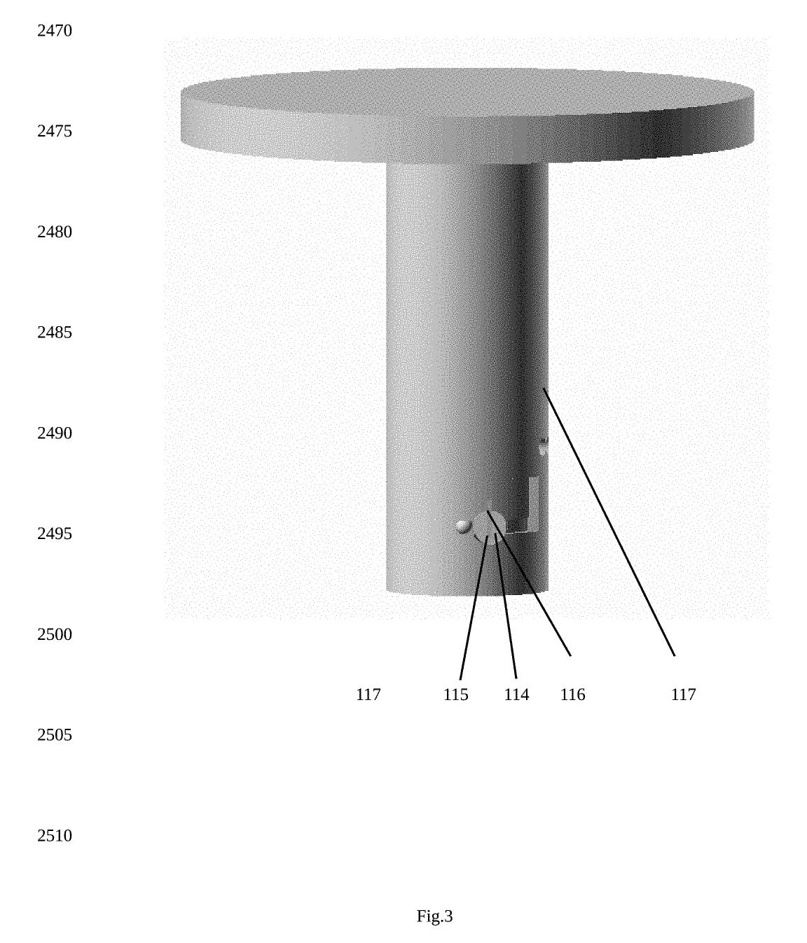

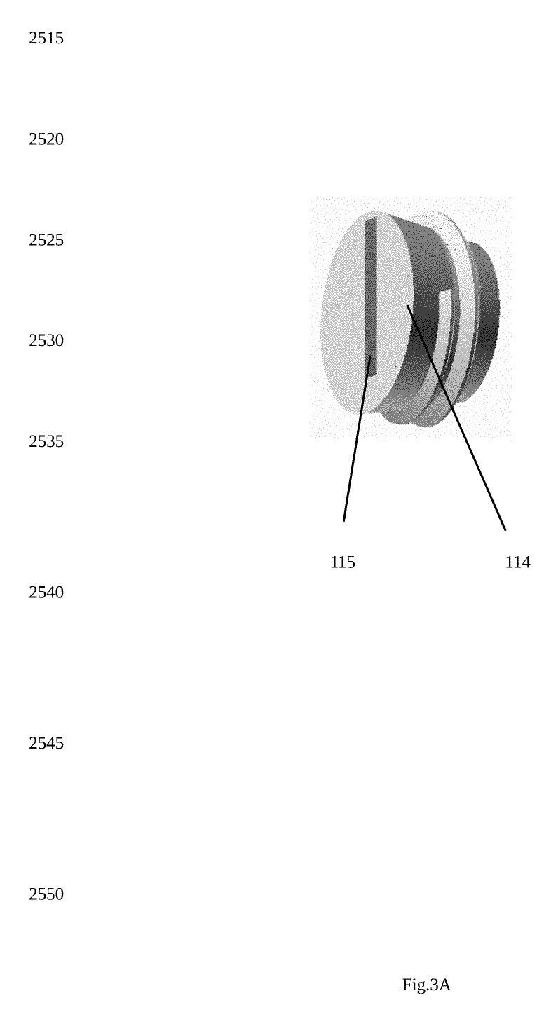

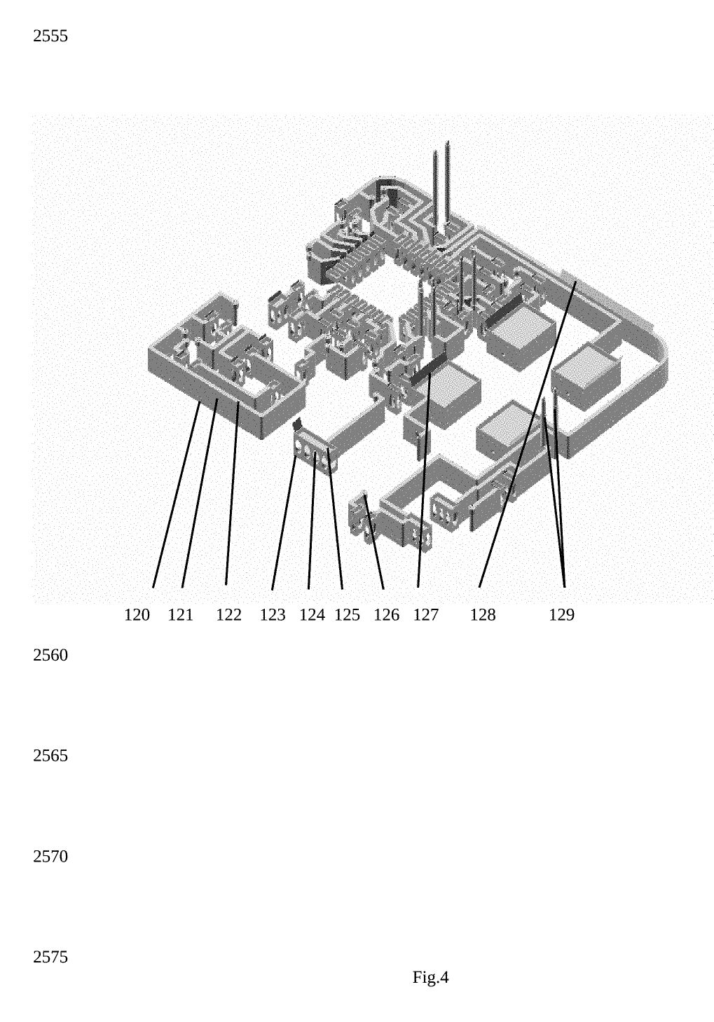

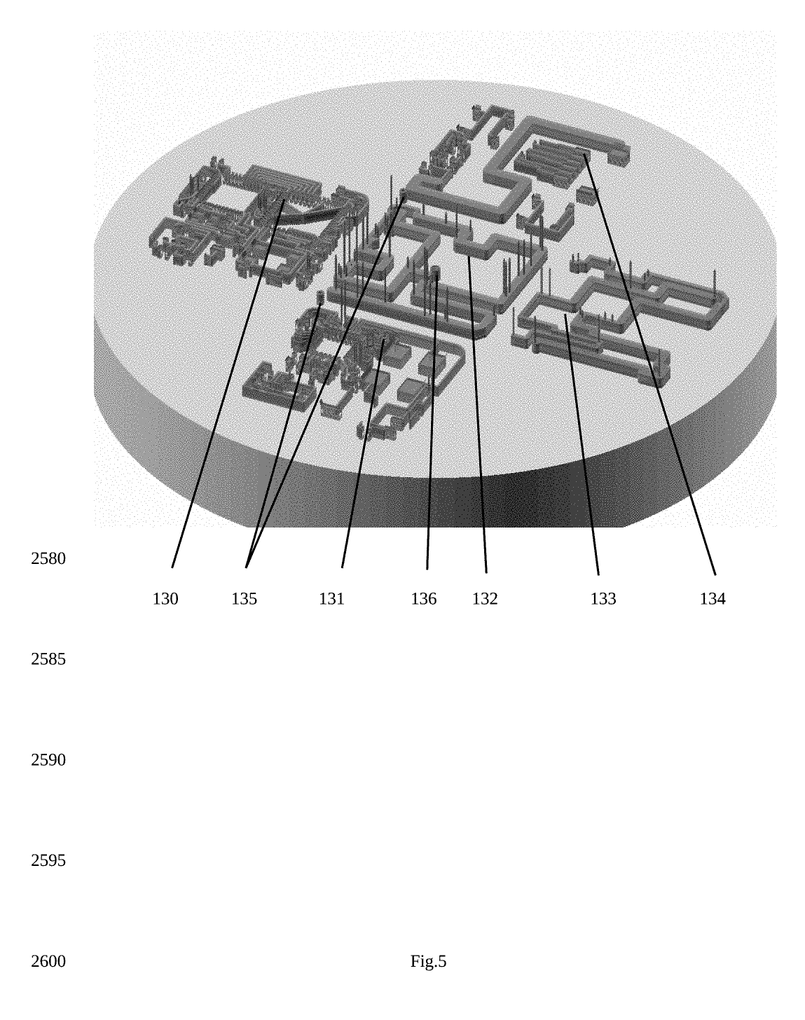

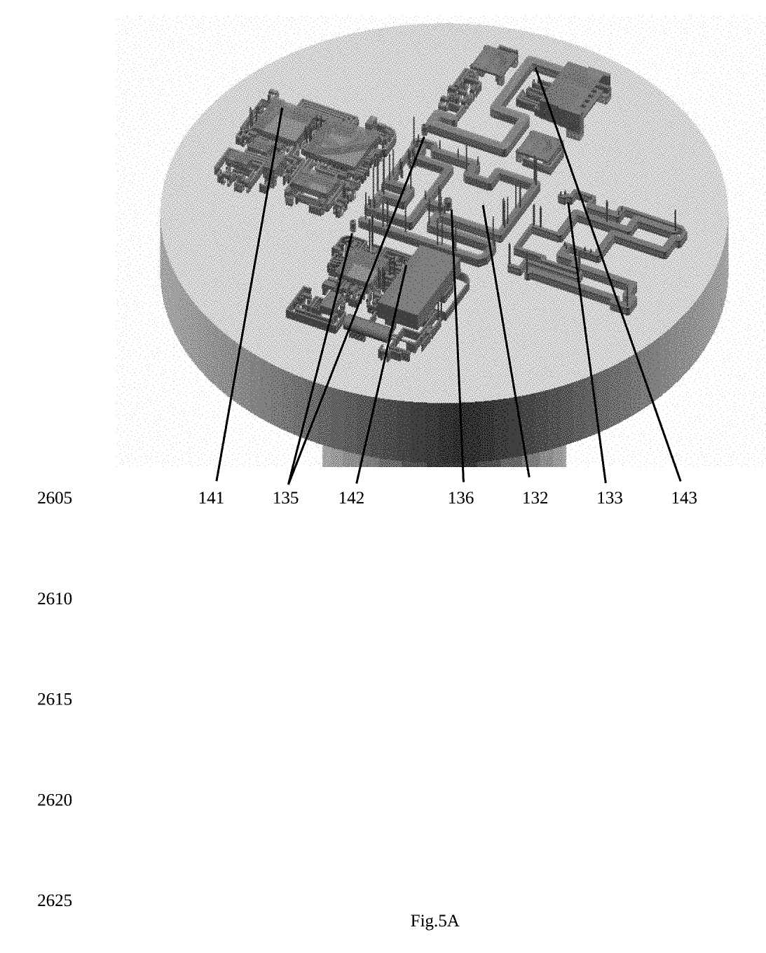

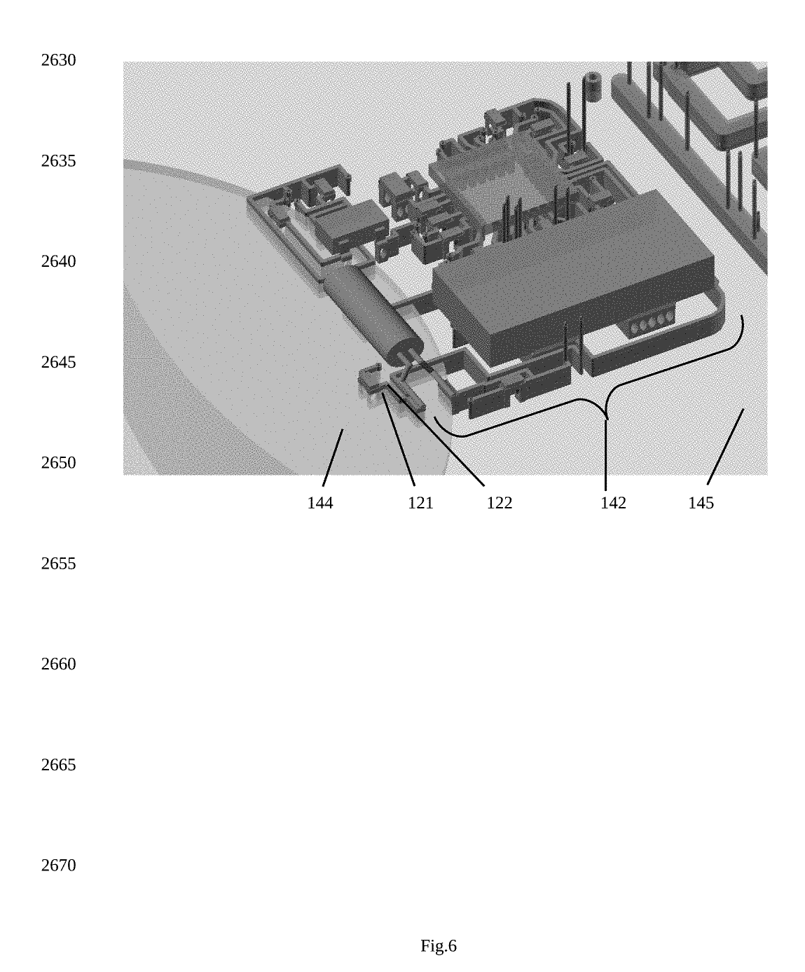

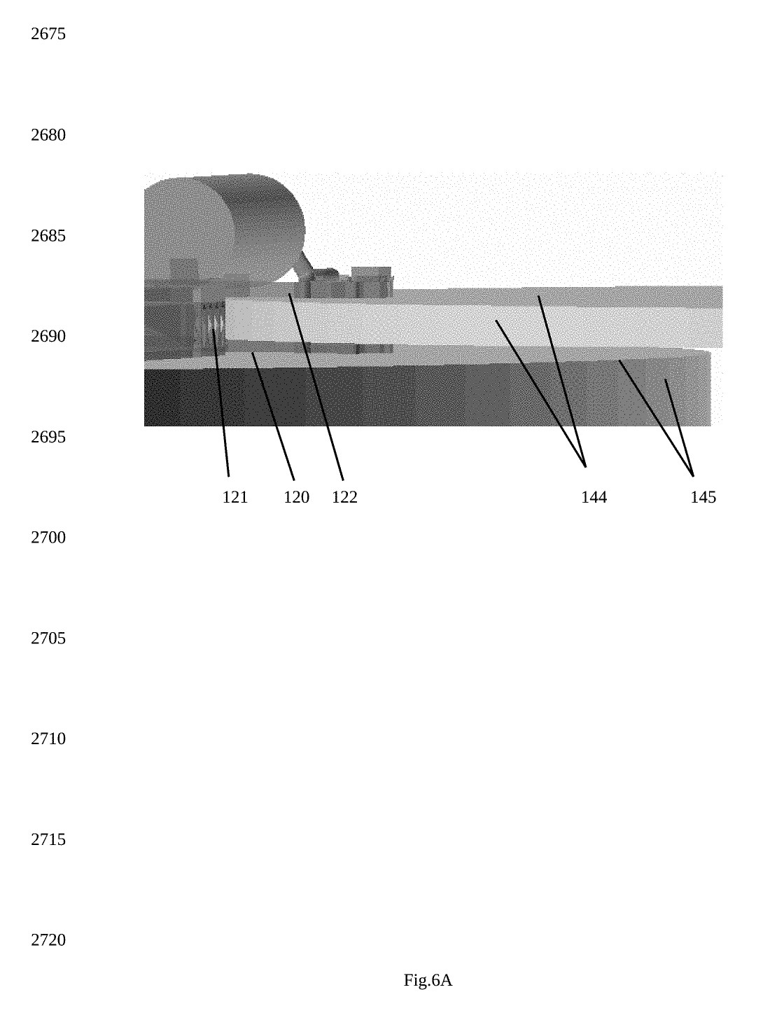

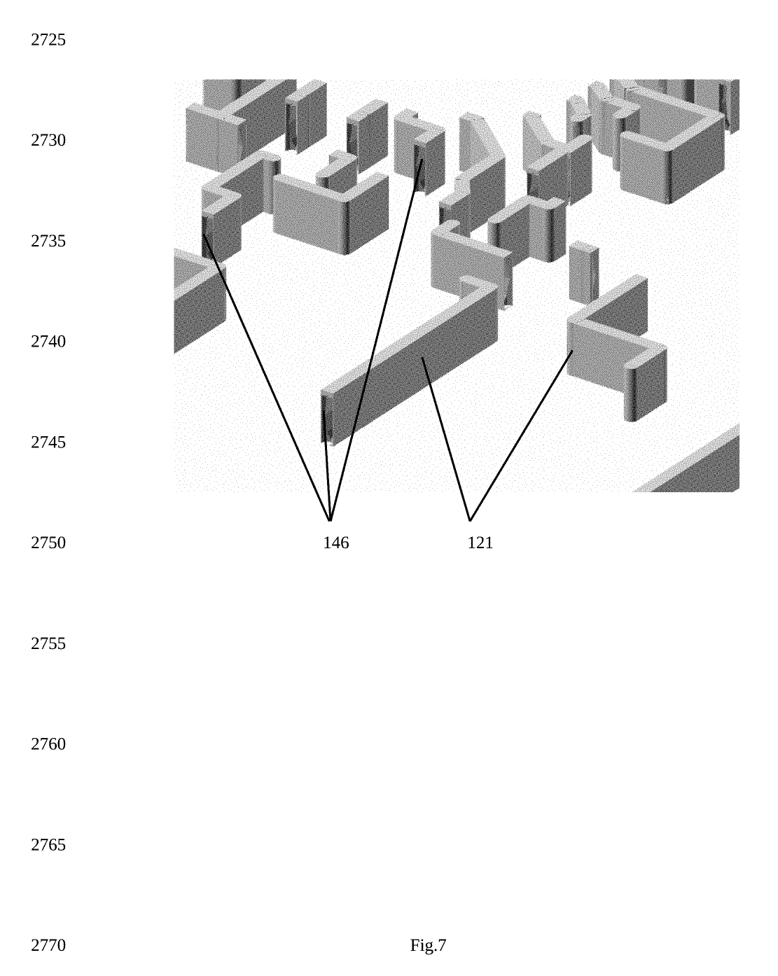

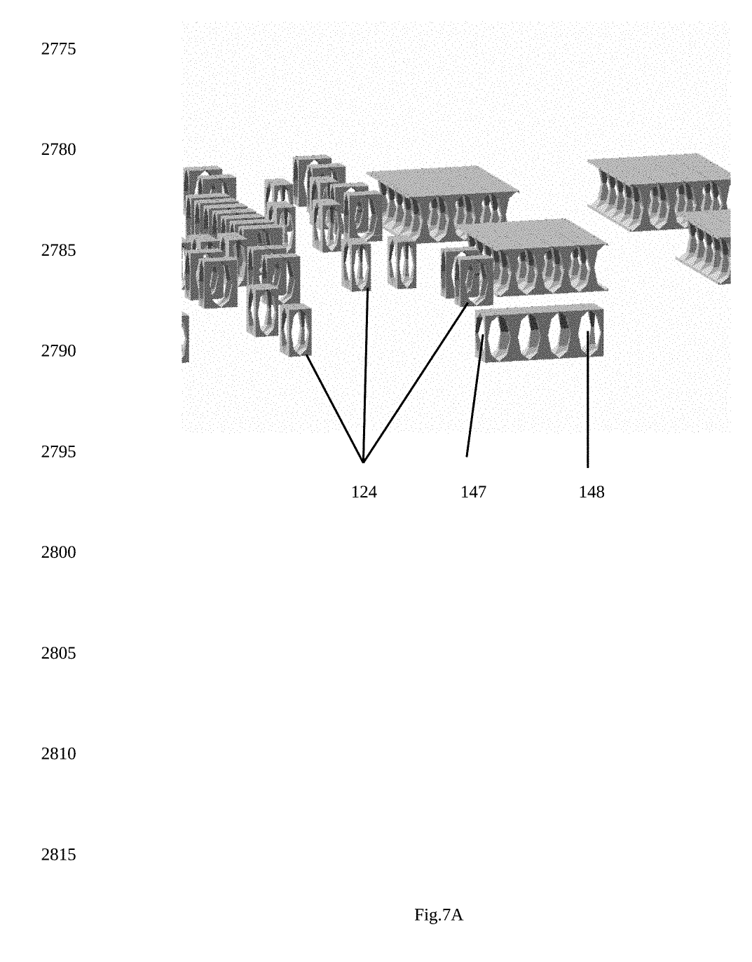

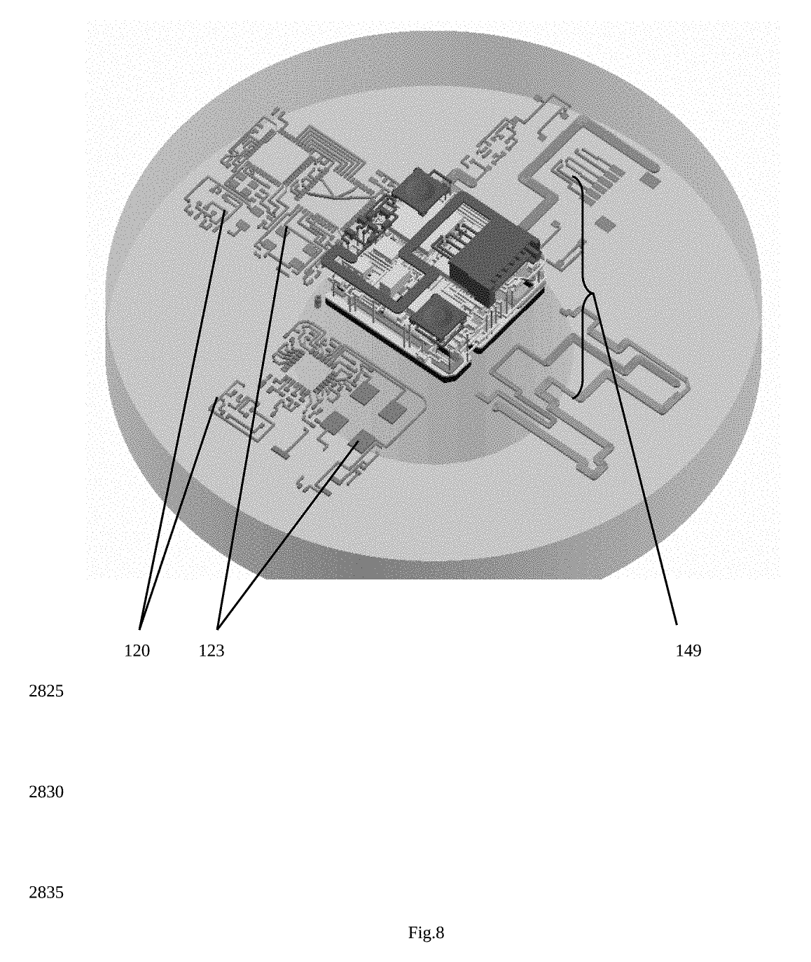

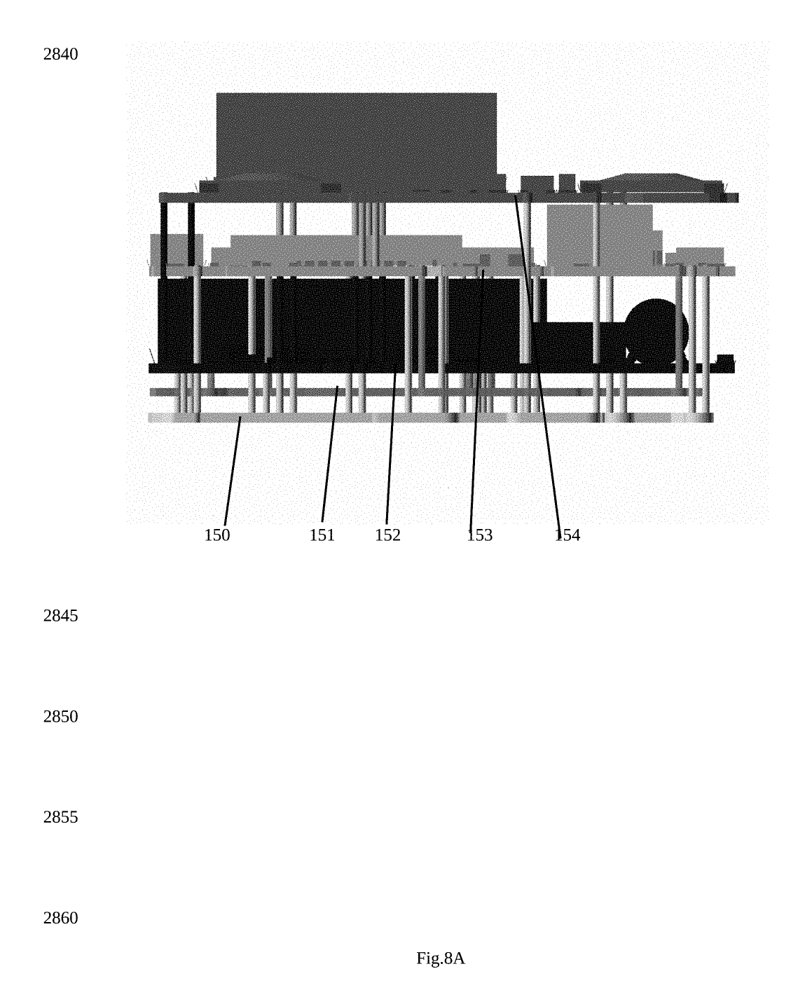

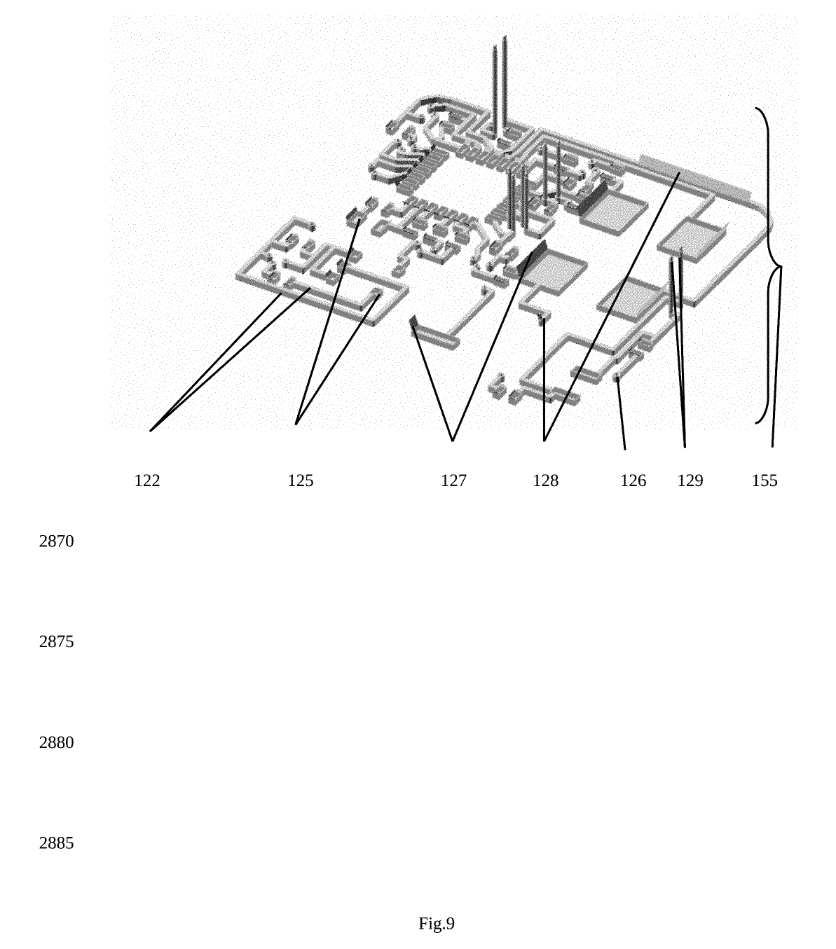

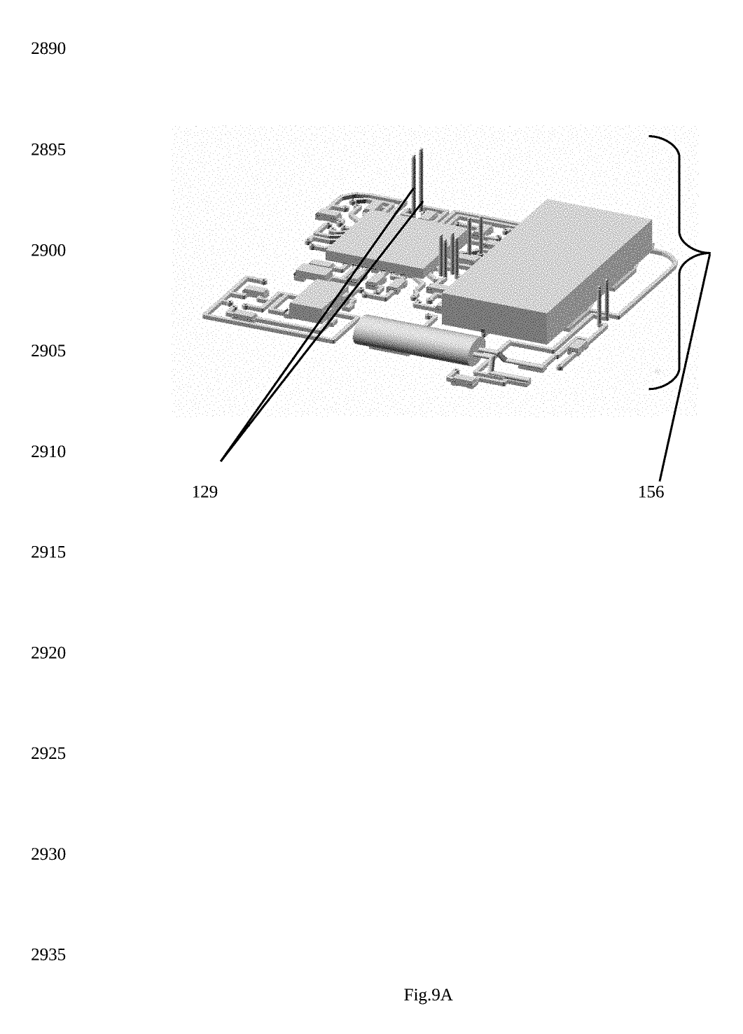

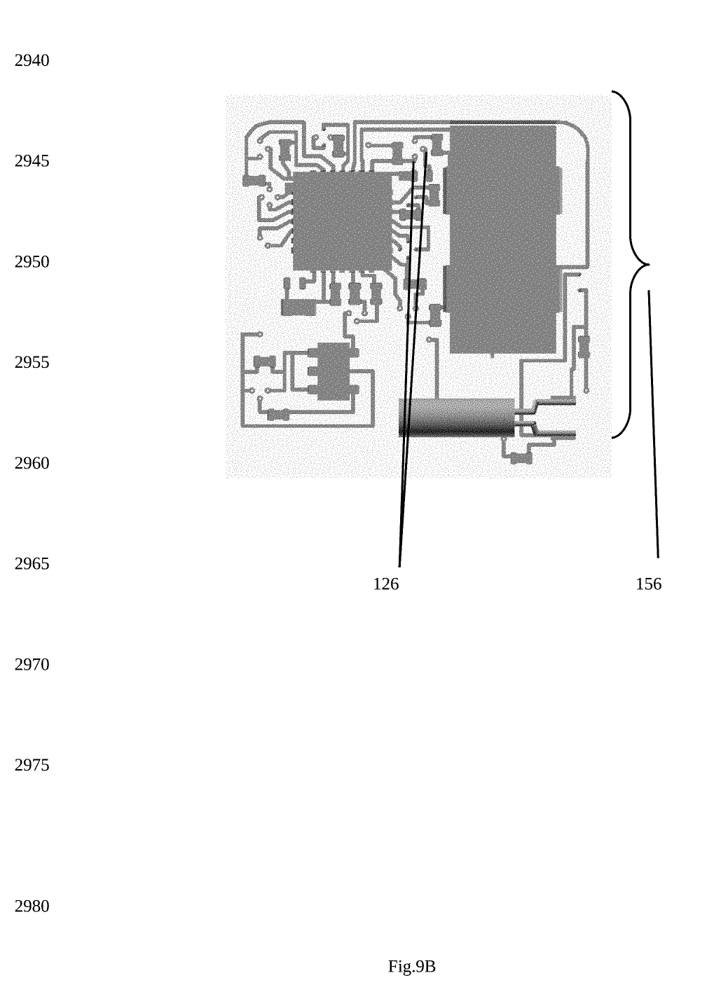

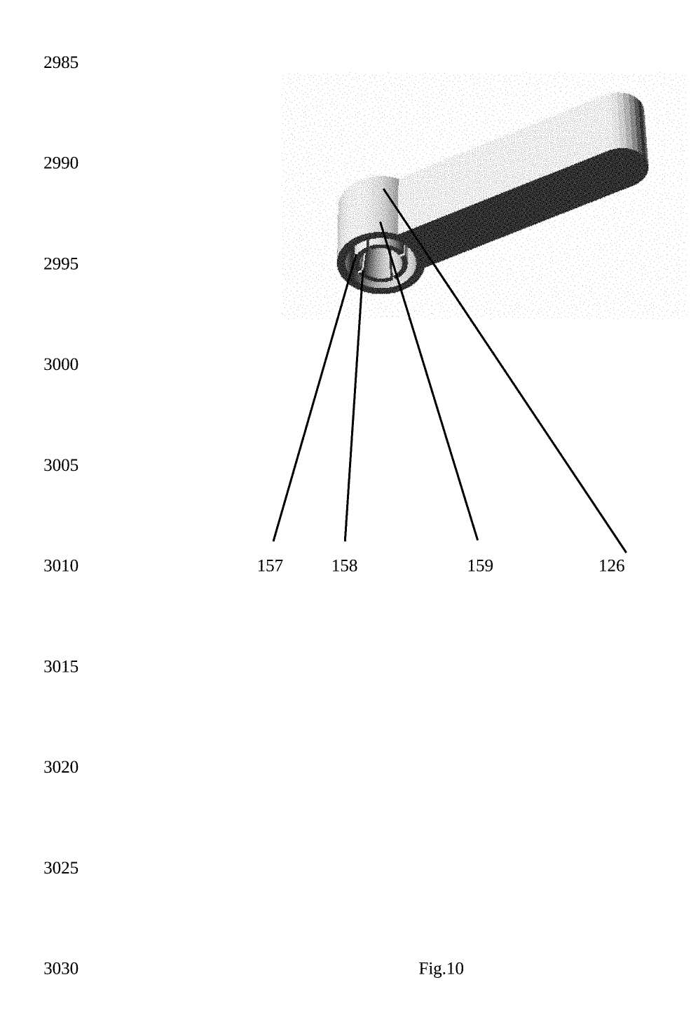

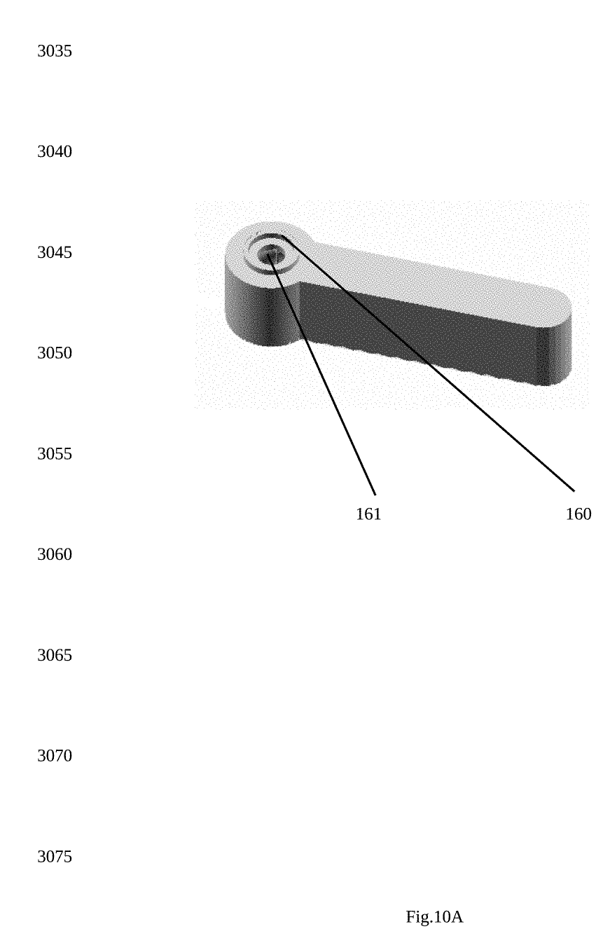

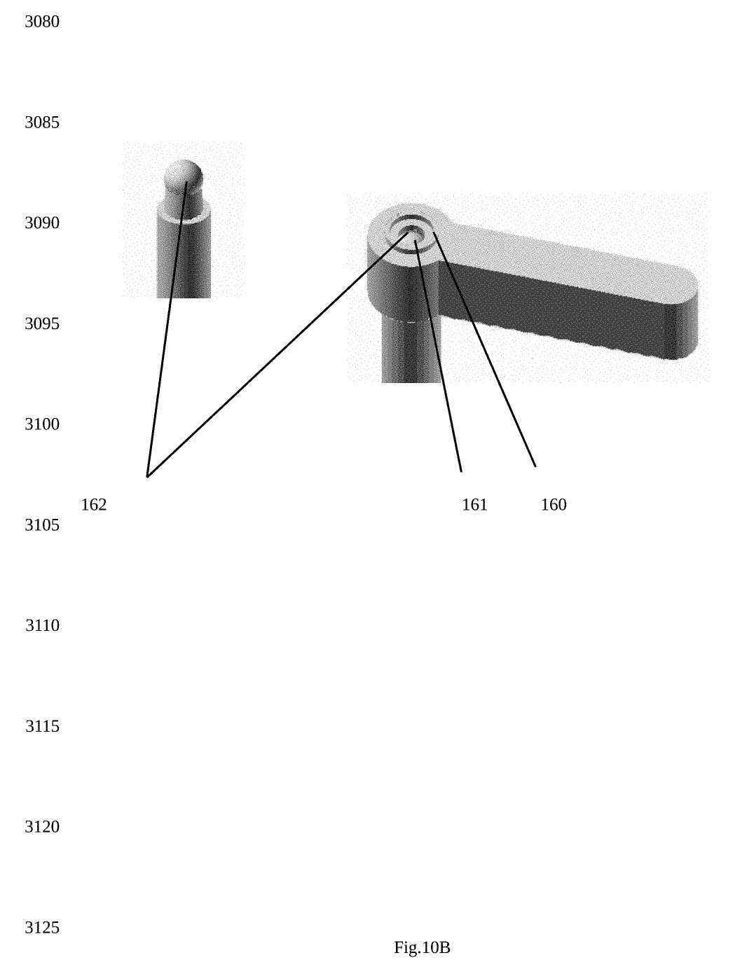

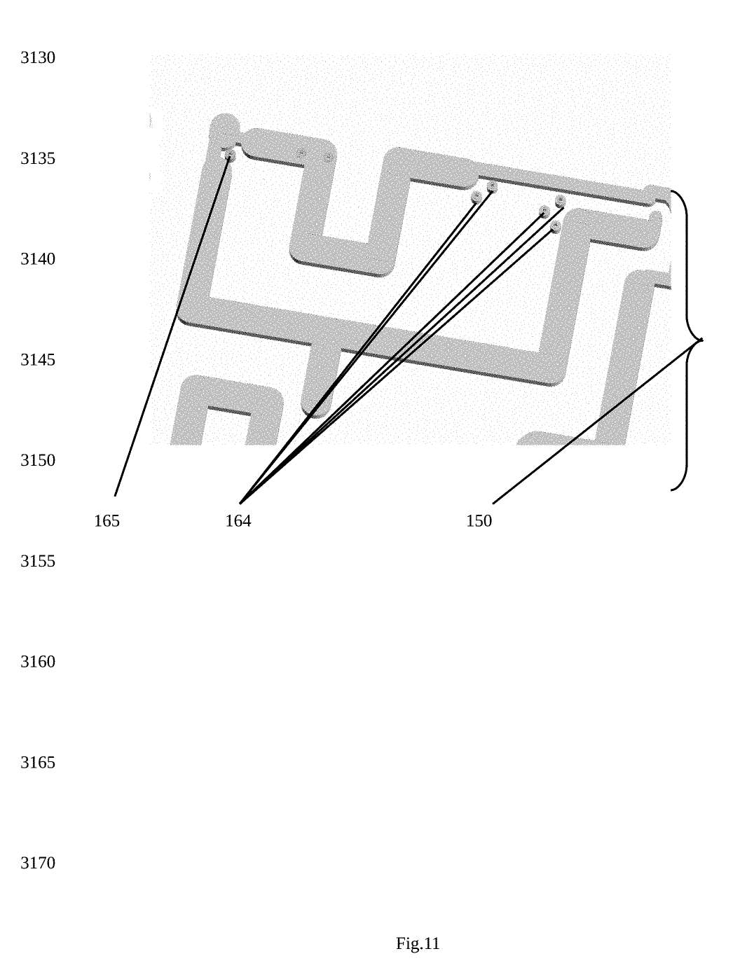

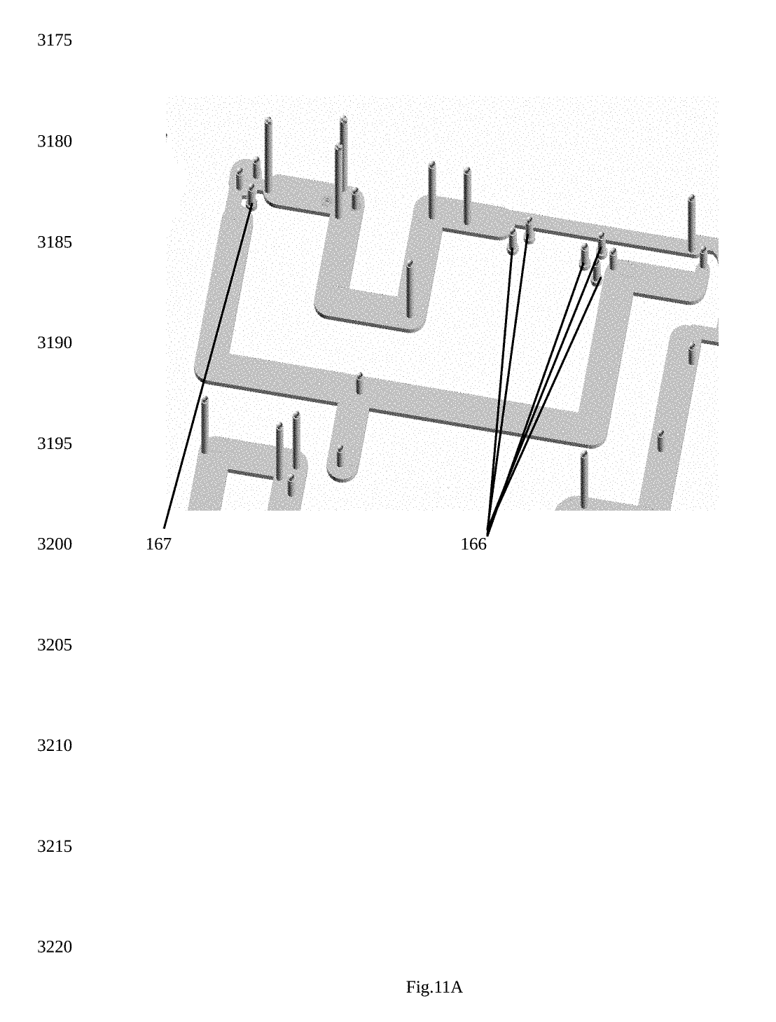

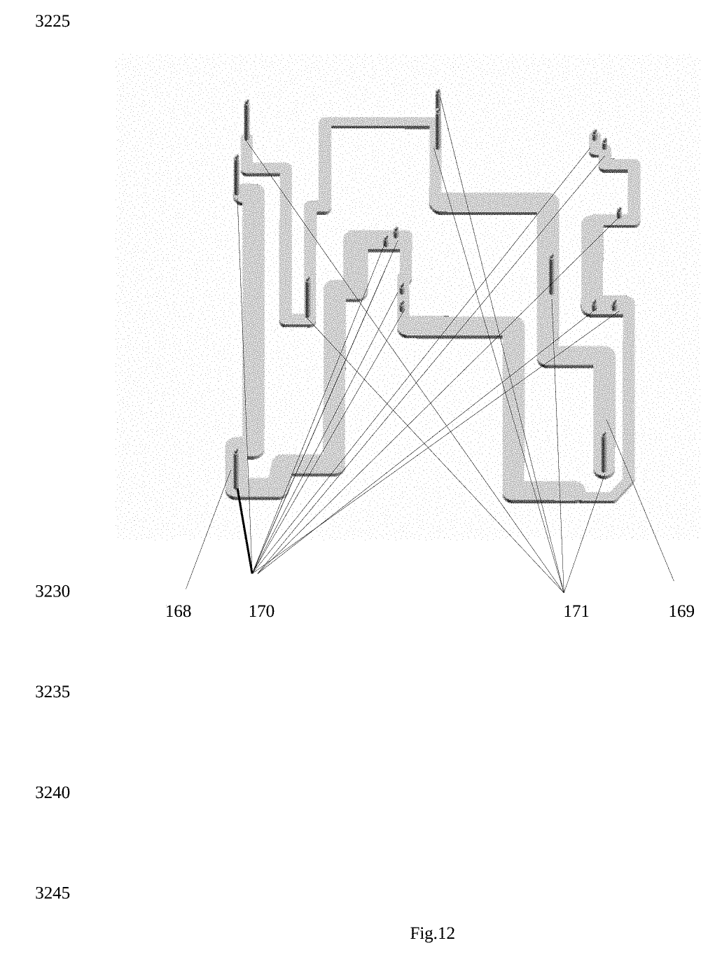

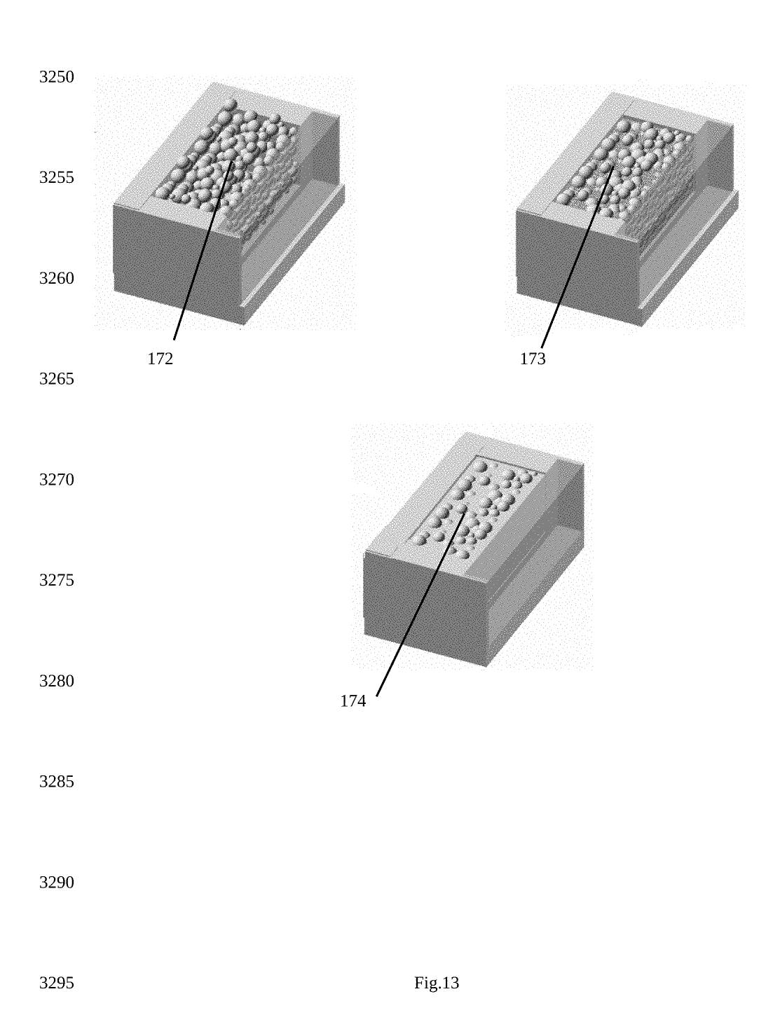

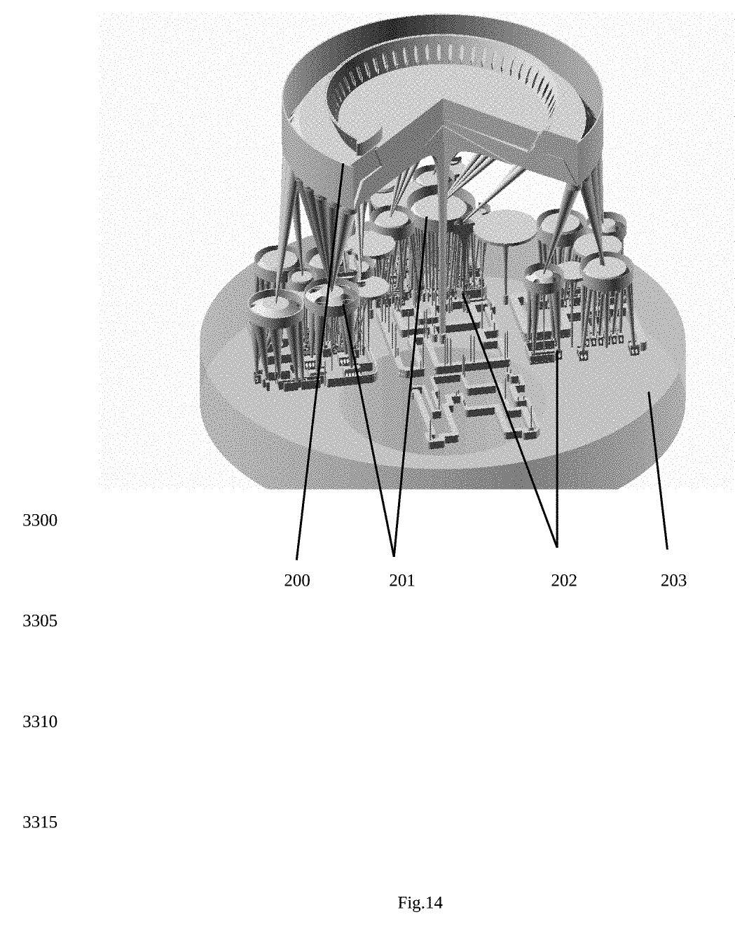

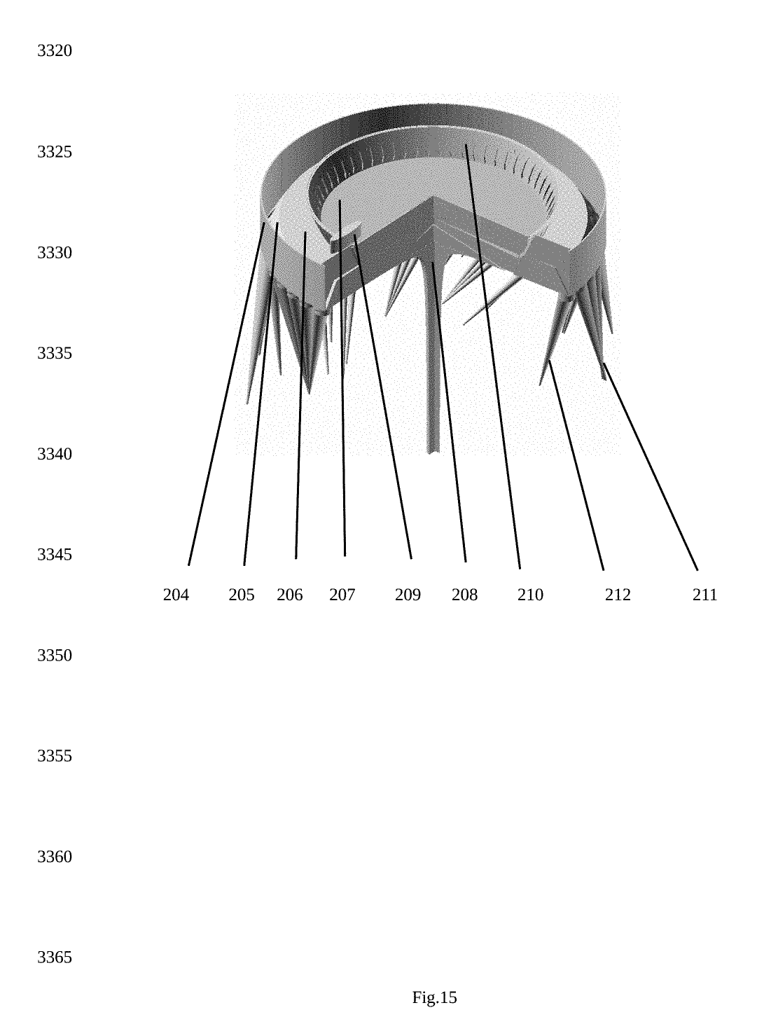

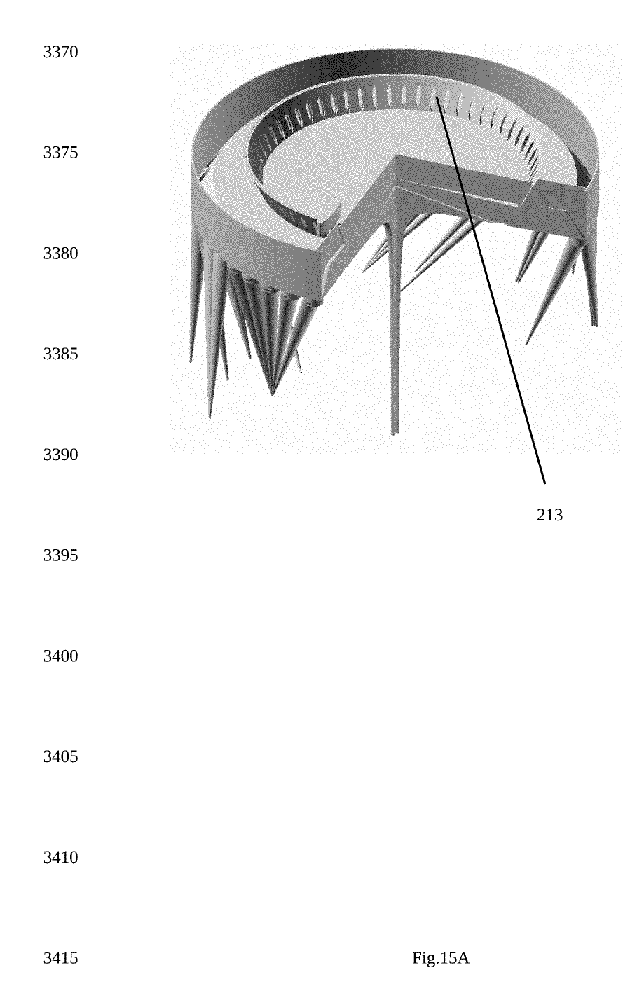

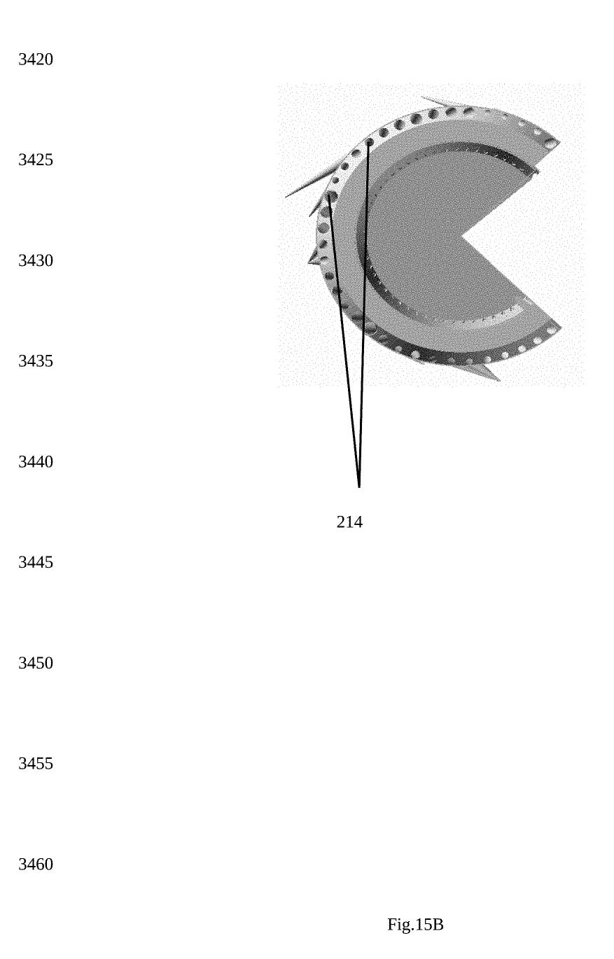

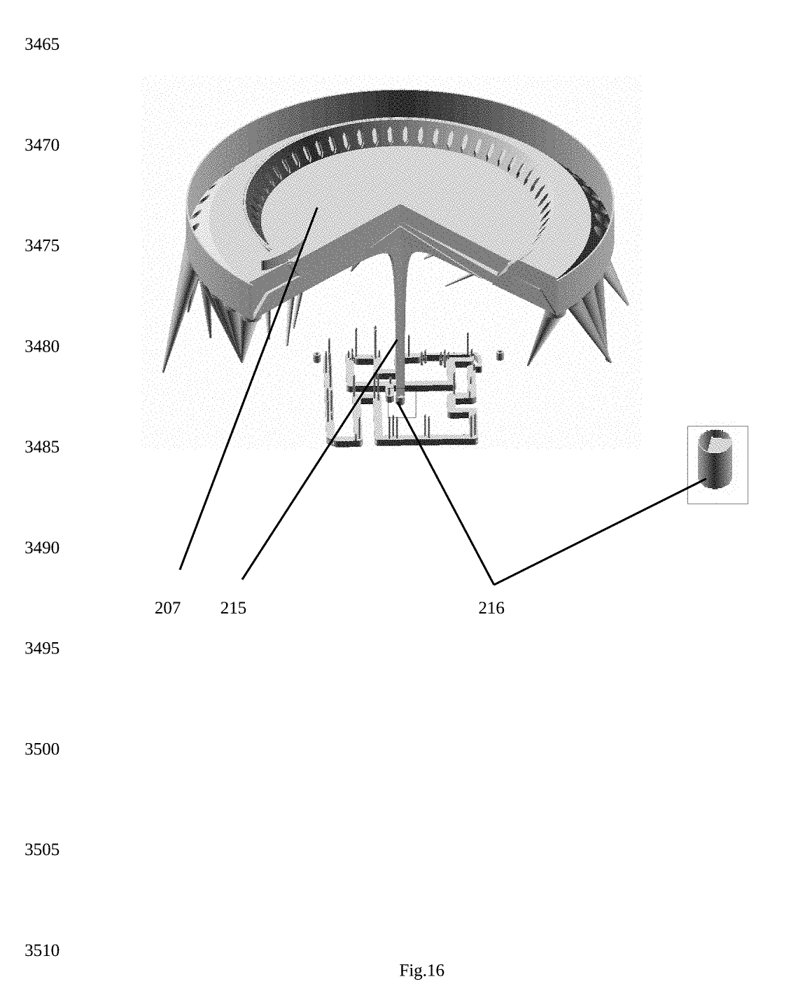

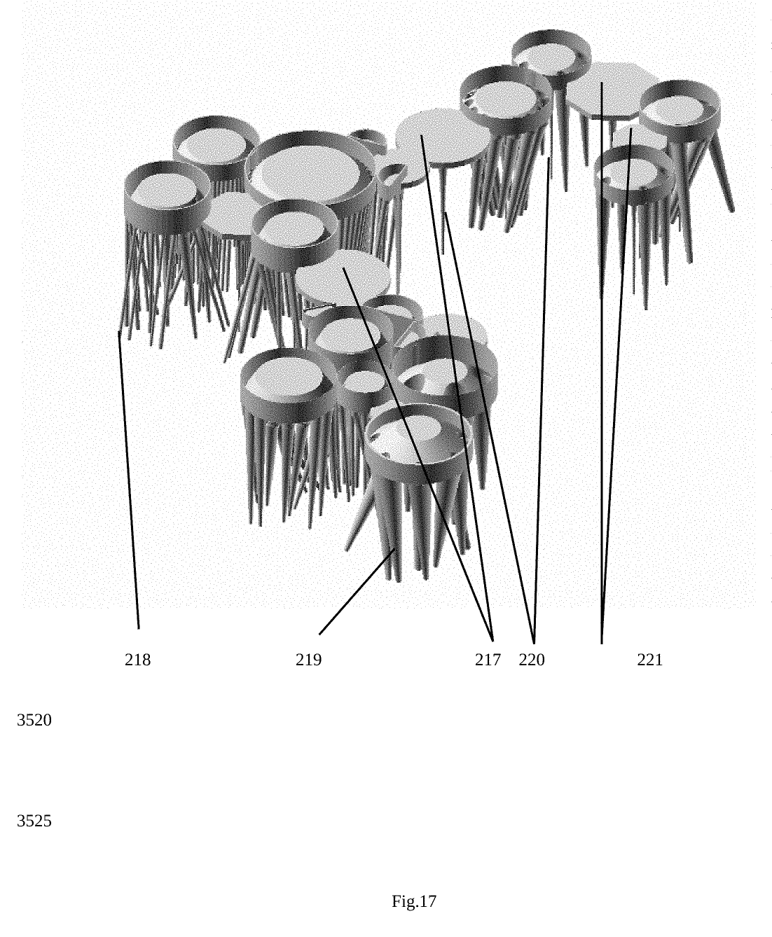

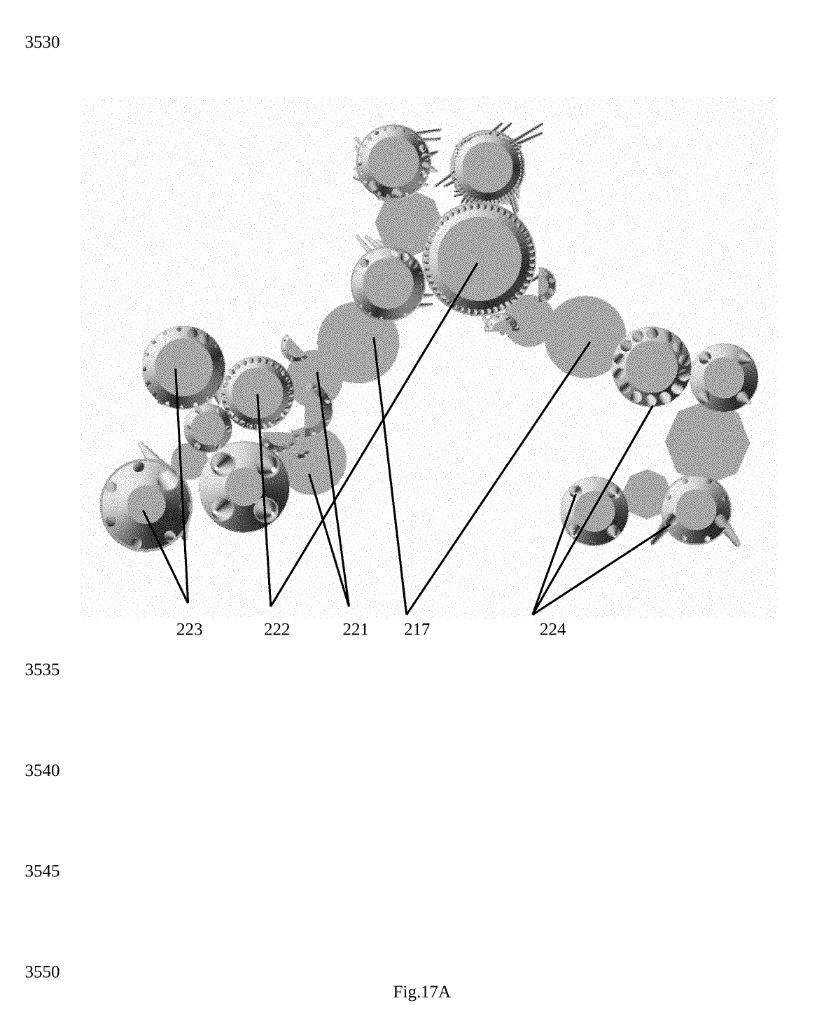

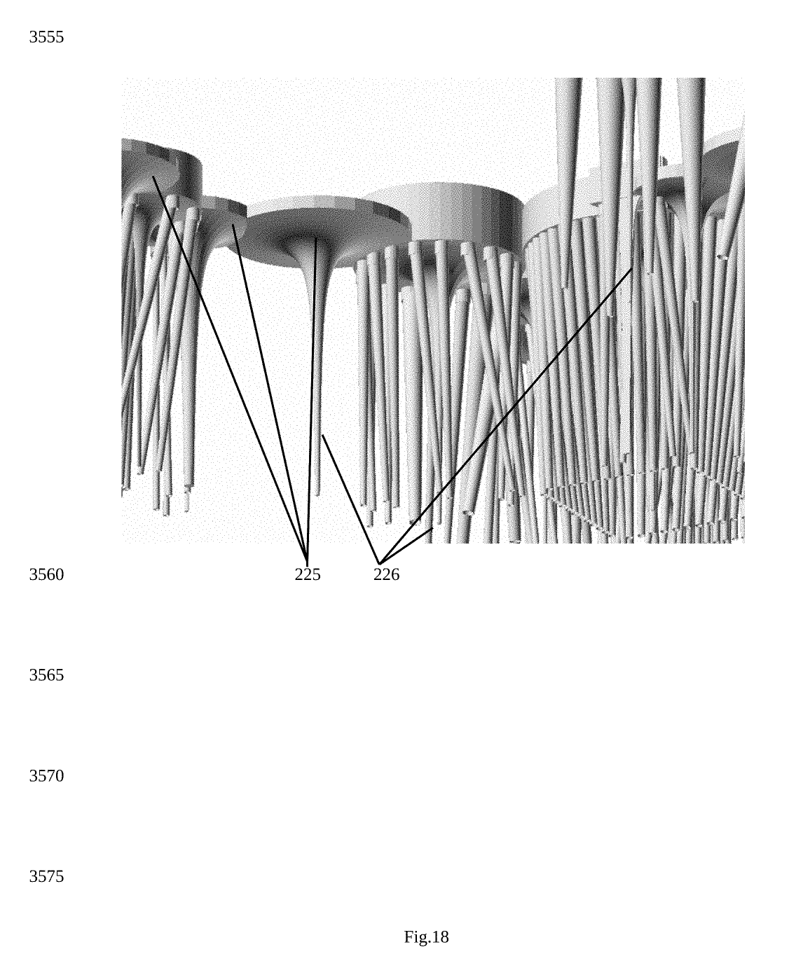

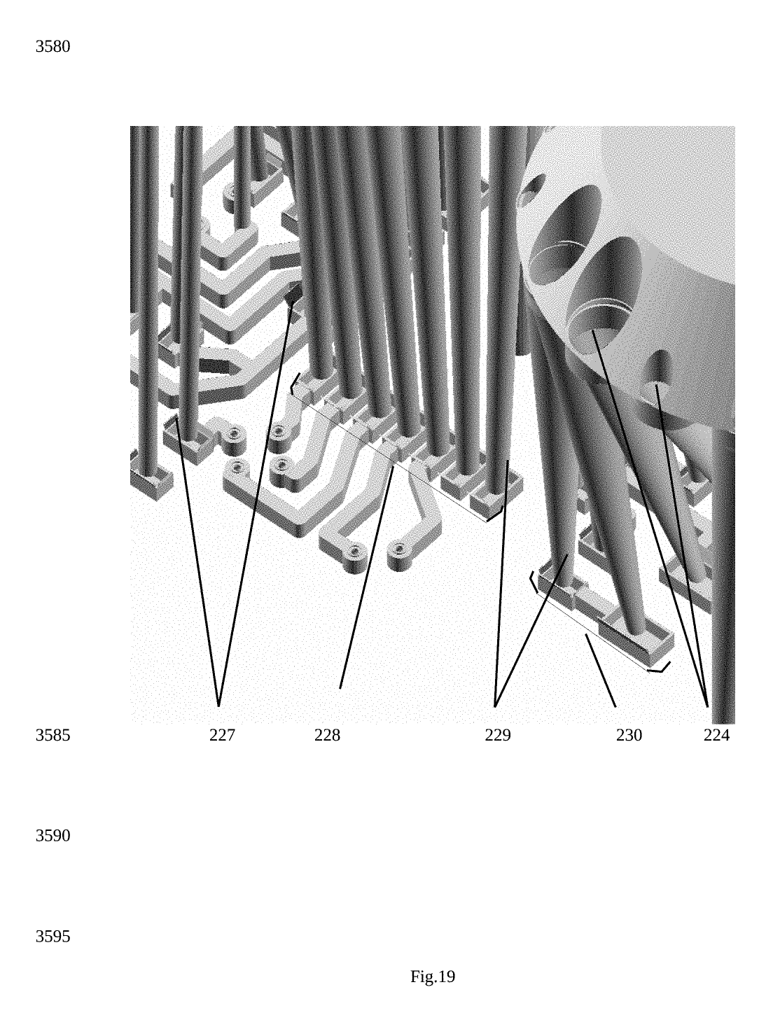

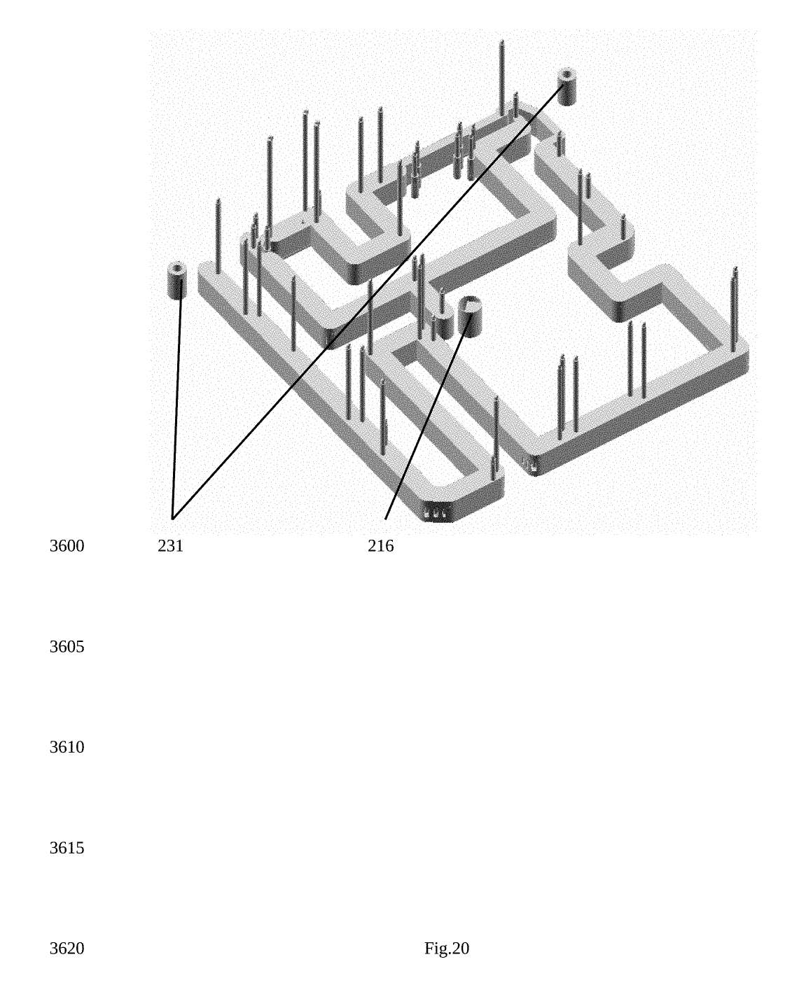

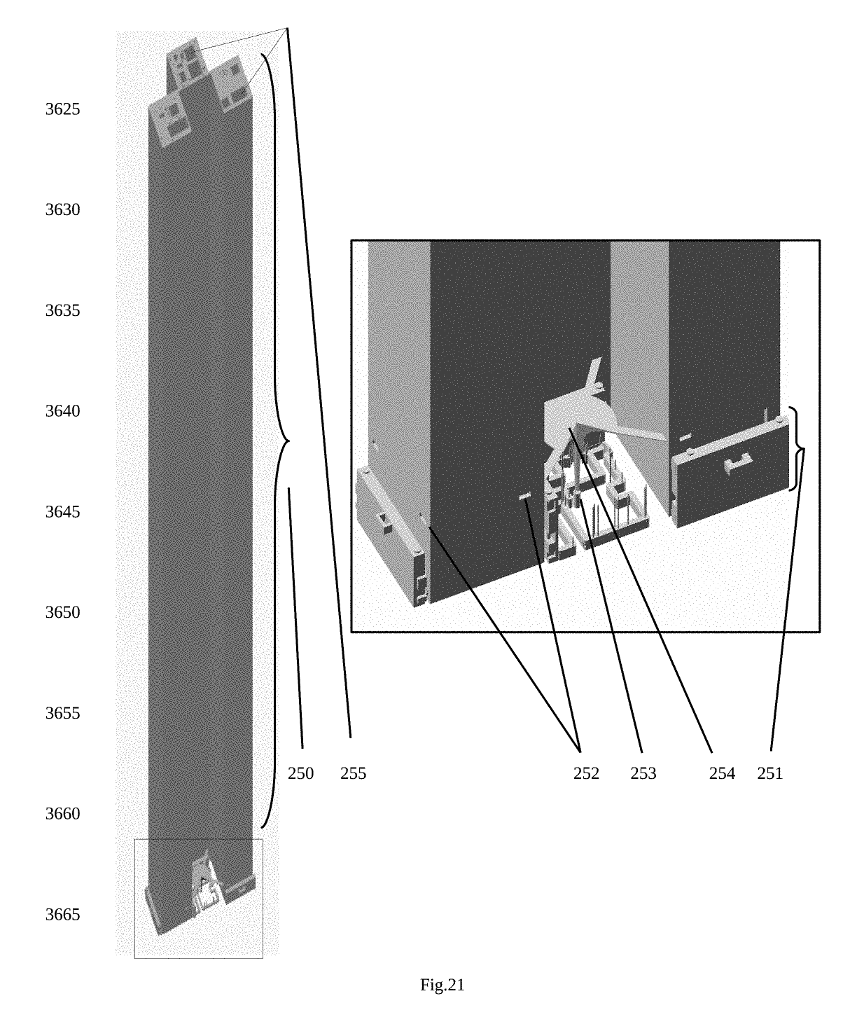

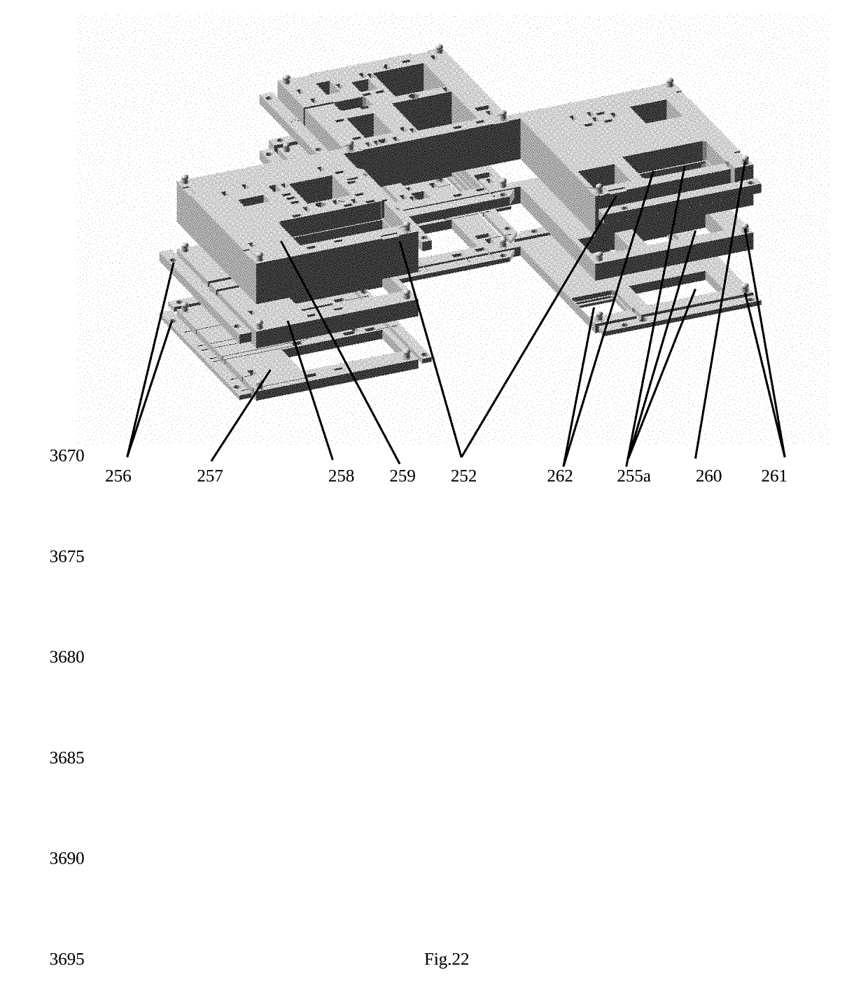

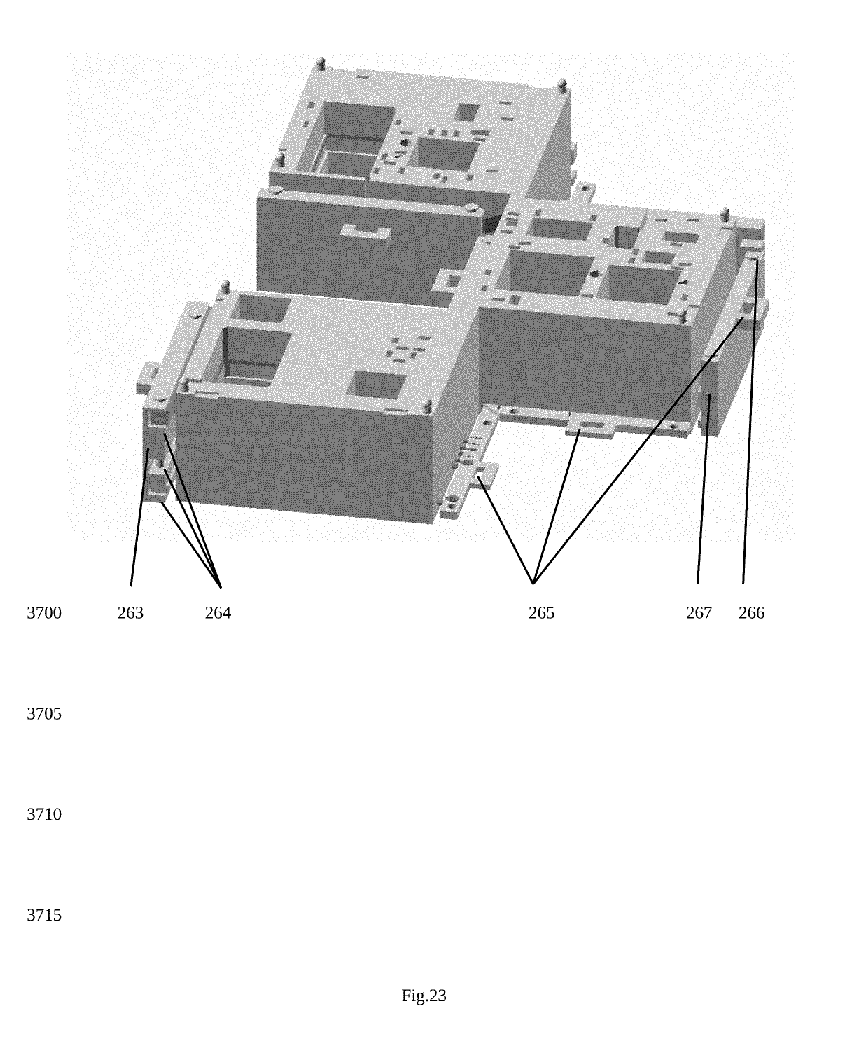

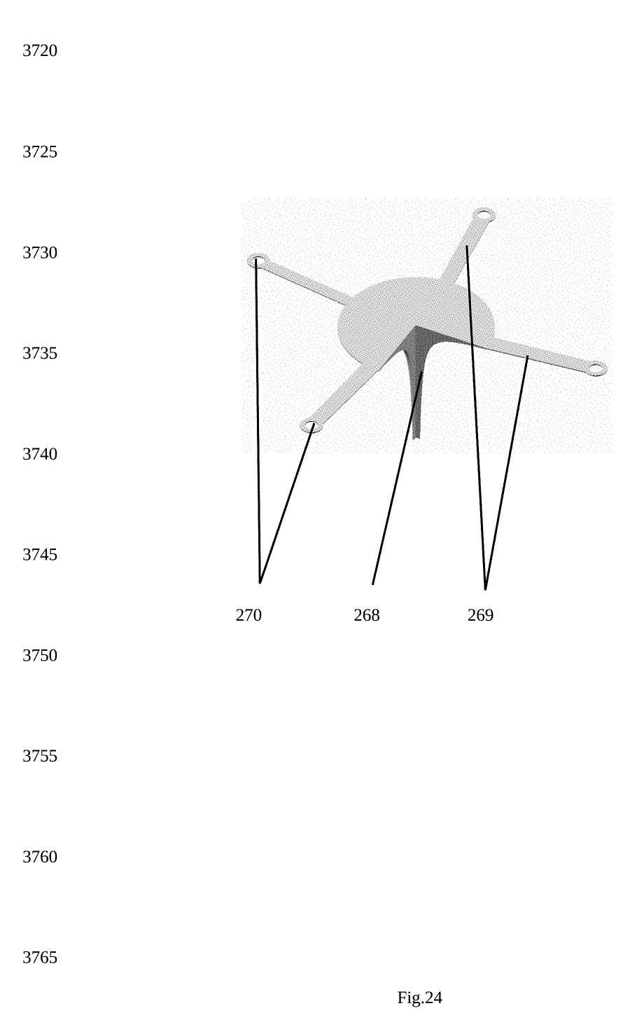

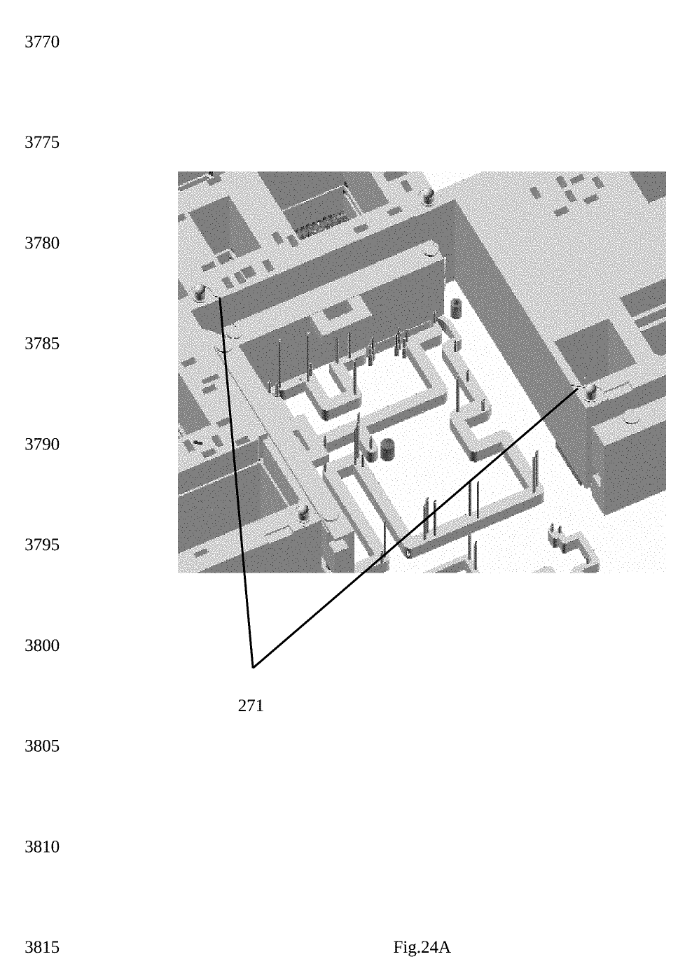

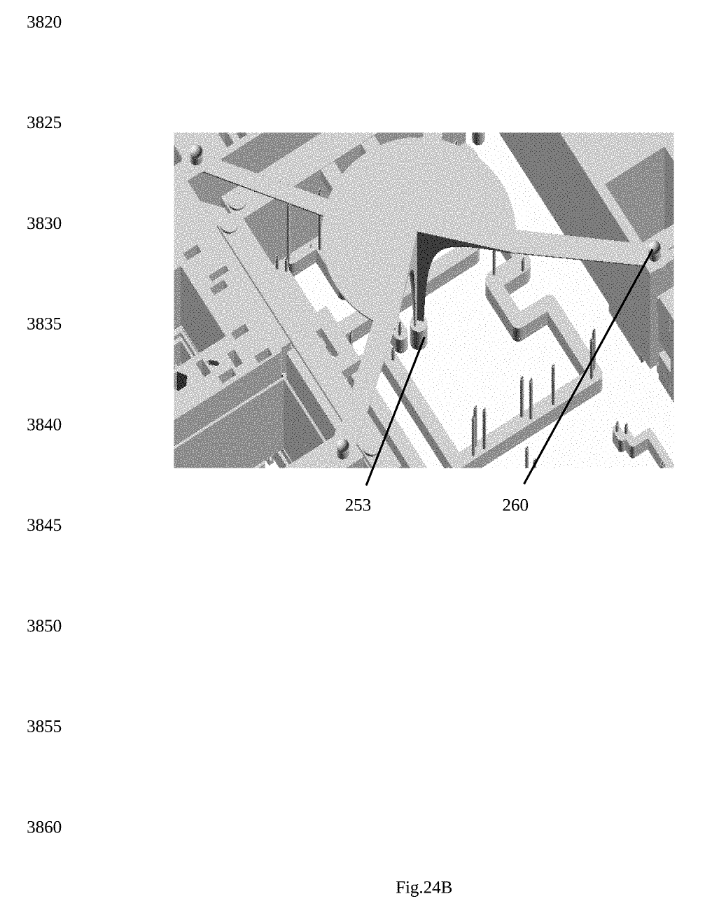

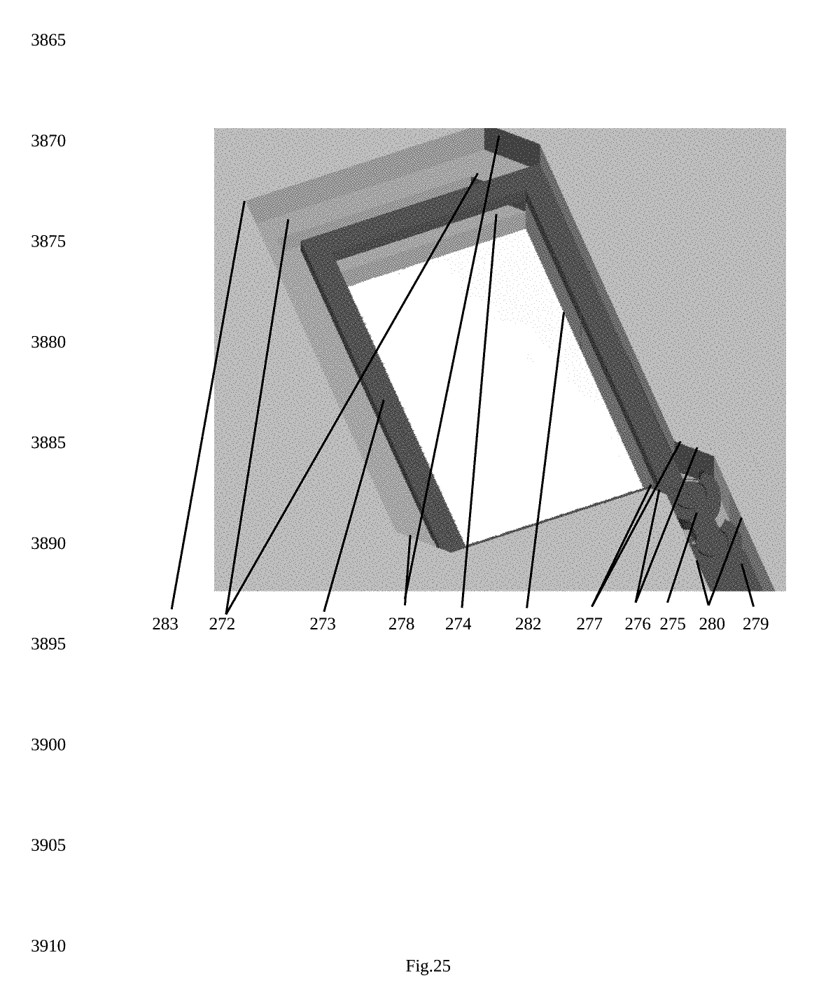

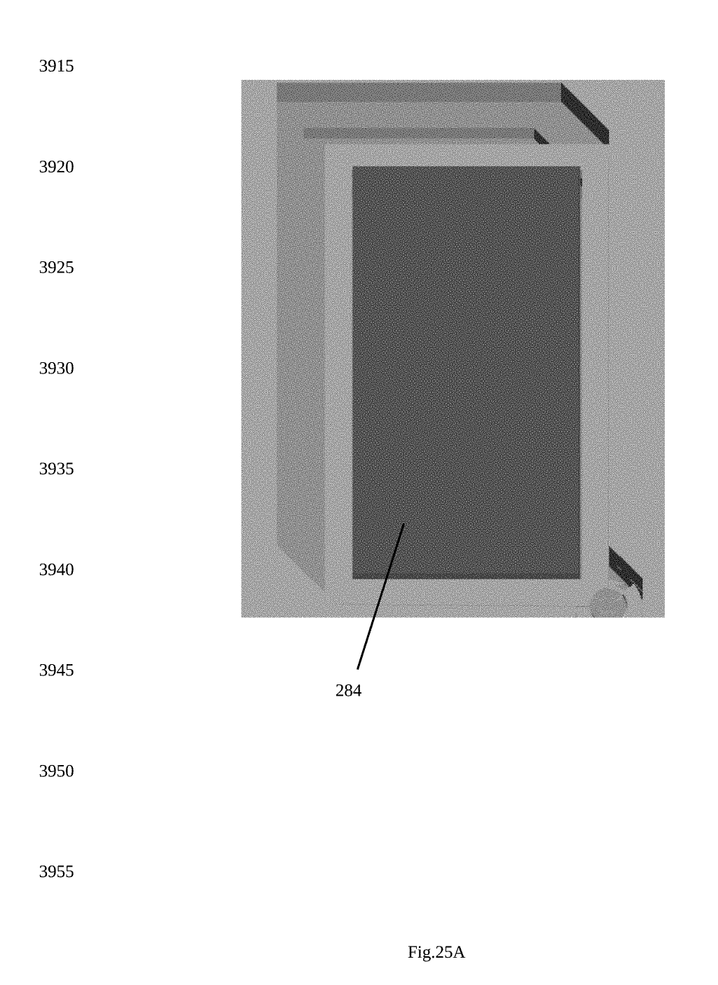

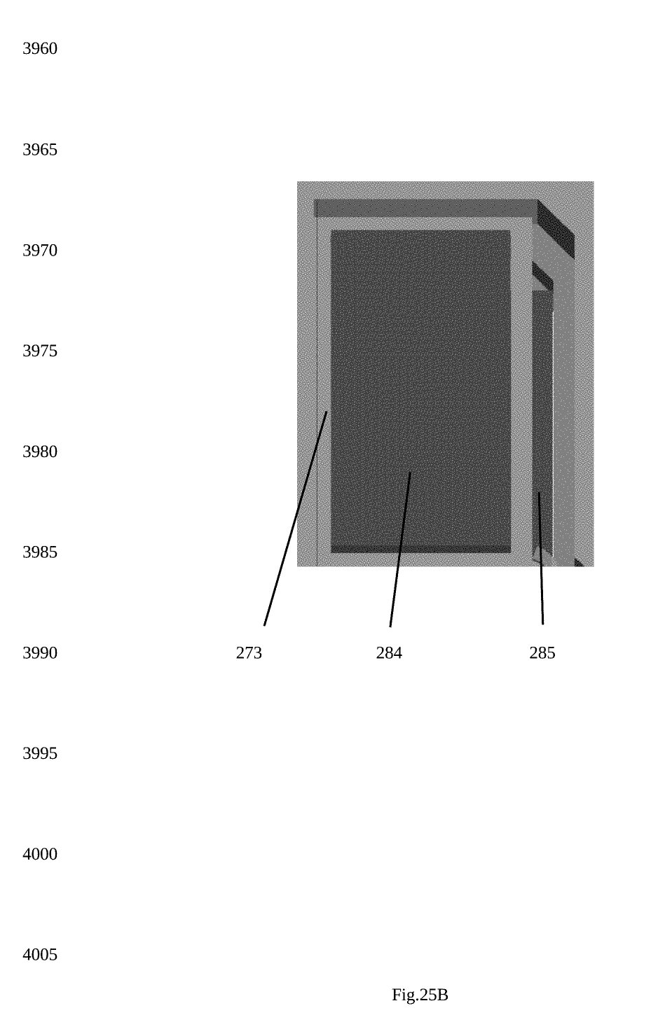

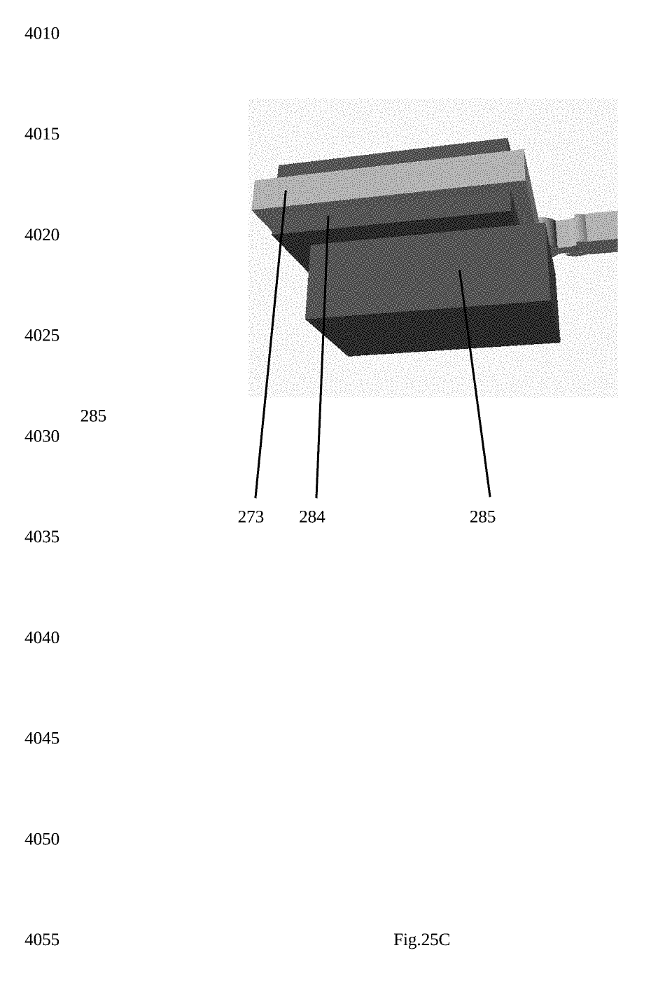

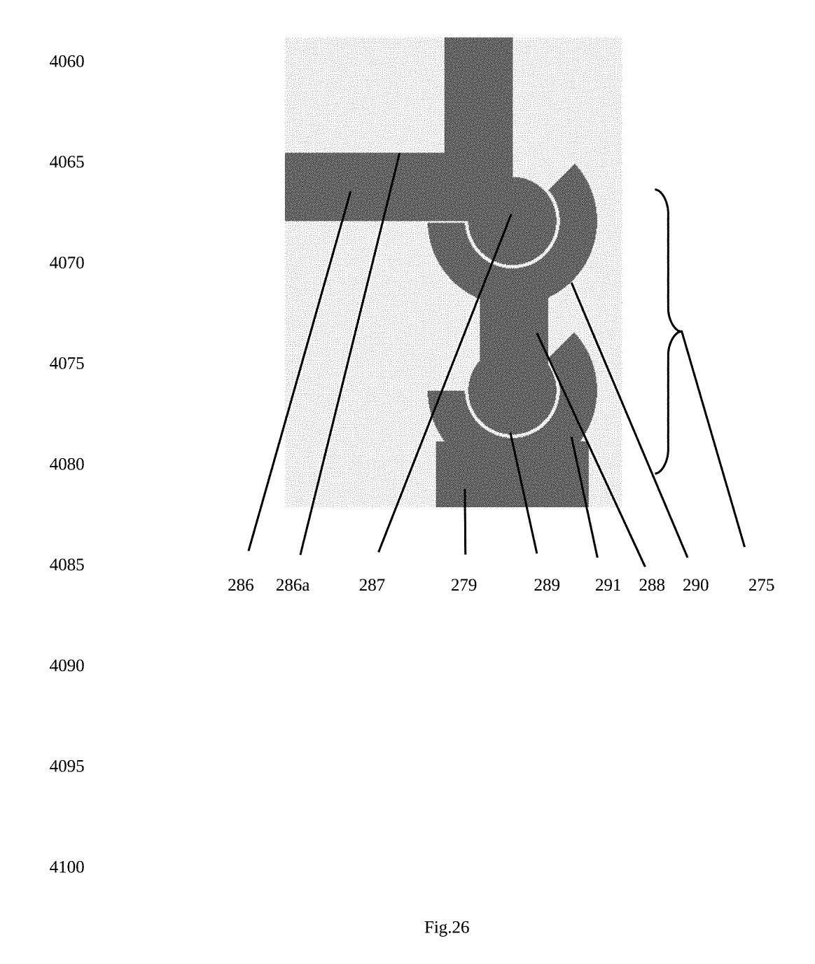

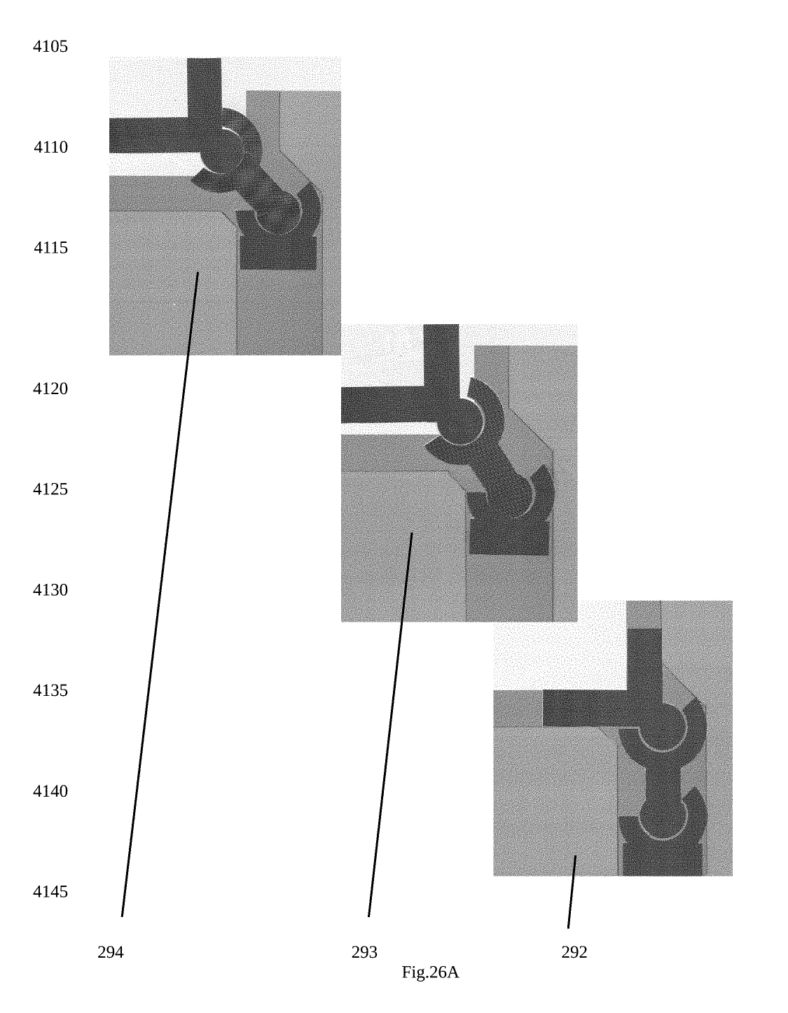

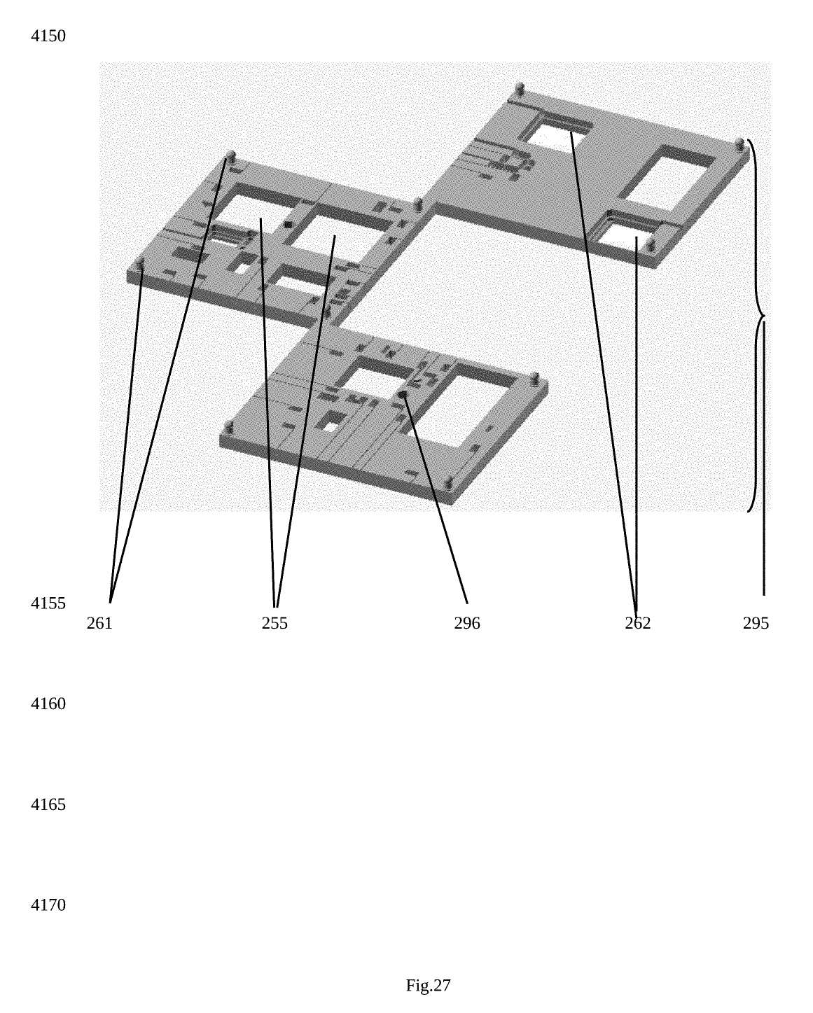

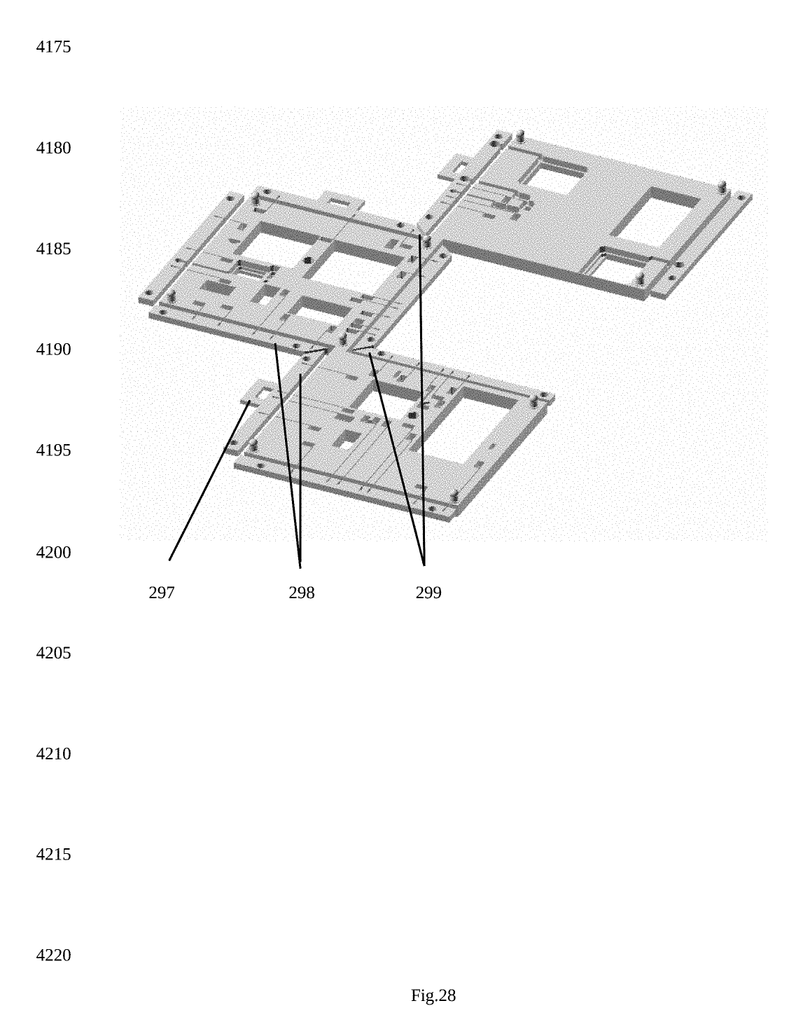

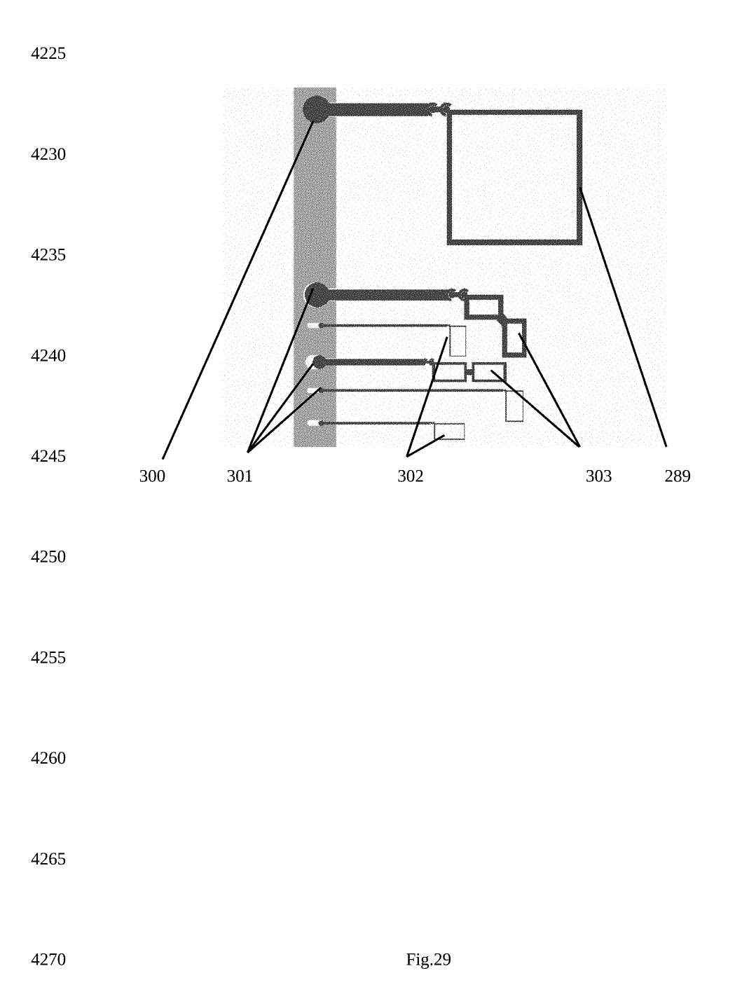

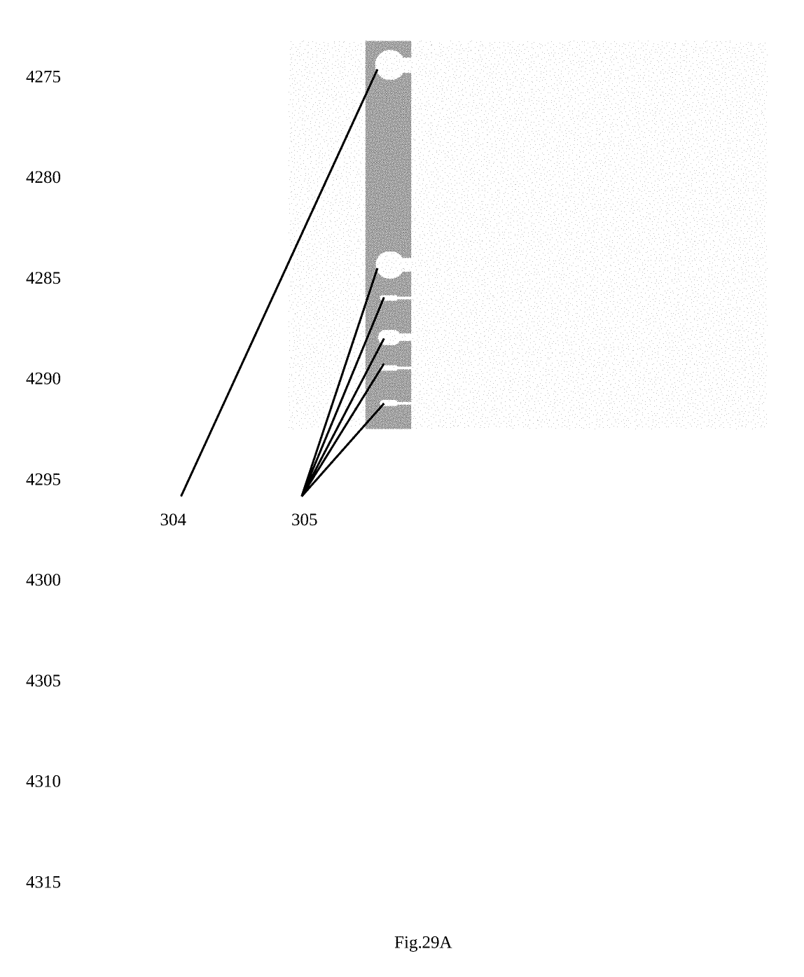

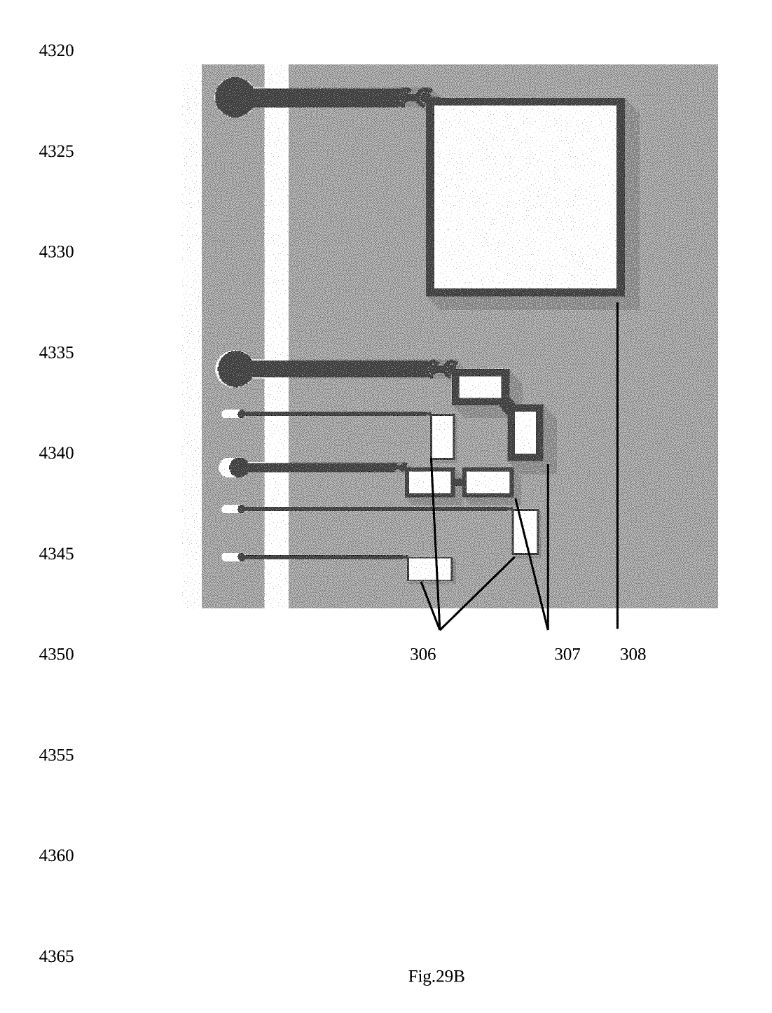

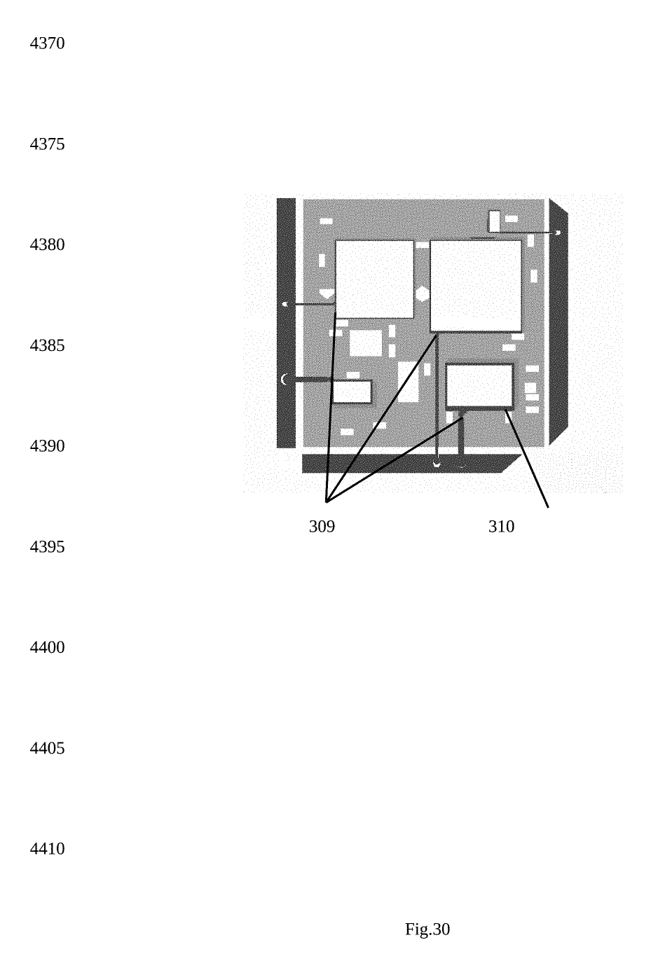

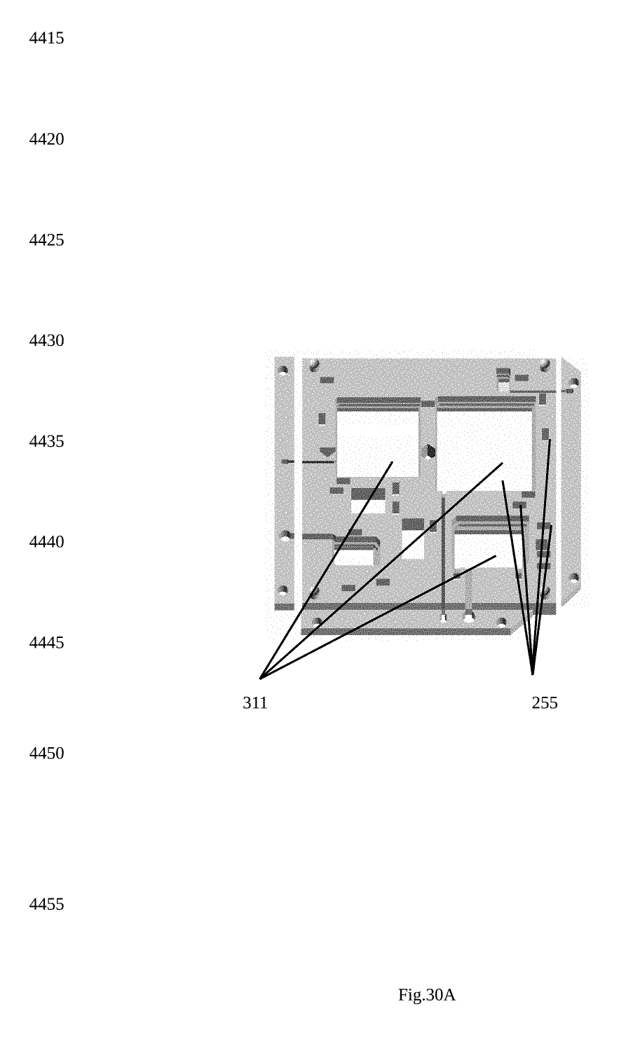

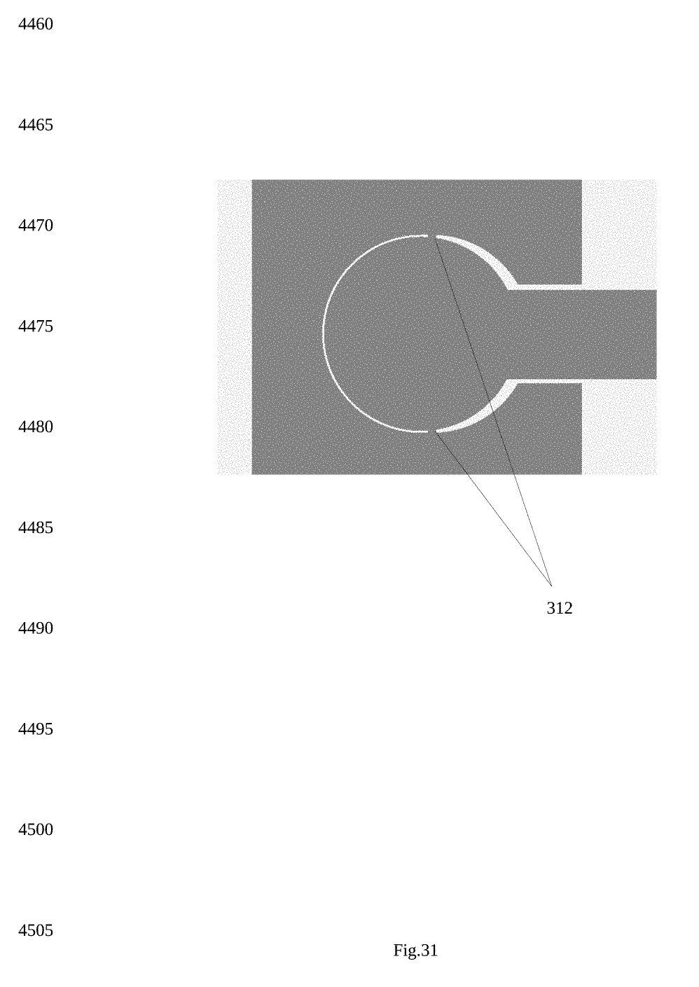

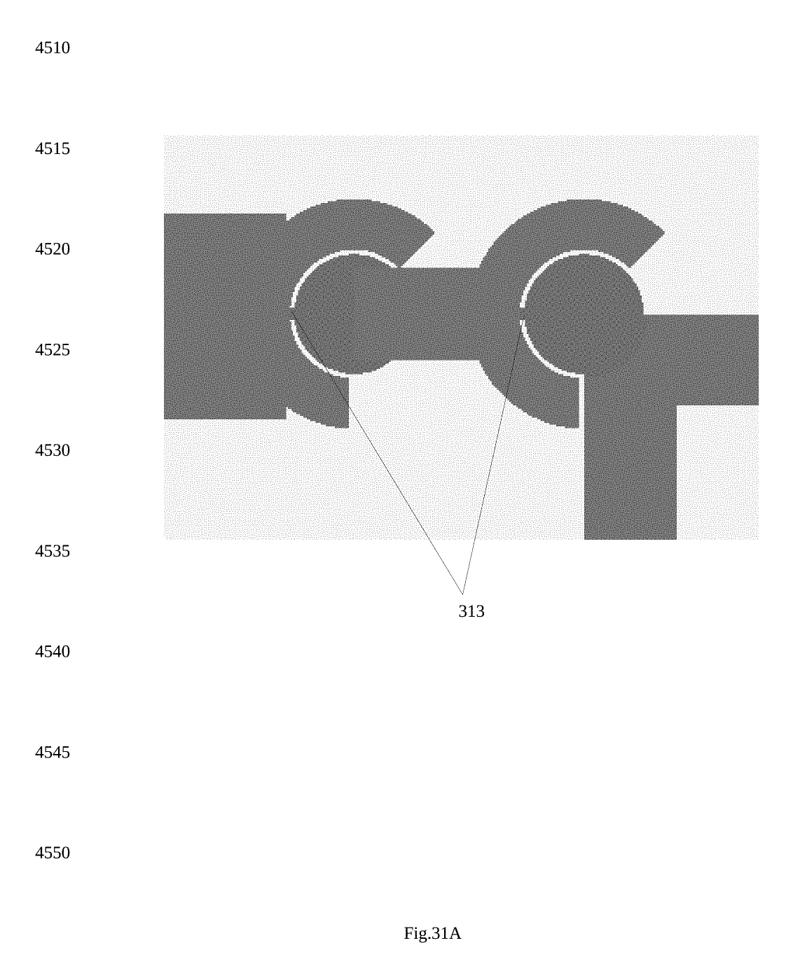

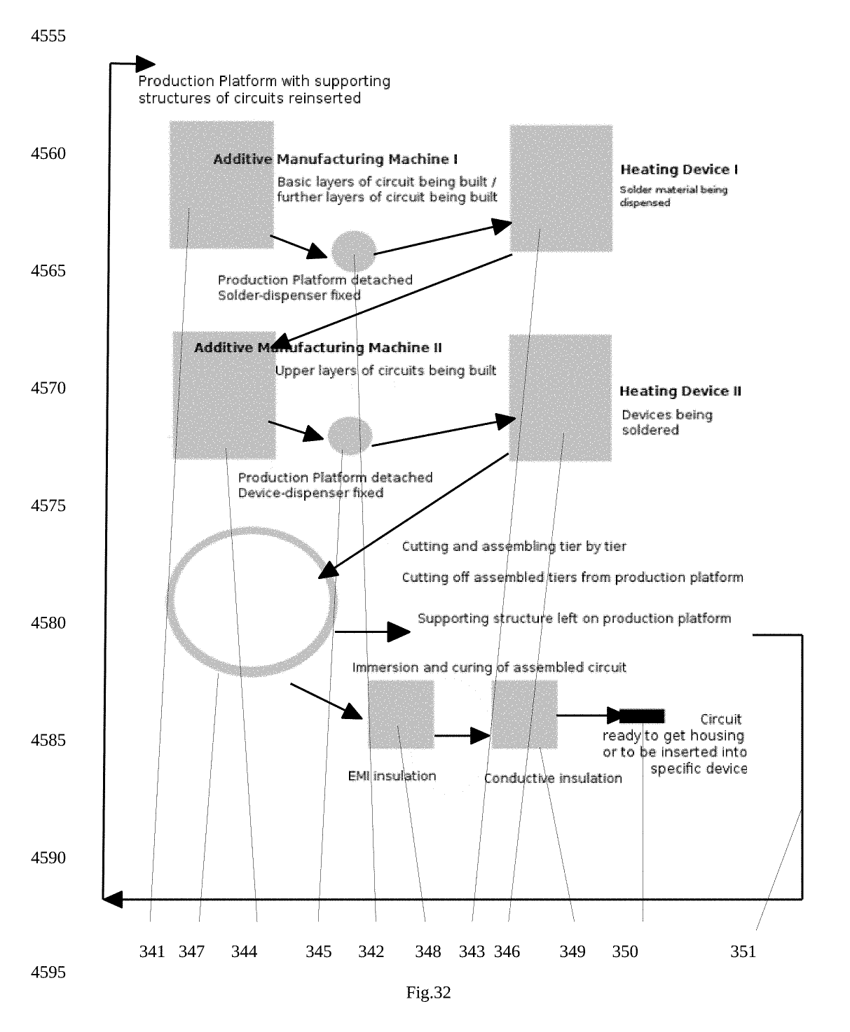

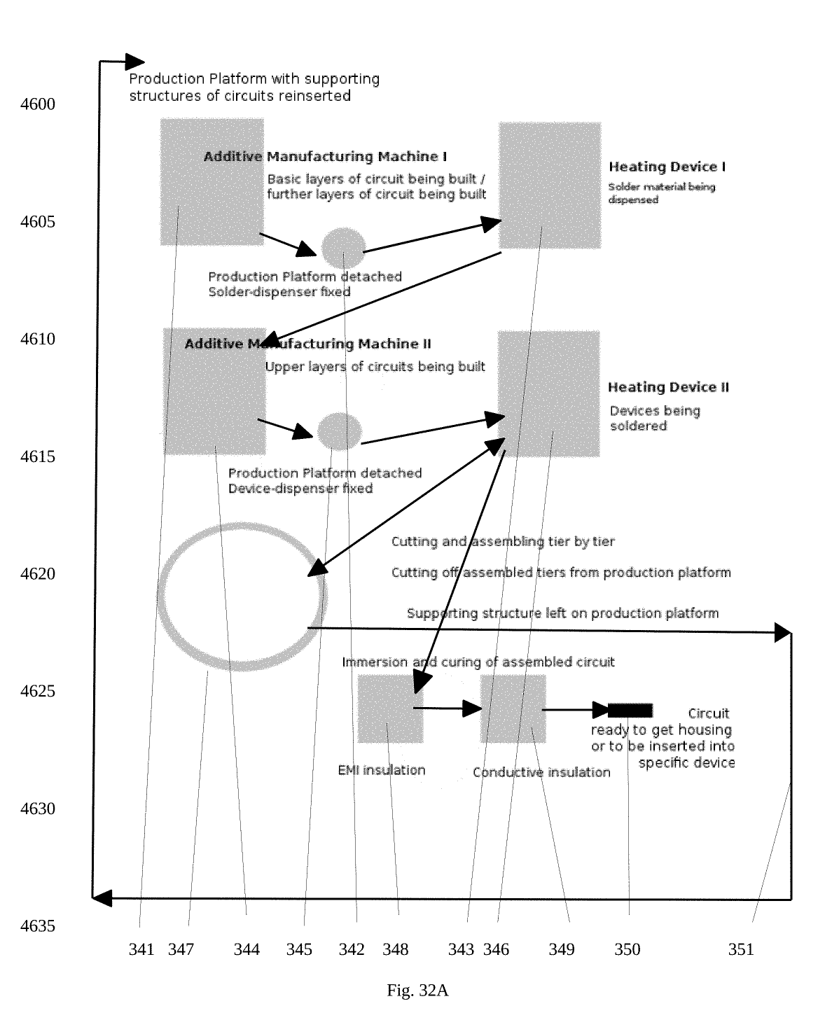

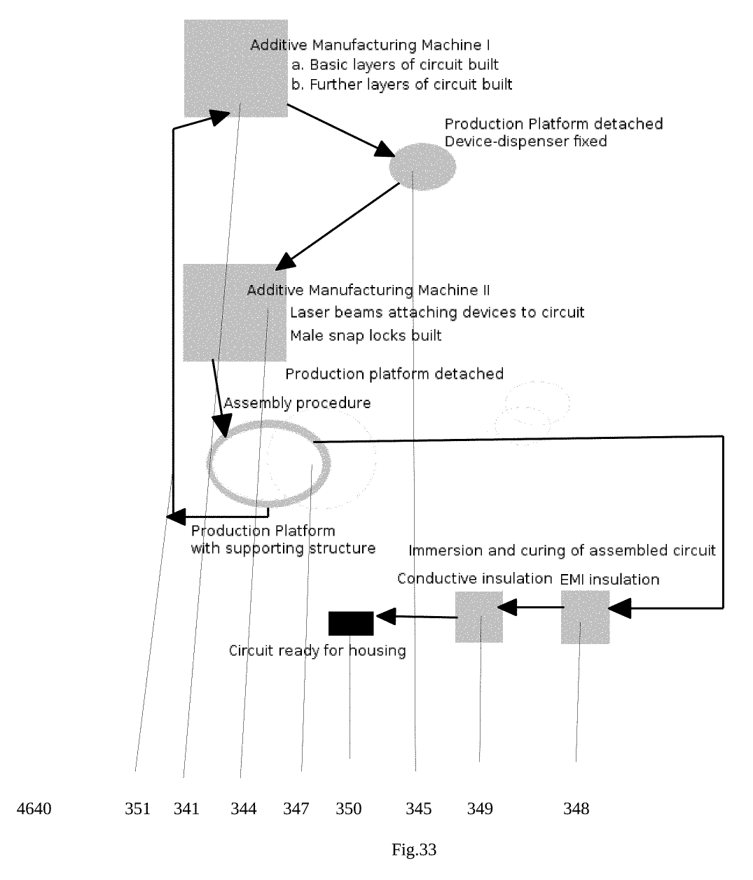

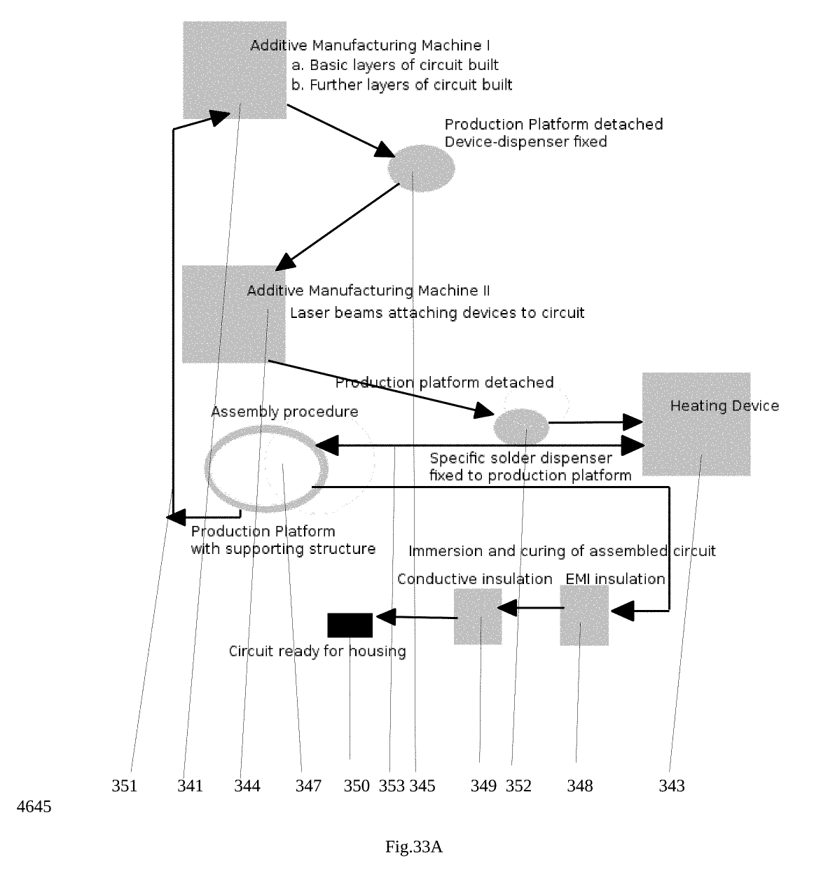

In this innovation the column of a production platform is divided in two, a lower part, the base column, FIG. 1, 103, and an upper part, the upper column, FIG. 2, 111. The upper part of the upper column, FIG. 1, 109, has a diameter slightly wider than the lower part of this upper column, 108. The base column is here cut out as a detail on its own, but it is to be understood as fixed in the manufacturing machine. The base column will have a diameter identical to the upper part of the upper column, but slightly bigger than said lower part of the upper column. Thus the unity of the upper column and the base column is a straight column, FIG. 3, 117, that can move in the manufacturing machine without hindrance.

The upper third of said base column will be hollow. Furthermore, it has opposing vertical slits, FIG. 1, 106, starting at the upper edge and reaching near to the end of the hollow part, where they will have right-angled bents, horizontal slits, 105, to continue a certain part of the circumference of the column. These horizontal slits have widenings, 104, close to their endings opposite the vertical slits.

Said upper column, FIG. 2, 111, has the production platform, as a prolongation at the upper end. At the lower end of the upper column it has two knobs, FIG. 1 and FIG. 2, 107.

The diameter of the upper part of the upper column being bigger than the diameter of the lower part of the upper column, this creates an edge, 113, that will rest on the rim of the base column when the assembled upper column is inserted into the base column.

FIG. 3 shows the upper column inserted into the base column; the knob now sits at the ending of the horizontal slit with a locking screw, 114, to the right. Once the reinsertion has taken place, locking screws are inserted into one or both widenings of the horizontal locking slits and the grooves for locking screws, FIG. 2, 112. At this stage, the lower part of the upper column is behind the widenings in the horizontal slits, aligned with the grooves for the locking screws in the lower part of the upper column.

There is an alignment mark, FIG. 3, 116, for the screw slit, 115. When inserting the screw, the screw slit and the alignment mark must be aligned, the screw then must be turned 360 degrees to end aligned to the mark.

To detach the production platform this or these screws must be unwound before the platform can be rotated horizontally, here in the counter-clockwise direction, to move the knobs to the vertical slits, where-after the platform can be lifted out of the production machine.

When reinserting the platform the knobs have to be fitted into the vertical slits, lowered to the end of these slits and here rotated horizontally clockwise. Last the screw(s) get inserted and turned to alignment.

### Alternative Embodiment, FIGS. 1, 1A

In one embodiment the production platform is fitted with an electro-magnet.

The upper column will be divided in two, FIGS. 1 and 1A, it will be hollow, and the hollow room will extend into the production platform, 101. This hollow space will house the electro-magnet.

The two parts of this upper column are both equipped with threads, FIGS. 1 and 1A, 102, to reassemble the column, once the electro-magnet has been put in place.

The magnet will have electrical connection wires extruding through the wall of the upper column, FIG. 1A, 110, at a point situated well above the level to which the upper column will be inserted into the base column on reassembling.

### Claims 1-2

### Abstract of the Disclosure

In the domain of additive manufacturing innovations are abundant. Many innovations concern the ability to build products with ever better resolution, reaching well into the realm of nano technology.

Adding the present innovation of detachable building platforms will move this development forward, both concerning products in nano sizes and products in the scale of airplanes.

### Background of the Invention

Demand has been growing for making conductive circuits ever smaller. This asks for novel design and production techniques as well as for answers to challenges concerning distortion, heat dissipation, decoupling, and EMI, among others.

Conductive circuits have hitherto been formed by using substrate of some kind to carry the conductive circuits, and components have been soldered to solder pads created on this substrate. Production of this type of traditional conductive printed circuit boards encompass an elaborate process with highly specialized and expensive machinery.

Development of the methods used in modern printed circuit boards started early in the 20th century. In 1903 a German inventor, Albert Hanson, described flat foil conductors laminated to an insulating board, in multiple layers. Thomas Edison experimented with chemical methods of plating conductors onto linen paper in 1904.

U.S. Pat. No. 2,990,310 to Richard Chan, 1961, is a patent of an invention that relates generally to a method of making electrical units and particularly to a method of making electrical circuits on laminated circuit boards.

U.S. Pat. No. 4,562,513 A to IBM, 1984, is a patent for a process for forming a high density solder pad and fan-out metallurgy system in a ceramic substrate wherein a pattern of indented lines is formed in the surface of a green ceramic substrate, the lines filled with a conductive metal paste, a layer of dielectric green ceramic material deposited over at least a portion of the area of the pattern of indented lines, and sintering the resultant substrate.

U.S. Pat. No. 8,263,874B2 to Toshihiro Hashimoto 2012 is a patent for a multilayer circuit board comprising low inductance through-conductors. The multilayer circuit board comprises first ceramic substrate means, first layered section, and second ceramic substrate means that allow insulation layers to be substantially thin, a length of through-conductors to be substantially short, and to have low relative permissibility of the insulation layers compared to resin insulation layers. Thus, increases in operation frequency of the multilayer circuit board are possible.

Substrate-based circuits have been standard in the industry, and to date the standard of electronic connections between layers consists of the above mentioned through-conductors, known as vias, vertical interconnect access. These take up quite some space horizontally. Each Printed Circuit manufacturer will have their standard, but hole and annular ring taken together easily reaches a diameter of 0.7 mm.

Hitherto it has not been possible to use layered manufacturing to directly fabricate miniature electronics packaging with true 3D structures. Available methods such as LTCC (low temperature co-fired ceramics) can only supply flat substrates where the electronic connections (vias) have to be placed perpendicular to the layers. This often makes it necessary to combine LTCC structures with other 3D-structures manufactured separately.

US20130170171 to Board Of Regents, the University Of Texas System, 2013, is a patent for a system and method for making a three-dimensional electronic, electro-magnetic or electromechanical component/device by: (1) creating one or more layers of a three-dimensional substrate by depositing a substrate material in a layer-by-layer fashion, wherein the substrate includes a plurality of interconnection cavities and component cavities; (2) filling the interconnection cavities with a conductive material; and (3) placing one or more components in the component cavities.

With this patent vias become obsolete, and the substrate is transformed to a body comprising components and connections.

As additive manufacturing procedures are becoming still more advanced recent development has made it possible to 3D print metal in an additive layer-by-layer fashion.

The machines typically used to print metal are Direct Metal Laser Sintering machines (DMLS) also called Selective Laser Melting machines (SLM), which use a powerful laser to sinter or melt a shape in a metal powder bed of fine powder or paste. The SLM is a method where a powder layer is distributed evenly on a surface and selectively melted by a laser beam in a layer-by-layer fashion. A new layer of material is added and the next layer is then sintered or melted.

Each machine manufacturing company has their own name for their technology and though different in some ways, they are all fundamentally sintering or melting very fine metal powders. In the original 3D printing invention (U.S. Pat. No. 6,146,567 to Massachusetts Institute Of Technology, 2000), the powder was applied on the surface by spraying a suspension. In a later invention the powder is spread in dry form to create a layer (WO03055628 to Urban Harrysson, 2003). The latter method is very fast but it is limited to coarser powders with approximately 10-20 μm particle size, that can be spread homogeneously in the dry state.

Micro Laser-Sintering (MLS) is a process in which particles that are 5 micrometer or less is utilized. These tiny particles, in conjunction with a laser spot diameter that is less than or equal to 30 micrometer, in theory make tiny prints possible.

### Known Problems

### Proper Decoupling

Anyone moderately skilled in the art of Integrated Circuits (ICs) knows why proper decoupling is necessary. Most ICs suffer performance degradation of some type by ripple and/or noise on the power supply pin. A digital IC will incur a reduction in its noise margin and a possible increase in clock jitter. For high performance ICs, such as microprocessors, the specified tolerance on the supply (+−5%, for example) includes the sum of the Direct Current error, ripple, and noise. The digital device will only meet specifications if this voltage remains within the tolerance.

The key aspects of proper decoupling are:

(a) a large electrolytic capacitor typically 10 uF-100 uF not more than 50 mm away from the chip. The purpose of this capacitor is to be a reservoir of charge to supply instantaneous requirements of the circuits locally so the charge need not come through the inductance of the power trace.

(b) smaller capacitors (typically 0.01 uF-0.1 uF) placed as physically close to the power pin of the chip as possible. The purpose of these capacitors is to short the high frequency noise away from the chip.

(c) all decoupling capacitors connected to a large area low impedance ground plane through a short vertical trace to minimize inductance.

### Distortion

When production processes comprise heating and cooling of material the possibility of differential distortion is always present.

### Cost Of Material

Present innovative method could with advantage be performed by using metal powder in additive manufacturing. The powders of particles less than 20 microns are relatively expensive on account of the processes involved in producing powder as fine as this.

Furthermore these powders are made of rather precious materials so it would be preferable to use the powder very economically.

### Tomb Stoning

A special problem of soldering tiny components is the risk of tomb-stoning, an unwanted effect in the manufacture of conductive circuits, in which a component stands on end instead of lying flat. Among the causes for this to happen is difference in volume of the surrounding circuit lines—if to one side of the component in question the circuit line is wider than to the other side the sheer volume of this wider line will amass more heat, at the same time heating up the neighboring solder pad, that will thus have a higher temperature than the solder pad at the other end of the component. The issue of tomb-stoning has risen to prominence because, while components and assemblies have become much smaller over the last decade, overall assembly processes have remained much the same.

### Misalignment

Another issue arising with the still smaller circuits and components is the risk of misalignment. With the innovative method being presented here, these issues are all being addressed as described in the following.

### Advantages

The following advantages are for one or more aspects of present innovative method.

### No Supporting Substrate

The most eye-catching advantage of these conductive circuits arises from the fact that no substrate is being used. There is no copper-clad board or any other type of supportive surface, and thus no board to take up space and also no costs for a board.

The stability of conductive circuits according to this method comes from the construction as such, with conductive lines and attached devices mutually stabilizing each other, and with female and male snap locks giving stability vertically.

### Simple Production Process

The production process for a conductive circuit of this method is simple.

It can be made in a few 3D printing processes, followed by solder material dispensation, a device-placing process, a soldering process, a process of cutting the tiers of the circuit off a production area, and an assembly process only concerned with stacking the individual tiers. The stacked unity of tiers then gets immersed and light-cured twice to get electrical insulation and EMI insulation.

One last process could eventually be to place the stacked unity in a housing.

### Further Miniaturization

This method for producing conductive circuits makes it possible to take further miniaturizing steps, a recent popular trend, that only seems to be growing ever stronger—there are no vias and there are minimal distance between conductive lines.

### Making Vias Obsolete

The conductive circuits created according to this method need no vias, and thus the size of such circuits is reduced. The conductive connections are created vertically between the tiers of circuits. Female snap-locks, accessible from beneath the conductive lines, are created within these lines at predetermined locations, and male snap-locks to connect to female snap-locks on tiers above are extruding vertically from the conductive lines at predetermined locations. These female and male snap-locks take up very little space horizontally. The female snap-locks are built-in in the conductive lines—the male snap-locks extrude from the lines with a horizontal extension that means that on the area of one via there is room for several snap-lock interconnections.

### Insulating Distance

The insulating distance between conductive lines on a substrate of course influences the size of the finished circuit. At least 0.15 mm is recommended as the distance between 2 conductive lines, for voltages as those used in the example of the preferred embodiment.

The method for 3D construction of conductive circuits presented here enables optimization of gaps between conductive lines. This distance is reduced to 0.1 mm. as both conductive insulation and EMI insulation is obtained by applying layers of fluid resin to be cured by ultraviolet light.

### Less Resistance, Less Amassing of Heat, Less Energy Needed

The resistance in conductive lines always demands some compromises between width of the lines and the overall space of a circuit. Different minimum widths of conductive lines are recommended by different Printed Circuit manufacturers, one typical width being 0.15 mm. The depths of conductive lines on substrate are typically 0.035 mm. The volume of a length of 1 mm in these dimensions is 0.00525 cubic mm.

The conductive lines suggested by the present innovative method typically have dimensions far exceeding these measures; in the preferred embodiment the conductive lines have a square profile of 0.2 mm times 0.25 mm. The volume of a length of 1 mm in these dimensions is 0.05 cubic mm—almost 10 times as much volume as conductive lines on substrate.

This has remarkable advantages—less resistance to conductivity, creation of much less heat, and use of much less energy to transfer a certain amount of data than would be the case in a circuit on substrate with standard measures.

### Heat Dissipation

Other advantages of this innovative method is built-in heat dissipation. Heat is a problem that intensifies with miniaturizing; it comes close to an inversely proportional relation. In circuits created according to this method air can circulate freely between the electrically insulated horizontal and vertical conductive circuits, thus highly reducing the amassing of heat.

### No Differential Distortion

This innovative method comprises a solution countering the risk of differential distortion by creating supporting structures designed to withstand such distortion.

The results of the building process can be divided into three distinct parts: Supporting structures, FIG. 4, 120 and 123, cutting structures, 121 and 124, and conductive lines with solder pad boxes, 122 and 125.

In our preferred embodiment a supporting structure outline, 120, 123, of the circuit is built to a certain height on the building platform of an additive manufacturing machine. A hollow cutting structure, 121, 124, following the same outline, is built on top of this supporting structure.

During the layer-by-layer building we make use of the fact that these hollow parts get filled up with powder that will act as a stabilizing agent, and will help to maintain the form and reduce differential distortion as building of conductive lines and solder pad boxes, 122, 125, continues on top of the hollow cutting structures.

Being hollow, the cutting structures, 121 and 124, FIG. 4, 146 FIG. 7 and 147 and 148 FIG. 7A, are created with use of a minimum of material, thus reducing the use of the conductive material and also making it easier to cut through at the desired level once the assembling of circuit tiers and devices is accomplished.

### Anti Tomb-Stoning

The tomb-stoning issue is overcome in this innovative method, as the solder pad boxes of any one device will contain exactly the same amount of solder material. They will furthermore have identical guides. These features ensure identical volumes of metal on all sides of any one device, amassing the same amount of heat and so heating up the solder material to the same level, whereby a device will attach in equal degree, and horizontally, to its solder pad boxes.

### Countering Misalignment

Another issue arising with the still smaller circuits and components is the risk of misalignment. Present innovative method has different characteristics addressing this issue.

Concerning possible misalignment of devices the guides of the solder pad boxes nudge the devices to the right positions.

Concerning possible relative misalignment between tiers male and female snap-locks ensure that the tiers align, one with respect to the others. At specific coordinates female snap-locks are placed within the horizontal conductive lines, and at corresponding specific coordinates male snap-locks are extruding from said lines to different heights. When tiers are stacked upon each other these locks make the tiers fit exactly and lock firmly together. The construction of the female snap-locks allows even for soldering together the female and male snap-locks.

Also such soldered inter-tier connections further stabilizes the unity of tiers, which might be of importance in embodiments without housing, for instance.

### Diminishing Noise

The dedicated tiers of ground and of power, and regions on ground tier of digital ground and analog ground, and regions on power tier of 3.3 volt and 1.8 volt help diminish noise in the weak analog signals from external sensors.

### Proper Decoupling

Furthermore the key aspects of proper decoupling can easily be met with circuits made in accordance with this innovative method. In the example of our preferred embodiment

(a) a large electrolytic capacitor is placed not more than 5 mm away from micro-controllers,

(b) smaller capacitors are placed close to the power pin of micro-controllers,

(c) all decoupling capacitors are connected to a large area low impedance ground plane through a

short vertical connection to minimize inductance.

No distance in the circuits of the preferred embodiment is more than 10 mm at the most.

### Accurate Device Placing

As all tiers of our preferred embodiment are built next to each other at the same time on the same building platform, FIG. 5, each tier kept as a unit by the anti-distortion cutting structures, the device-placing function can operate unhindered on all the tiers that are thereby accessible directly.

### Economical Aspects and Additive Manufacturing

The innovative method here presented is economical in several aspects. One thing is that the production procedure is simple relative to hitherto used procedures, and so takes less time and less equipment. The production being additive, contrary to the reductive procedures mostly used in connection with production of conductive circuits, means that material is used sparingly.

### Re-Use

Furthermore the supporting structures, that stay on the production platform after one circuit is finished, will be reused as supporting structures for the next productions as long as the design of the circuits being produced are identical. The supporting structures are only built one time for any design, no matter how big the production volume, resulting in less waste.

### Brief Summary of the Invention

A method for establishing conductive circuits on their own, consisting only of the conductive lines, with intermediary devices on tiers on top of each other.

The preferred embodiment of this innovative method has circuits in tiers on top of each other, ground and power on each their tier furthest down, and one or a plurality of tiers carrying components on top of these two.

The conductive lines have solder pad boxes to contain solder material, and they have female and male snap-locks to vertically interconnect the tiers both physically and conductively. The solder pad boxes have guides at the edges to guide solder material and devices.

This method includes insulation to counter EMI and electrical insulation. This is obtained by immersing the final unity in liquids and curing these by ultraviolet light.

The final product is an insulated circuit in several interconnected tiers with devices between the tiers.

### Detailed Description of the Invention

### Preferred Embodiment, FIGS. 4-13

The multi-tier conductive circuits of this method comprise conductive lines, FIG. 4, 122, solder pad boxes, 125, guides, 127 and 128, female snap-locks, 126, and male snap-locks, 129.

In our preferred embodiment the circuits are made of conductive material, making use of additive manufacturing.

This embodiment is by way of example equipped with devices for an ECG-monitor as of 2013, that can analyze incoming analog signals and communicate via Blue-tooth Low Energy.

The extension of this embodiment is 18 mm times 18 mm and the height is 7.4 mm.

The conductive lines are arranged to supply power and data to devices, to connect devices to power and to ground and to interconnect devices. The conductive lines are equipped with solder pad boxes, open boxes to be filled eventually with solder material, on locations where devices will be soldered. The solder pad boxes are sized and placed according to the footprints of the devices to be soldered.

On the solder pad boxes are guides with two purposes: securing correct application of solder material to the solder pad boxes, and securing accurate positioning of devices to be soldered on the solder pad boxes.

For the preferred embodiment the circuit consists of 5 tiers, of an identical square design, FIG. 5, each 18 mm times 18 mm: ground tier, 132, power tier, 133, tier for analog front end, 131, tier for Blue-tooth Low Energy sender and a micro-controller for analysis of incoming signals from sensors, 130, and tier with Blue-tooth antenna and for connector, 134. The tiers are built next to each other on a production platform of an additive manufacturing machine, FIGS. 6 and 6A, 145, and they are stacked to one unity at the end of production.

FIG. 5A shows the same 5 tiers after devices have been placed. 141 is the tier for the Blue-tooth Low Energy sender, 142 is the tier with the analog front end and 143 is the antenna tier.

On both FIG. 5 and FIG. 5A the reference numbers 135 and 136 are pointing at two types of location columns, that are needed for procedures for solder dispensing and device dispensing.

In the finished unity connections between the tiers are obtained with the female snap-locks, 126 and the male snap-locks, 129 (FIG. 4).

The female snap-locks are embedded in the conductive lines, accessible from the underside of the lines, the male snap-locks extrude perpendicularly from the upper side of the lines. Thus a male snap-lock will connect to a female snap-lock on a tier above and create a conductive connection between the two conductive lines involved. The female snap-locks have an inner cylinder, FIG. 10, 157, and an outer cylinder, 159, to make room at locking for momentary expansion within the female snap lock. The inner wall have slits, 158, to ensure that the crown of the male snap-lock, 162 (FIG. 10B), can connect properly inside the female snap-lock. As seen in FIG. 10A, the female snap-locks furthermore have constructions, 160, 161, that make it possible to strengthen the connections by soldering.

### Production Procedures Adapted to This Method

In order to produce the conductive circuits of this innovative method supporting structures are created, 120 and 123 (FIG. 4), and on these supporting structures cutting structures are constructed, 121 and 124. On top of the cutting structures the conductive circuits and solder pad boxes will be built, 122 and 125.

A 3D printed product needs to be cut or broken loose from the production platform. In this innovative method we turn this condition into an advantage—the supporting structures will be re-used.

When all production processes are finished, when the solder material has been dispensed and the devices have been placed and soldered, a cutting procedure starts. In the preferred embodiment it is a cut disc of type Keystone-034-1900300 Cut-Off Discs 38×0.7 mm, pure aluminum oxide, that is used, FIGS. 6 and 6A, 144.

As the name indicates, the cutting structures are where the cutting loose will take place, FIGS. 6 and 6A, 121. The height of the cutting structures is decided according to the cut disc chosen. In the preferred embodiment the height of the cutting structures is 0.8 mm, the cut disc being 0.7 mm.

In the cutting procedure the cutting structures, 121 (FIGS. 4 and 6) are reduced to powder, while the supporting structures, 120 (FIG. 4), will be left intact on the production platform, and the conductive circuits, 122, and solder pad boxes with devices will be free. The downwards openings of the female snap-locks in the conductive lines will be accessible after the cutting procedure. In this way the connections can be made between female snap-locks and male snap-locks when stacking of the tiers starts.

One tier at a time will be cut loose. At first, the tier with analog front end gets cut loose, to be stacked on top of the power tier. The procedure continues with cutting off of the tier carrying the Blue-tooth Low Energy sender and the analyzing micro-controller. This tier will be stacked on top of the tier with analog front end, already stacked on the power tier.

Thereafter the power tier, now carrying both the analog front end tier and the Blue-tooth Low Energy tier, is cut loose, and stacked on top of the ground tier. Last the antenna tier gets cut loose and stacked on top of the Blue-tooth Low Energy tier, as the last in the order. FIG. 8, 149 shows the 4 tiers stacked on top the ground tier. When the stacking has been accomplished the ground tier gets cut loose, FIG. 8A. This figure is a side-view of the 5 tiers stacked: 150 is the ground tier, 151 the power tier, 152 the tier with analog front end, 153 the tier with Blue-tooth Low Energy sender and 154 is the antenna tier. As it can bee seen the tiers are rather densely packed—the snap-locks are designed to accomplish that.

As the stack of tiers, now including devices, is cut loose from the production platform, the next procedure is to immerse the stack in a bath of EMI insulating material, take it up again and light-cure the layer of EMI insulation. This procedure will be repeated to obtain insulation to prevent unintended conduction.

The cutting structures have several designs, all devised in order to make cutting as easy as possible and to save material. Cutting structures for conductive lines have oval cavities running lengthwise inside the entire length of a line. In FIG. 7 cutting structures of conductive lines are cut through to show these cavities, 146. Cutting structures for solder pad boxes have cavities of ovals both lengthwise and across, 147 and 148, FIG. 7A.

### Horizontal and Vertical Unities

As described, the tier with analog front end gets cut loose as the first tier, to be stacked on top of the power tier.

This procedure underlines another feature of this innovative method. The circuit of conductive lines, not having any supporting features in the final product, must have another unity not to disintegrate. In FIG. 9 the conductive lines of the tier for the analog front end can be seen, 155, with their solder pad boxes, guides, female snap-locks and male snap-locks. What can be seen as well is that the circuit is actually a discontinued circuit; the lines form minor entities that do not unite. Reference number 156, (FIG. 9A) is the same tier with the devices soldered, and at this stage the tier is a horizontal unity, a proper circuit. The discontinuities that appear at first glance are either points where female snap locks, 126, FIG. 9, receive a connection from below, or male snap locks, 129, FIG. 9, connect upwards.

For the power tier the situation is different. There are no devices to be soldered, and there are two areas on this tier, one to supply 3.3 +volts and one to supply 1.8 +volts.

This means, that the power tier comes in two sections, FIG. 12—one with 3.3 +volts, 168, and one with 1.8 +volts, 169. Consequently, this tier is not a unity horizontally, and it needs to have unity-creating connections vertically. Thus the tier with analog front end in the stage where the devices have been soldered, 156, FIG. 9A, must be stacked on top of the power tier to make a unity. Eleven male snap-locks, 170 (FIG. 12), will snap into female snap-locks of the tier with analog front end and make a unity of the 3.3 +volts power area with the analog front end tier. The 1.8 +volts power area only has connections to the tier with the Blue-tooth Low energy sender and the analyzing micro-controller. Consequently this tier, including its devices, has to be stacked on top of the analog front end tier, that is on top of the power tier, before the six male snap-locks from the 1.8 +volts power area, 171 (FIG. 12), snap into female snap-locks to make a unity and connect.

The ground tier is a proper circuit although as it has no devices either—the digital ground area has a bridge to the analog ground area, as is the proper way the two areas should interrelate.

Thus the individual tiers of the circuit get their horizontal unity once the devices are in place. The vertical unity between the tiers is established by the stacking of tiers.

Once the unity of stacked tiers is fitted into a housing there must be connecting points from the outside for sensors and for power, and in this embodiment of the method these connecting points will be at the bottom of the housing, and concern the ground tier.

However, neither sensor signals nor power can connect to the circuits of the ground tier. Instead they are connecting to each their island, independent of the ground tier circuits. Consequently, the vertical unity-creating solution that is used for the power tier comes into play for the ground tier islands. The five sensor connection islands have female snap-locks within, 164 (FIG. 11), and male snap-locks, 166 (FIG. 11A), extruding vertically to the height of the analog front end tier.

The same is true for the battery connection island, 165 (FIG. 11). It has a female snap-lock within, and a male snap-lock, 167 (FIG. 11A), connecting to the analog front end tier.

During the very first production process, the procedure is as described above. But as the supporting structures, 120 and 123, FIG. 8, are left on the production platform, they do not have to be built again as long as the same design is being produced.

The cutting structures, and thereafter the conductive lines and solder pad boxes, will be built directly on top of the existing supporting structures, saving both production time and material.

All solder pad boxes have guides, 127 (FIG. 4), and even some conductive lines have guides, 128. These are sized according to the devices they should guide to correct position on their solder pad boxes. Where guides are placed on conductive lines it concerns big devices with footprints underneath that do not reach to the short side of the device. Instead guides are placed on conductive lines where the short sides of the device touch down, 128.

Apart from the guides assisting in the process of getting solder material dispensed to the exact destination, there is also another function of the guides, as they contribute to the fact that there is the same amount of metal on all sides of a solder pad box. This is of importance in order for the devices to solder horizontally, attaching in equal degrees to all their solder pad boxes. The result if this does not happen easily resembles so called tomb-stoning, where a device ends up standing more or less on an edge, and thus not connecting properly to the circuit.

### First Alternative Embodiment, FIG. 13.

The alternative embodiment concerns surface quality of the conductive lines as well as the application of solder material to the solder pad boxes of the preferred embodiment. For this alternative embodiment the means of production is an additive manufacturing machine, providing laser beams for sintering or melting fine metal particles.

This additive manufacturing machine is equipped with the here presented removable production platform, wherein an electro-magnet is inserted.

Electro-magnetic force is added to the weak fundamental gravity force of the small powder particles of electrically conductive and magnetic material, such as nickel, that is used.

This added magnetic force, combined with a vibration of the building platform, accomplished by turning the magnet on and off in quick successions, thereby creating ultrasonic vibrations, results in an even distribution and denser packing of the particles, remarkably enhancing both the surface quality and the density in the built structures.

This combination of forces—attractive magnetic forces and vibration—or the single use of either of them, counteract van der Waals forces, that by making the particles agglomerate and by giving them reduced fluidity have until now made it difficult to obtain the technical parameters necessary for producing details as fine as needed in further miniaturizing of conductive circuits.

The building material for the circuit is powder with a diameter of 40 micrometers, μm, on average.

When the height of the horizontal lines and solder pad boxes has been reached, the building platform will be emptied of this micro-particle powder, and another nickel alloy with particle sizes less than 5 μm, nano-particles, will be dispensed over the building area. The electro-magnet again has the effect of packing the particles more densely, 173, as compared to 172 (FIG. 13). On the predetermined coordinates of the solder pad boxes the nano-particles will be melted by a laser beam with much smaller effect than used for the coarser micro-particle material, thereby making a melted pool of the smaller particles, while leaving the coarser 40 μm particles intact, 174 (FIG. 13).

As the coarser particles have lower molecular weight than the pool of melted nano-particles they will be carried to the top of the melted pool as the level of this melted pool rises, and pushed out—a functional ‘cuckoo-nest effect’—as the volume of the specific solder pad box gets filled up. Building with the smaller particles and melting these particles will continue until the solder pad boxes are filled up with melted nano-particle material.

Thereafter building with the coarser particle material continues, to create the guides and the extruding male snap-locks.

The choice of material for filling the solder pad boxes for this alternative embodiment is made with regard to obtaining a lead-free material that will match high performance standards.

Material of nano-particles have the promising quality of a low melting temperature, and the innovative procedure of applying magnetic forces when using powder of electrically conductive and magnetic materials is an efficient way to come round the challenges of van der Waals forces posed by material of such small particles.

In this alternative embodiment the procedure of adding solder material to the solder pad boxes is as described accomplished during the additive manufacturing procedure. This means that the production of circuits gets to be even simpler. The circuits are ready to have devices placed directly after leaving the additive manufacturing machine.

Furthermore, when the devices are on their destinations the attaching of the devices to the nano particle filled solder pad boxes can also be performed by the laser beams of the additive manufacturing machine.

### Second Alternative Embodiment

In this embodiment the solder pad boxes are made solid, which means that they will consist of the same material as the conductive lines. To attach the devices to such solder pad boxes the laser beams are being utilized the same way as in the first alternative embodiment.

This procedure will take place in the second building session, which means that the production platform has been detached in order to get devices dispensed to the circuit, where-after the production platform is re-inserted into the additive manufacturing machine to have the devices attached to their solder pad boxes.

The dispensing of solder material, that took place in the preferred embodiment by the solder-dispenser being fixed on the production platform and the platform afterwards being transferred into a heating device, has become obsolete. This is also the case for the second transferring of the production platform to a heating device; this second heating device was where the devices got soldered to the circuit, which is now happening in an additive manufacturing machine.

### Software

The software of this innovative method has a graphical user interface, written in C++, that takes into account all relevant design rules, and uses the CGAL and openGL libraries.

The input are gerber files. In the end the software produces STL files. These can be loaded into any suitable additive manufacturing machine and the described circuits of ‘Detailed Description’ will be produced ready to be assembled and put into their housing after eventually having had solder paste applied and after having devices dispensed.

### Claims 3-10

### Abstract of the Disclosure

The present method describe establishing of circuits that can have solder material dispensed in several ways, and they can have devices dispensed by traditional pick-n-place machines, but at the same time these new types of circuits invite to innovations in the areas of solder dispensation and device dispensation.

The circuits of this method are made using additive technologies, employing limited amounts of materials. Likewise, the production process is simple in comparison with production processes for substrate supported Printed Circuit Boards.

Furthermore added flexibility are obtained with this new type of circuits, and the limits for miniaturization have been pushed forward.

### Recent Development

Additive manufacturing technology keeps developing.

“Laser-assisted direct ink writing of planar and 3D metal architectures” is the headline of a paper by Mark A. Skylar-Scott, Suman Gunasekaran, and Jennifer A. Lewis of Harvard University, the John A. Paulson School of Engineering and Applied Sciences, and the Wyss Institute for Biologically Inspired Engineering.

On the 18^{th} of May 2016 the site DIGITAL TRENDS had an article with the headline “This 3D printer builds circuits out of silver nanoparticles while floating in midair” about this research-paper.

The researchers write about the significance of their project:

The growing demand for customized electronic devices underpins the need for 3D fabrication methods that enable form factors well beyond those that are flat and rigid. A printing method is introduced for one-step fabrication of conductive and ductile metal features in planar and complex 3D shapes that combines direct ink writing with “on-the-fly” laser annealing.”

With an additive manufacturing machine working according to the method developed by the researchers of Harvard University the method of multi-tier conductive circuits described in detail above finds its optimal manufacturing environment. Such a machine will provide the material and the architecture needed for this invention and it will furthermore accommodate the particle dimensions needed.

From the opposite perspective the multi-tier conductive circuits would take advantage of this new type of additive manufacturing machine in a spectacular way, highlighting its advantages.

### Background

Only once automation and miniaturization in production of electrical devices got started did the need for other methods than manual methods of applying solder material to conductive circuits arise.

With patent U.S. Pat. No. 3,152,388A to Norman Grossman of Litton Industries Inc, priority date 1958, Mar. 3, the solder mask was introduced. In various materials it is still to a high degree the state of the art for preparing PCBs to have devices mounted.

It works on a solid, preferably horizontal, surface.

### Known Problems

The multi-tier conductive circuits free of supporting substrate with intermediary devices soldered on a plurality of tiers, however, have no solid surface and must have another type of solder-dispensing, adapted to this type of circuit.

### Advantages

The solder-dispensers of this innovation are made by additive manufacturing, and they are conceived for use in additively manufactured multi-tier conductive circuits free of supporting substrate with intermediary devices soldered on a plurality of tiers. For each new circuit design a new set of solder-dispensers of this innovation is created using the very design of the circuit in question.

In the solder-dispensers of this innovation no other forces are at work than the gravitational force, and all solder pad boxes of a conductive circuit free of supporting substrate will be filled in one procedure.

The solder material is delivered directly to the designated coordinates, and in volumes exactly calculated to fit the volume of the solder pad boxes in question.

### Summary

To fit the multi-tier conductive circuits free of supporting substrate this innovation presents a solution for specifically applying solder material to this type of circuits.

These solder-dispensers are additively manufactured, according to the specific circuit design for which the specific solder-dispensers are intended.

Once the building platform of the additive manufacturing machine has been detached from the machine, as described in the presentation above of the Production Platform for Additive Manufacturing Machines, it is moved to a working surface or a belt, and thereafter to a heating device. The solder-dispensers will be fitted into designated location columns of the circuit design, and the total amount of solder material for all the circuit will be placed in a receptacle on the upper level of the solder dispensers, to be let out, once the melting temperature for this material has been reached. The solder material will flow down pipes from the top-level solder-dispenser to lower-level solder-dispensers, and from the lower-level solder-dispensers down pipes directly to the designated solder pad boxes of the conductive circuits free of supporting substrate.

### Detailed Description of the Invention

Conductive circuits need solder material to be dispensed in preparation for having devices soldered. This innovation proposes a specific unity of solder-dispensers for the purpose of dispensing solder material to conductive circuits made according to the method for establishing multi-tier conductive circuits free of supporting substrate with intermediary devices soldered on a plurality of tiers. The solder-dispensers are produced to accurately fit the design of the circuit in question. They can be made of any suitable material in an additive manufacturing machine, and they are during production fitted with supporting structures and cutting structures as are the multi-tier conductive circuits.

For production of quantities of conductive circuits of a specific design it might be preferable to cast present solder-dispensers in a mold.

The preferred embodiment presented for the multi-tier conductive circuits is the design for which the solder-dispensers as way of exemplification are adapted in this description. This exemplification is not meant to limit the scope of this innovation.

The solder-dispensers of this exemplification comprise 2 units of dispensers. A top-level solder-dispenser, 200 (FIG. 14), to contain the solder material to be used for all solder pad boxes throughout the device-containing tiers of the conductive circuit in question. And a lower level of solder-dispensers, 201, that will receive this solder material initially—for further distribution. The solder-dispensers of the top level and the lower level have a basic design in common. It is a container with a vertical wall, 204 (FIG. 15), openings of different diameters, 214 (FIG. 15B), along the inside of this wall. The openings are situated in the slope, 205 (FIG. 15), that from a central horizontal platform, 206, inclines at a certain angle towards the wall.

Common for the top-level solder-dispenser and the lower-level solder-dispensers is furthermore a supporting pillar, 208 (FIG. 15). The supporting pillar is part of the solder-dispenser as such. It underlines the central horizontal platform, 206, FIG. 15, and has a form like an umbrella, 225 (FIG. 18), that ends in a handle. Two parts work together as foundations for the solder-dispensers, the supporting pillars and the location columns, 216 (FIGS. 16 and 20) and 231 (FIG. 20).

The lower parts of these foundations, the location columns, are built in the surroundings of the conductive circuit, 202 (FIG. 14) on the building platform, 203.

The top-level solder-dispenser has unique features.

The shape of the top-level solder-dispenser is dictated by the circuit to which the given solder-dispensers are adapted.

The shape of the top-level solder-dispenser is here dictated by the fact, that in the basic design of the exemplary multi-tier circuits two of the five parts being produced at the same time on the building platform, are not going to contain devices, and do not need solder material, as can be seen in FIG. 14.

The shape of the top-level solder-dispenser is thus three quarters, 270 degrees, of a circle, and this shape concerns every part of the top-level solder-dispenser.

The top-level solder-dispenser has a solder container centrally on the horizontal platform, 207 (FIG. 15). This solder container has oval, or eventually round, openings all along its wall, and these can be closed, 210 (FIG. 15), or open, 213, FIG. 15A. Reference number 209, (FIG. 15), is a solder container handle with which to regulate the position of closed or open.

The supporting pillar of the top-level solder-dispenser is also only 270 degrees of a circle, which gives a v-profile to the handle of the supporting pillar, 215 (FIG. 16). To accommodate to that the location column of the top-level solder-dispenser has an opening that corresponds to this v-profile, 216.

Lower-level solder-dispensers are constructed to apply solder material to the solder pad boxes of one device with several legs, such as micro-controllers, 222 (FIG. 17A), or to apply solder material to the solder pad boxes of several neighboring devices, 223. In FIG. 19, reference number 228 shows pipes for a device with several legs and thus several identical and closely placed solder pad boxes, and reference number 230 shows pipes for solder pad boxes for a plurality of devices.

Bridges are constructed between the lower-level individual solder-dispensers of a tier, 221 (FIG. 17), to make the solder-dispensers of this tier a unity, and other bridges, 217, are constructed between the solder-dispensers of one tier and solder-dispensers of neighbor tiers. In this way the lower-level solder-dispensers become one unity, as seen in FIG. 17A, that can be handled as such.

The lower-level bridges and solder-dispensers are provided with a plurality of supporting pillars, 220 (FIG. 17) and 226 (FIG. 18), to stand on the building platform while the dispensation of solder material takes place. They end in pointed handles of a length that makes the supporting pillars stand on the building platform, while the pipes of the solder-dispensers end at the level of the solder pad boxes, 229 (FIG. 19), to let solder material flow into the solder pad boxes and fill them up.

Solder pad boxes of a circuit according to the multi-tier method are supplied with guides, 227 950 (FIG. 19). These further ensure that the individual pipes of the solder-dispensers align correctly to the designated solder pad boxes.

The lower-level solder-dispensers have location columns of their own, 231, FIG. 20. These are built on the building platform, as is also the top-level location column.

The handles of the supporting pillars of the lower-level solder dispensers and bridges being of a circular design there are two location columns in order to properly locate the lower-level solder dispenser unit.

The only force at work in these solder-dispensers is gravity.

The radius of the openings of the pipes, 214 (FIG. 15B) and 224 (FIG. 17A), are calculated as functions of the volume of the solder pad box to be filled by the individual pipe and of the distance from the opening in the solder-dispenser to the end of the pipe.

The openings at the end of pipes are adapted to the size of the solder pad box to be filled, 218, and 219 FIG. 17.

Furthermore, the length of one pipe in relation to the length of an average pipe goes into a calculation of the amount of solder material adhering to the inner walls of the pipe during solder material dispensation. These calculations also influence the size of the opening of a pipe at the solder pad box, and of the dimensions of the individual pipe at outset in the solder-dispenser.

For the top-level solder-dispenser it is the sizes of the lower level solder-dispenser the individual opening and pipe connects to, that decides dimensions for the opening in the solder-dispenser and the dimensions of the pipe. The sizes of lower-level solder-dispensers, to supply solder material to solder pad boxes, vary to such a degree, that some will get solder material from the top-level solder-dispenser from only one pipe, 212 (FIG. 15), and others will be filled up by a plurality of pipes, 211.

When the solder material is in a solid state and has been placed in the solder container of the top-level solder-dispenser, and the container-handle of the solder container has been moved to put the solder container in a closed position, the building platform as such, with all the tiers of conductive circuits and the two levels of solder-dispensers, is placed in a heating device. Once the heating device reaches the temperature for making solid solder material liquid, the solder container will be put in the open position and the solder material will on its own flow through the openings of the solder container and down from the top-level solder-dispenser to the lower-level solder-dispensers, and from the individual lower-level solder-dispenser to the designated solder pad boxes. This will happen for all solder pad boxes on all tiers at the same time.

### Claims 11-13

### Abstract of the Disclosure

Presented here are solder-dispensers to apply solder material to multi-tier conductive circuits, with all tiers being built at the same time on a production platform. It is intended for circuits of this type built in non-magnetic material, and thus in need of solder material after building. The solder-dispensers are designed to supply solder material to the totality of solder pad boxes of the circuit, all at once and in this procedure making use of the gravitational force alone.

### Background

### Prior Art

The need for automated pick-n-place capacity origins in mass-production of personal portable electronic devices, such as mobile phones.

Surface-mount technology was developed in the 1960s and became widely used in the late 1980s, as capacity for automatically mounting electronic components was developed.

With a priority date in 1979 Matsushita Electric Industrial Co. Ltd, holds a patent for ‘Apparatus for mounting electronic components’, U.S. Pat. No. 4,346,514A. It is an apparatus for mounting electronic components on an accurate position of a printed board substrate.

‘Automatic mounting device for special components’ is the title of a patent to Siemens Aktiengesellchaft, EP0181556 A1, with priority date in 1984. This patent introduces an industrial robot into a pick and place machine.

The state of the art pick-n-place machines are adapted to placing devices on surfaces. They function with robotic arms, and although there can be a multitude of these arms each of them is still placing one device at a time.

### Advantages

The device-dispenser here presented is adapted to the type of multi-tier conductive circuits presented above, and it takes advantage of the detachable building platform for additive manufacturing machines likewise presented above.

However, the design can be adapted to a broad range of conductive circuits. And an overall advantage of this innovation is that it places all devices on a whole circuit at once. Furthermore it can contain devices for 100 circuits or more of any design at a time. The number of circuits that can be equipped with devices from this device-dispenser depends on the height of the tallest device to be placed. There is a trade off between the height and the numbers of each device and the height of the cartridge.

Considering precision and accuracy in the process of dispensing devices, the miniaturization trend only adds to the need of perfection in these fields. The device-dispenser here presented has the advantage of containing the devices ready at the exact coordinates of each device.

This type of device-dispenser is very low-cost. The bigger parts of the dispenser could be cast in any kind of rigid plastic, e.g. from a mold built by additive manufacturing, or these bigger parts could be produced directly by additive manufacturing.

The parts of finer scale could with advantage be manufactured additively as well, but in a process apart, and probably in an additive manufacturing machine working in metal and in finer details.

The type of device-dispenser presented is conceived with miniaturization in mind, and only the limits set by the present additive manufacturing technology and component size restrain or at least retard the speed with which the miniaturization evolves, that this device-dispenser makes possible.

### Summary

This innovation presents a solution for specifically mounting devices on the described type and design of multi-tier conductive circuits.

The device-dispenser is additively manufactured, according to the specific design of the circuit for which the specific device-dispenser is intended.

Once building of the conductive circuits has reached the stage where devices need to be placed, the building platform of the additive manufacturing machine will be detached from the machine, and moved to a working surface or an assembly line, and eventually to or through a heating device.

Once solder material has been dispensed the device-dispenser will be fitted into a designated location column of the circuit design, and by applying mechanical force the devices for the circuit will be released and placed on their designated places, all at the same time.

### Detailed Description of the Invention

### Specific References

Hereafter all defined distances should be understood to take into account tolerances and necessary clearances to permit free movement.

It should furthermore be understood that device shafts are openings going all the way through the entire device-dispenser, whereas shaft caves are specific caves at specific levels in these device shafts, of certain heights and certain extensions outside the through-going openings of these device shafts.

### Parts

A device-dispenser for the preferred embodiment of the conductive circuit described above is 30 cm high and its surface area is 60 mm by 41 mm, in the shape of a slightly asymmetrical clover leaf pattern.

It comprises 2 principal parts, the device-dispenser base unit, and the cartridge. FIG. 21 shows these two principal parts assembled.

The device cartridge, 250, is a unit on its own; the device-dispenser base unit, 251, comprises 3 device-dispenser base levels, shown in FIG. 22, 257, 258, 259, plus shuttle bar panels, FIG. 23, 263, 265, 267. These panels are joined to the shuttle bars by cylinders, 266, being inserted into prepared openings in the top shelf of the shuttle bar panels, and in the shuttle bars, 256 (FIG. 22). To make the device-dispenser base levels a unity when assembled each level has male snap-locks, as the snap-locks of the conductive circuits presented above, extruding from the corners of the device-dispenser body, FIG. 22, 261, and the device-dispenser base levels two and three have corresponding female snap-locks beneath, also as of said conductive circuit.

To j oin the two principal parts, the device-dispenser base unit and the device-dispenser cartridge, there are male snap-locks extruding from the third level of the device-dispenser base unit, FIG. 22, 260. In the bottom of the cartridge there are corresponding female snap-locks. There are slots formed by horizontal excavations in the bottom of the cartridge and in the top level of the device-dispenser base unit, FIG. 21 and FIG. 22, 252. These slots make it possible to release the cartridge from the device-dispenser base unit, when it is time to replace an emptied cartridge with one fully loaded with devices.

A cartridge of the device-dispenser for the conductive circuits described holds 100 units of each of the devices needed for the presented preferred embodiment of the conductive circuit, which means a total of 6000 units.

There is a third component to the device-dispenser—a location supporting pillar, FIG. 21, 254. The design of this supporting pillar is a reuse of some of the design of the solder-dispenser presented:

Of the partial circle profile of the built-in supporting pillar, and of the umbrella-like design of this supporting pillar.

Specific for the location supporting pillar of the device-dispenser are the arms, FIG. 24, 269 and the eyes ending each arm, 270. The arms are horizontal extensions of the top of the umbrella-like supporting pillar, and the eyes at their ends are shaped to easily pass around a male snap-lock. The eyes and the part of the arms that reach the device-dispenser body fit into shallow grooves, 271, FIG. 24A in the surface of the device-dispenser base body, in order to make the device-dispenser base unit and device-dispenser cartridge fit together exactly with the location supporting pillar fixed between the base and the cartridge. By this construction the location supporting pillar fits properly inside the unity of the device-dispenser. And further fixed in the location column, FIG. 21, 253, the device-dispenser gets placed correctly in relation to the coordinates of the devices, each time.

This central location column, FIGS. 21 and 24B, 253, is situated within the ground tier of the example conductive circuit above, and is being built at the same time as the circuit tiers. Both the top-level solder-dispenser described above and the device-dispenser described here use this column for their proper location when in service. In FIG. 24B, reference number 253 shows the partial circle-angled opening in the location column, into which fit both the partial circle-angled handle of the device-dispenser location supporting pillar, 268 (FIG. 24), and the partial circle-angled handle of the supporting pillar of the top-level solder-dispenser.

### Inside the Device-Dispenser

There are vertical device shafts penetrating the body of the device-dispenser base units, as well as the cartridge. FIG. 21, 255 shows the device shaft openings on the top of the cartridge, and FIG. 22, 255 shows identical device shaft openings on all three device-dispenser base levels. There is one device shaft for each device, and in the device-dispenser base unit each device shaft has a cavity, the shaft cave, 262 (FIG. 22), and a shuttle, 273 (FIG. 25).

The shape of the body of the device-dispenser base unit, whereof FIG. 27, 295 presents one level, corresponds to the outlines of the device-carrying tiers of the conductive circuits of the preferred embodiment. The device-dispenser base unit is constructed in levels, to be assembled in the final stage of its production. Each level has a thickness (or height) corresponding to the maximum height of the group of devices it will contain, FIG. 22, 257, 258 and 259. These heights are calculated by the Analytical Software, mentioned later.

The levels of the device-dispenser base unit are constructed with the shaft caves open to the surface, FIGS. 22 and 25, 262. This is necessary for placing of the shuttles and shuttle bars at assembly.

The shaft caves get their ceilings, that are partial as are also the cave floors, at the assembly of the device-dispenser base unit, obtaining their necessary heights by their position in specific base levels, FIG. 22, 262. It can be seen, that the device shaft openings all at some point have a corresponding shaft cave, 255a. The base level in which they are positioned decide their heights, and thus the levels of their subsequent cave ceilings. FIG. 22, reference number 262, shows two shaft caves. The shaft cave on the third base level is much deeper, than the shaft cave on the first base level.

The shuttles, FIG. 25, 273, with hinges, 275, shuttle handles, 279, and shuttle handle cylinders, FIG. 29, 300, get built in a separate process that also includes shuttle bars, FIG. 28, 298. These shuttle bars will make it possible to operate all shuttle handles at the same time. The shuttle bars follow the outlines of the device-dispenser base unit body leaving 0.5 mm of distance between the body and the shuttle bars, corresponding to the operating distance for shuttles and shuttle handles.

Shuttle bar panels, FIG. 23, 263 and 267, on the sides of the device-dispenser base unit, enclose the shuttle bars on the particular side. They have shelves for the shuttle bars on the inside towards the base unit, FIG. 23, 264. This stabilizes the shuttle bars, but most importantly, the shuttle bar panels make it possible to work the shuttle bars all at the same time with mechanical means, such as pressured/under-pressured air or robotic arms.

FIG. 23 shows three types of solutions to enable working the shuttle bars and thus the shuttle handles connected to the shuttle bars. One solution is the shuttle bar panel with a panel handle on one side and on the other shelves for shuttle bars on all three device-dispenser base levels, reference number 263. Another solution is a shuttle bar panel with panel handle and two shelves, one for first level shuttle bars and one for second level shuttle bars, 267. The third solution is handles added directly to a shuttle bar, in cases where only one device-dispenser base level has a shuttle bar at this side of the base unit, 265.

To keep production costs down the type of shuttle bar panel with three shelves can also be used when only first and third device-dispenser level have shuttle bars, 263.

And although there are two types of shuttle bar panels and one type of shuttle bar on its own, there are only two levels of panel handles and bar handles, FIG. 28, 297, to facilitate the movements of them.

Every device shaft contains a stack of identical devices, whereof the bottom device is to be released to the receiving solder pad boxes on a particular location of the conductive circuit. To make sure that only one device at a time is released, the shaft cave is situated just above the bottom device. In the cave the shuttle is exactly the size of the device in this particular device shaft. The second-from-the-bottom device will be enclosed in the shuttle, FIG. 25B, 284, by which it will be pushed into the shaft cave, and thus effectively create a closure of the device shaft, to prevent devices further up from moving down.

### Into Details

The shaft cave, FIG. 25, has a cave floor, 274, on which the device in the shuttle rests, and it has a shuttle shelf, 272, on which the shuttle, 273, rests. The shuttle comprises a shuttle frame, FIG. 26, 286, to encompass the device to be ‘misaligned’—that is, to be pushed to the farthest corner of the shaft cave in order to block the device shaft opening, FIG. s 25B and 25C, 284. From outset the inner side of the shuttle frame, FIG. 26, 286a, is aligned to the edges of the device shaft opening, 282, FIG. 25. As long as that is the situation, devices pass through the device shaft. However, the purpose of the shuttle is to cause the closure of the device shaft, and for that to happen, the misalignment must take place.

FIGS. 25B and 25C depict such a misalignment, with a device in the grip of a shuttle, 284, pushed into the right-angled corner of the shaft cave, FIG. 25A, 283. The device beneath the one in the shuttle, FIGS. 25B and 25C, 285, has reached its final position.

Several features work together to accomplish the device shaft blocking misalignment:
In the body of the device-dispenser base unit, FIG. 27, 295
   the shaft cave entrances, FIG. 25, 277,
   the grooves for hinges, FIG. 25, 276,
   the grooves for shuttle handles, FIG. 25, 280.
In the shaft caves, FIG. 22, 262
   the sliding planes parallel to the hinge groove, FIG. 25, 278.
In connection with the shuttles, FIG. 25, 273,
   the hinge, 275, the shuttle handle, 279, the handle cylinder FIG. 29, 300, the shuttle bar, FIG. 28, 298.
In the shuttle bars
   the shuttle handle cylinder holes, FIG. 29A, 304

The misalignment is initiated by the shuttle bars being pushed towards the body of the device-dispenser base unit, FIG. 27, 295.

Starting with the shuttle handle cylinders, FIG. 29, 300, this movement acts through the shuttle handles, FIG. 25, 279, and the hinges, 275, to the shuttles, 273, on the shuttle shelves, 272, in the shaft caves, FIG. 22, 262. The design of the shaft caves, and of the grooves for shuttle handles, FIG. 25, 280, and for hinges, 276, guides the movement.

There are angles of 45 degrees at the shaft cave entrances, 277, as also at the two neighboring sliding planes, 278, that the shuttles are passing on their way to the right-angled corner 283, opposite the shaft cave entrance.

The movement reaching the cradle of the shuttle handle, FIG. 26, 291, is a force in one direction, perpendicular to the shuttle bars, FIG. 28, 298. At the shaft cave entrance, FIG. 25, 277, this force encounters a corner of the rectangular shuttle and is split into two equal forces with an angle of 90 degrees between them. The resulting force is a vector quantity having both magnitude and direction. The magnitude of the force can be calculated using Pythagoras's Theorem. As long as the mechanical force initially applied to the shuttle bars are greater than the force of the inertia of the shuttle towards the sliding planes, the shaft cave walls and the shaft cave floor, the shuttle will move.

The magnitude of the mechanical forces needed to push the shuttle bars will furthermore depend on the precision and accuracy of the additive manufacturing machine used for production of the shuttles, and on the precision and accuracy obtained for the device-dispenser base levels during their production.

When the shuttle bar is pushed towards the device-dispenser base unit body, the shuttle handle moves inwards, which in FIG. 26A is depicted as a movement upwards towards the top of the page. In this movement the intermediary, FIG. 26, 288, is forced to the left by the angle of the hinge groove, FIG. 25, 276. The cylinder of the intermediary, FIG. 26, 289, turns in the cradle of the shuttle handle, 291, and the shuttle cylinder, 287, turns in the cradle of the intermediary, 290. FIG. 26A depicts the functionality of the hinge during a misaligning movement, from the starting position of shuttle, hinge and shuttle handle, 292, passing through an intermediate position, 293, to the end position of these, 294.

To allow for the misaligning, inward movement of the shuttle bars, they have 45 degree slots in corners where two shuttle bars meet, FIG. 28, 299.

The shuttle bars being initially 0.5 mm from the body of the device-dispenser base unit, this is the distance of the movement that will occur when misalignment is initialized.

The shuttle handle cylinders are fixed in the shuttle bars in cases where the shuttles are full size as in FIG. 29, 300, and will be moved 0.5 mm towards the shaft cave.

However, not all shuttles are full size.

### Specific Designs

The shuttle frames for smaller devices are scaled down proportionally to the device size, FIG. 29, 302 compared to FIG. 29, 289. So are also the hinges, the shuttle handles and the shuttle handle cylinders, 301, compared to 300. In these cases the shaft caves are scaled down as well, FIG. 29B, 306 compared to FIG. 29B, 308, and thus the shuttles with devices have a shorter distance to move to reach the right-angled corner of the shaft caves. In the shuttle bar the scaled down shuttle handle cylinders, FIG. 29, 301, have a hole in the shuttle bar sized, FIG. 29A, 305, to reduce the movement of the shuttle handle proportionally. The shuttle handle cylinder in such a hole is not fixed once the device-dispenser is in use, and will move to the furthest end of the hole before actually being pressed towards the device-dispenser, and this shortening of distance results in the juxtapositioned shuttle traveling the same shorter distance.

A regular shuttle, full sized or scaled down, will have the hinge, FIG. 25, 275, attached to a corner of the shuttle, and thus the shuttle handle, 279, will leave from this corner. The shaft cave is designed accordingly, with a groove for shuttle handle leaving from a corner, FIG. 25, 280. To accommodate for devices sitting in such a position that they have no room for hinges and shuttle handles to leave from a corner of the shuttle frame, asymmetrical shuttles, FIG. 30, 309, and shaft caves, FIG. 30A, 311, are possible. The side of a shuttle frame to which the hinge and shuttle handle is attached is in that case reinforced, FIG. 30, 310, to obtain the same stability for a hinge and shuttle handle attached to the shuttle frame side as for a hinge and shuttle handle attached to a shuttle frame corner. The point on the shuttle frame side, to which the hinge and shuttle handle get attached, must be chosen to make the misaligning force come from a position that will enable the diagonal movement to be correct.

There are also devices sitting in a position where there is no room for shuttle handles to reach the shuttle bar at all. This challenge is met by another variant: Shuttles that work together in a group, getting served by only one hinge, one shuttle handle and one shuttle handle cylinder. FIG. 29, 303, shows two variants of shuttle groups, and FIG. 29B, 307 shows group shaft caves. It is of importance, that the shuttles in a group are all scaled to the same degree, and furthermore that the diagonal movements are to have the same direction for the shuttles in the group. The misaligning force must come from a position that will enable this diagonal movement to head in the desired direction.

There are two reasons for the situations to arise, where there is no room for hinges and shuttle handles to be in the normal positions.

Through-going device shaft openings, FIGS. 21 and 30, 255, is one such reason. Openings in the device-dispenser base unit for male snap locks extruding from the conductive lines of the conductive circuit, FIG. 27, 296, is another reason.

Male snap locks of the described preferred embodiment of the conductive circuit have several heights, and as the device-dispenser by definition needs to be positioned directly on the level of the circuit to which it is to dispense devices, the high male snap locks must have room to pass through the device-dispenser body.

Concerning the through-going device shaft openings, even though the device-dispenser has a level for each height group of devices, making the placing of devices on the individual levels less dense, there must be room for all devices to pass through all levels to reach their proper location in the conductive circuit.

For the device-dispenser of the preferred embodiment the finished device-dispenser consists of the three base levels and the cartridge placed on top of each other, which means that all devices have to pass through the whole height of the device-dispenser, beginning with the height of the cartridge.

The devices with shaft caves and thus device shaft closures on the third device-dispenser base level have levels two and one below this closure, and in principle the device below the closure would have to pass through levels two and one after being released to their solder pad boxes. However, these third level devices have such a height—a group qualifying criteria—that the devices below the device shaft closure will already be on their destinations as the closure takes place.

Likewise, devices with shaft caves on second level, passing through third level on the way to their device shaft closure, will in principle have to pass through level one when being released, but their heights mean that they will actually be at their destinations.

Devices that have shaft caves on first level will have passed through levels three and two on their way to their device shaft closure, and when released they will also already be at the destination solder pad boxes.

### Analytical Software

The Analytical Software is used to group the devices into as few height groups as possible, to facilitate both design and production, e.g. shortening of the additive manufacturing time.

In the example of the preferred embodiment of the described conductive circuit there are devices of 13 different heights (0.4 mm, 0.5 mm, 0.55 mm, 0.66 mm, 0.8 mm, 0.9 mm, 0.95 mm, 1.05 mm, 1.15 mm, 1.22 mm, 1.8 mm, 2.5 mm, 2.95 mm.) If they were not grouped, there would have to be 13 device-dispenser levels, with each their height and position of shuttles and of shaft caves. However, using the results of the analyses of the software now only 3 levels are required.

The challenge is to identify devices that could be handled by one height and position of a shuttle and fit into one height and position of a shaft cave. The devices that could thus fit into the same height and position of shuttle and shaft cave could all get their positions on the same level of the device-dispenser base unit—the height of these levels being determined by the heights of the shaft caves of this level.

During the analyses it turned out that for the smallest of devices of a group it could happen, that the height and position of the shuttle would enclose two devices. In order to obtain as few groups as feasible, the software would accept this on the condition that these two devices could still both fit into the shaft cave at the same time. The priority is that they could get gripped by the shuttle and get ushered to their right positions to create the desired device shaft closure.

The three levels of the device-dispenser base unit for this device-dispenser adapted to the preferred embodiment of the described conductive circuit correspond to three groups thus identified by the analytical software. Each group of devices within a range of heights have their own level of the device dispenser base unit with shaft caves and shuttles fitting these heights.

In the example the accepted tolerance of device surface area is +−2.5%, and the accepted tolerance for device heights is +−2.75%.

### Specific Features Concerning Building Processes

With the building process in additive manufacturing machines in mind the design of the preferred embodiment has features exclusively created to make such a building possible.

No matter what kind of additive manufacturing—which type of material being used, and which type of machine—a guiding principle is to have everything supported from the ground and upwards.

The design of the location supporting pillar is one example of this, The supporting pillar begins with the partial circle-angled handle of the supporting pillar, and from there it grows in height and gradually in width to the full diameter.

Another principle has been to make everything stay together until it has found its final destination. This rule has e.g. been applied concerning the shuttle handle cylinders. In the shuttle handle cylinder holes of the shuttle bar the shuttle handle cylinders have two tiny cylinders across the diameter, attaching a shuttle handle cylinder to the walls of the hole, FIG. 31, 312. FIG. 31A, reference number 313 shows the same feature in a hinge of a shuttle.

In cases where such tiny fixing-cylinders are created for production, these cylinders will be broken first time the device-dispenser is being used. This breaking is on purpose in order to obtain the clearance needed for the parts to move relatively to each other

Although the descriptions above contain many specificities, these should not be construed as limiting the scope of the embodiments but as merely providing illustrations of some of several embodiments. For example, the device-dispenser can have other shapes, such as rectangular, circular, oval, trapezoidal, triangular etc.

Thus the scope of the embodiments should be determined by the appended claims and their legal equivalents, rather than by the examples given.

### Claims 14-22

### Abstract of the Disclosure

Systems of dispensing devices for miniature conductive circuits evidently demands methods for handling miniature devices in very restricted spaces.

The innovation here disclosed has arisen in response to the multi-tier conductive circuits, presented above, making use of the exact coordinates of the destination of each device.

This device-dispenser work on simple principles, dispensing devices to all the tiers of the circuit in one procedure only using either pressured air or robotic arms to release the devices. The device-dispenser has a detachable cartridge to refill; it can carry great quantities of devices for identical circuits.

### Detailed Description of the Invention

As will be evident from the descriptions above the multi-tier circuit is the focus of the unity of innovations presented here.

The detachable production platform is a prerequisite for the manufacturing of these circuits and the solder-dispenser and device-dispenser are necessary peripherals in order to have a final multi-tier conductive circuit ready to be fitted into a housing or inserted directly into some specific apparatus.

The individual parts of this innovative unity come into play one after the other, which implies that the procedure can be performed on a production line, equipped with at least two additive manufacturing machines, as shown in FIG. 32.

This diagram is to be understood only as an outline to suggest how mass production can be organized.

Reference number 341 is an additive manufacturing machine in which the first steps of the building procedure are performed. Once the building has reached the level where the conductive lines and the solder pad boxes are ready, the production platform is detached from the manufacturing machine and transferred to next part of the procedure, 342, where the solder-dispenser will be fitted into its location column on the production platform. Solder material in solid form will be in the central solder receptacle in a quantity to exactly fill up the solder pad boxes. This entity hereafter gets transferred to a heating device, 343, where the solder material will be dispensed automatically once the solid material reaches the temperature to make it fluid. Once the solder material is in the solder pad boxes the production platform is re-inserted in exact position in Additive Manufacturing Machine II, 344, and the building continues to produce the guides and the male snap locks to different heights.

Hereafter the production platform is again detached and transferred to fifth part of the procedure, 345. Now the device-dispenser will be fitted into the location column, and means will be applied to dispense one device to each solder pad box in one procedure. Next the platform goes into Heating Device II, 346, to get the devices soldered to the circuit.

With the devices now firmly attached to the circuit the assembly procedure takes place, 347. This consists of cutting off one tier from the production platform at a specific time to stack it on top of another specific tier, according to the design of the circuit. In the end the united stack of tiers gets cut off the production platform.

Two more steps finish the creation of the multi-tier circuit. 348 is a bath of EMI insulating fluid, into which the united stack of circuits gets immersed; it thereafter gets cured by means of a light with the specific capacity of hardening the EMI insulating fluid. The same procedure is performed at 349, only this bath consists of a fluid to insulate against conductivity, and the type of light applied is adapted to such a fluid.

350 is the finished multi-tier conductive circuit, ready to get housing or to be fitted into the apparatus for which it was conceived.

The production platform goes into a new production cycle.

All the tiers being cut off, including also the cut off of the assembled unity, will leave the supporting structures on the production platform, that is then recycled in an outer loop, 351, back to the initial additive manufacturing machine, 341, where building will be resumed on top of the existing supporting structures with the cutting structures followed by the conductive lines and solder pad boxes.

Assembling female and male snap locks FIG. 32A+FIG. 33A

During the assembly procedure the male snap locks automatically snap into the designated female snap locks as the tiers are stacked one on top of the other.

The connections they thus form are designed to secure the flow of current.

However, some circuits might need stronger connections, if for instance the finished circuit will be handled without a housing, and if the final destination of such a circuit is exposed to strain of one kind or the other.

It could thus be deemed reasonable to chose the option of soldering the two snap locks together. Such a choice necessitates solder material to be dispensed to the openings on the surface of the female snap locks.

In the preferred embodiment the solder material for the female snap locks would then be dispensed at the same time as the solder material is dispensed to the solder pad boxes, FIG. 32A, 342 and 343.

In the assembly procedure the unity of tiers after being stacked will stay on the production platform for a final transfer to a heating device, 346, that will ensure the soldering of the male snap locks inside the female snap locks, and only after this procedure be cut off the platform to go into the processes of insulating immersions, 348 and 349, and curing.

In the two alternative embodiments—that have either solder material of metal nano particles filled into the boxes during the building procedure or have solid solder pad boxes—solder material will have to be dispensed to the female snap lock openings in a separate process, FIG. 33A, 352. This can be done before the production platform with the tiers is transferred to the assembly session. And then after the assembling has taken place the unity of tiers will go into the heating device again, 353, for a final soldering together of the male and female snap locks.

### Brief Description of the Several Views of the Drawings

FIG. 1 shows the three parts of the production platform and column, the production platform, the upper part of the upper column, the lower part of the upper column and the base column. This lower part is a feature of the additive manufacturing machine as such. Here it is taken out of this context. The base column has slits of a lock, to unlock the production platform and to re-lock it.

FIG. 1A is a diagonal view from below of the bottom of the upper part of the upper column showing the thread within.

FIG. 2 has the two parts of the upper column assembled.

FIG. 3 is the upper column inserted into the base column and locked.

FIG. 3A is a picture from an angle of the screw, that keeps the knob of the upper column strictly in place, once the upper column is inserted into the base column.

FIG. 4 is the tier for analog front end, comprising conductive lines and solder pad boxes, cutting structures and supporting structures, guides, male snap-locks, female snap-locks.

FIG. 5 is the production platform of a 3D printer with all five tiers—ground tier, power tier, analog front end tier, tier of Blue-tooth Low Energy sender and analyzing micro-controller, tier of antenna and connector—before devices are added.

FIG. 5A is identical to FIG. 5, but now including devices on the analog front end tier, on the tier of Blue-tooth Low Energy sender and analyzing micro-controller, and on the antenna and connector tier.

FIG. 6 shows the cutting disc in action on the analog front end tier, cutting through the cutting structure, cutting off the conductive line level and leaving the supporting structure on the production platform of the 3D printer.

FIG. 6A side view of the cutting disc in action on the analog front end tier.

FIG. 7 shows cutting structures of conductive lines and cross sections of these to show cavities.

FIG. 7A shows cutting structures of solder pad boxes.

FIG. 8 is the production platform of a 3D printer, where in the middle all tiers are stacked on top of the ground tier to a unity, while supporting structures for the other four tiers are left on the production platform.

FIG. 8A side view of the five tiers stacked and cut off the production platform.

FIG. 9 is a conductive line level without cutting structures and supporting structures. There are solder pad boxes with guides, female snap-locks and male snap-locks.

FIG. 9A a diagonal view of the tier of FIG. 9 with devices.

FIG. 9B a top view, of the tier of FIG. 9 with devices.

FIG. 10 to 10B is two perspectives of a conductive line with a female snap-lock within, and a perspective of a male snap lock plus a perspective of a female snap lock joined by a male snap lock within a conductive line.

FIG. 11 shows female snap-locks within islands, independent of the conductive lines of ground tier.

FIG. 11A shows male snap-locks on top of the islands of FIG. 11.

FIG. 12 is the two parts of the power tier, each with their male snap-locks.

FIG. 13 is solder pad boxes with micro- and nano-particles in different stages of the production, all fitted with one transparent wall, to make visible the changing structures of the solder material within.

FIG. 14 shows the building platform with conductive circuits free of supporting substrate and solder-dispensers, top-level and lower-level.

FIG. 15 is the top-level of the solder-dispensers, with the oval openings of the solder container in closed position.

FIG. 15A the top-level of the solder-dispensers, with the oval openings of the solder container in open position.

FIG. 15B is a top-view of the top-level solder-dispenser showing different sizes of pipe openings, corresponding to different sizes of pipes.

FIG. 16 shows the top-level solder-dispenser, in a diagonal view positioned on the building platform and placed in the top-level central location column in the surroundings of one tier of the conductive circuits under construction.

FIG. 17 depicts the lower-level solder-dispensers in their unity.

FIG. 17A is a top view of the unity of lower-level solder-dispensers.

FIG. 18 shows an excerpt of the lower-level solder-dispensers in a diagonal view from below.

FIG. 19 is an excerpt of the lower-level solder-dispensers, seen diagonally from above, positioned in surroundings of conductive circuits free of supporting substrate on the building platform. To the right is a part of a lower-level solder-dispenser platform, here depicted without the wall, in order to show pipe openings in the slope of the platform.

FIG. 20 shows the central part of the conductive circuits on the building platform with the location columns positioned in these surroundings.

FIG. 21 depicts the totality of the device-dispenser, and the insert shows in bigger scale the device-dispenser base unit in situ of the preferred embodiment of the conductive circuit under construction.

FIG. 22 is an exploded view of the device-dispenser base unit.

FIG. 23 is the device-dispenser base unit assembled.

FIG. 24-24B has three different views of details of the location supporting pillar of the device-dispenser.

FIG. 25 shows a shaft cave with a shuttle.

FIG. 25A is a top view of a shuttle with a device.

FIG. 25B depicts the same views as FIG. 25A, here concerning the device shaft closing misalignment, with a device in the shuttle being pushed to the corner of the shaft cave opposite the shaft cave entrance.

FIG. 25C is a side view from slightly below of the same scene as in FIG. 25B

FIG. 26 is an enlarged depiction of the hinge at the corner of a shuttle.

FIG. 26A is three stages of the misaligning movement with focus on the movements of the hinge.

FIG. 27 shows the first level of the device-dispenser base unit.

FIG. 28 is the same level of the device-dispenser base unit as FIG. 27 with the bars added.

FIG. 29 shows details of a shuttle bar with shuttles and shuttle handle cylinders inserted, from a part of the first device-dispenser base level.

FIG. 29A shows details of the same shuttle bar without devices—shuttle handle cylinder holes can be seen.

FIG. 29B shows the same part of the first device-dispenser base level, here including the body of this level, with shuttle bar, shuttle handle cylinder holes, shaft caves and shuttles.

FIG. 30 is a view of another part of the first device-dispenser base level, focused on asymmetrical shuttles and shaft caves, top view with shuttles.

FIG. 30A a view in perspective of FIG. 30 without shuttles.

FIG. 31 and FIG. 31A illustrates how fixing-cylinders are created within specific features for manufacturing purposes.

FIG. 32 diagram of procedures for production of conductive circuits of preferred embodiments from start to finish.

FIG. 32A diagram as FIG. 32 with the addition of soldering of connections between male and female snap locks.

FIG. 33 diagram of procedures for production of conductive circuits of first and second alternative embodiments.

FIG. 33A diagram as FIG. 33 with soldering of connection between male and female snap locks.

### REFERENCE NUMERALS

### FIG. 1

101 production platform

102 thread

103 base column

104 widening for locking screw

105 horizontal lock slit

106 vertical lock slit

107 knob for lock

108 lower part of upper column

109 upper part of upper column

### FIG. 1A

110 openings for electrical connections

### FIG. 2

111 upper column

112 groove for locking screw

113 diameter of upper part of upper column bigger than diameter of lower part of upper column

### FIG. 3

114 locking screw

115 slit in locking screw

116 alignment mark for locking screw slit

117 unity of upper column and base column

### FIG. 4

120 supporting structure of conductive line

121 cutting structure of conductive line

122 conductive line

123 supporting structure of solder pad box

124 cutting structure of solder pad box

125 solder pad box

126 female snap-lock inside conductive line

127 guide on solder pad boxes

128 guide on conductive lines

129 male snap-locks

### FIG. 5

130 tier for Blue-tooth Low Energy sender and analyzing micro-controller, supporting structure, cutting structure, conductive lines

131 tier for analog front end, supporting structure, cutting structure, conductive lines

132 ground tier, supporting structure, cutting structure, conductive lines

133 power tier, supporting structure, cutting structure, conductive lines

134 tier containing antenna and basis for connector, supporting structure, cutting structure, conductive lines

135 location columns

136 central location column

### FIG. 5A

141 tier containing Blue-tooth Low Energy sender and analyzing micro-controller, supporting structure, cutting structure, conductive lines

142 tier containing analog front end, supporting structure, cutting structure, conductive lines, solder pad boxes, guides, female snap-locks, male snap-locks, and devices

143 tier containing antenna and connector

### FIG. 6

144 cutting disc, here made transparent, the edge of production platform visible through the cutting disc

145 production platform of additive manufacturing machine

### FIG. 7

146 cross sections of cutting structures for conductive lines showing cavities

### FIG. 7A

147 oval openings lengthwise inside cutting structure for solder pad boxes

148 oval openings across the short side of cutting structure for solder pad boxes

### FIG. 8

149 all tiers stacked on top of ground tier and on top of each other

### FIG. 8A

150 ground tier, conductive line level cut loose

151 power tier, conductive line level cut loose

152 tier containing analog front end, conductive line level cut loose

153 tier containing Blue-tooth Low Energy sender and analyzing micro-controller, conductive line level cut loose

154 tier containing antenna and connector, conductive line level cut loose

### FIG. 9

155 analog front end tier, conductive lines, without devices

### FIG. 9A

156 analog front end tier, conductive lines, with devices

### FIG. 10

157 wall of inner cylinder of female snap-lock

158 slit in inner cylinder of female snap-lock

159 wall of outer cylinder of female snap-lock

### FIG. 10A

160 low wall to contain solder paste on top of female snap-lock

161 hole on top of female snap-lock

### FIG. 10B

162 male snap-lock crown

### FIG. 11

164 islands with female snap-locks for sensor signals

165 island with female snap-lock for battery contact

### FIG. 11A

166 male snap-locks from islands to analog front end tier

167 male snap-lock connecting battery of 3.3 volt to analog front end tier

### FIG. 12

168 3.3 +volts power area

169 1.8 +volts power area

170 male snap-locks from power tier 3.3 volt area to tier with analog front end

171 male snap-locks from power tier 1.8 volt area to tier with Bluetooth Low Energy sender and analyzing micro-controller

### FIG. 13

172 micro-particles in solder pad box, one side transparent

173 micro-particles and nano-particles in solder pad box, one side transparent

174 nano-particles melted, micro-particles on surface in solder pad box, one side transparent

### FIG. 14

200 top-level solder-dispenser

201 lower-level solder-dispensers

202 conductive circuit to have solder material applied

203 building platform

### FIG. 15

204 vertical wall of top-level solder-dispenser

205 slope from central platform to wall

206 central horizontal platform

207 solder container

208 supporting pillar of top-level solder-dispenser

209 solder container handle for opening and closing oval openings

210 oval openings oval openings of solder container, closed

211 plurality of pipes for one lower-level solder dispenser

212 single pipe for one lower-level solder dispenser

### FIG. 15A

213 oval openings of solder container, open

### FIG. 15B

214 pipe-openings of top-level solder-dispenser, different diameters

### FIG. 16

215 v-profile of handle of built-in supporting pillar

216 central location column on building platform

### FIG. 17

217 bridges between tiers

218 lower-level solder-dispensers, pipe with narrow ending

219 lower-level solder-dispensers, pipe with wider ending

220 supporting pillars of solder-dispensers and of bridges

221 bridge within a tier

### FIG. 17A

222 solder-dispenser for one device, such as a micro-controller

223 solder-dispenser for plurality of devices

224 solder-dispenser pipe-openings

### FIG. 18

225 supporting pillar design like an umbrella

226 plurality of supporting pillars to stand on building platform

### FIG. 19

227 guides of solder pad boxes

228 pipes of solder-dispenser for designated solder pad boxes of one device

229 pipes reaching each their designated solder pad box

230 pipes for solder-dispenser for a plurality of designated solder pad boxes

### FIG. 20

231 lower-level location columns on production platform

### FIG. 21

250 device cartridge

251 device-dispenser base unit

252 slots for releasing cartridge from device-dispenser

253 central location column

254 location supporting pillar

255 device shaft opening

### FIG. 22

255a device shaft opening with shaft cave on one level

256 holes prepared for cylinder to join shuttle bar panels to shuttle bars

257 first level of device-dispenser base, thinner than second and third level

258 second level of device-dispenser base, thicker than first level

259 third level of device-dispenser base, thicker than first and second level

260 male snap-locks to connect cartridge and base unit and to fix location supporting pillar

261 male snap locks to connect device-dispenser base unit levels

262 shaft cave, open to the surface of the body of the device-dispenser base level during manufacturing

### FIG. 23

263 panel for shuttle bars, full height

264 shelves for shuttle bars

265 bar handles and panel handle

266 cylinder to join shuttle bars and panels

267 panel for shuttle bars, two stories

### FIG. 24

268 handle of location supporting pillar

269 arms of location supporting pillar

270 eyes at the end of location supporting pillar arms

### FIG. 24A

271 grooves for arms and eyes of location supporting pillar

### FIG. 25

272 shuttle shelf

273 shuttle

274 cave floor

275 hinge

276 hinge groove, angled 45 degrees to shaft cave

277 shaft cave entrance

278 sliding planes, parallel to hinge groove

279 shuttle handle

280 shuttle handle groove leaving shaft cave from corner after hinge groove, going in a straight line, the shortest distance to the shuttle bar at the edge of the device-dispenser base level body

282 edge of device shaft opening

283 right-angled corner of shaft cave

### FIG. 25A

284 device in shuttle

### FIG. 25B

285 device below shuttle, placed on destination

### FIG. 26

286 shuttle frame

286a inner side of shuttle frame

287 shuttle cylinder

288 intermediary

289 cylinder of intermediary

290 cradle of intermediary

291 cradle of shuttle handle

### FIG. 26.A

292 starting position of misalignment for shuttle, hinge and shuttle handle

293 intermediate position of misalignment for shuttle, hinge and shuttle handle

294 end position of misalignment for shuttle, hinge and shuttle handle

### FIG. 27

295 device-dispenser base unit body, one level

296 opening for male snap-lock pins of circuit

### FIG. 28

297 shuttle bar handle

298 shuttle bars

299 slits between two shuttle bars

### FIG. 29

300 shuttle handle cylinder

301 shuttle handle cylinders, scaled down

302 shuttle frames scaled down

303 shuttles in group

### FIG. 29A

304 shuttle handle cylinder hole in shuttle bar

305 shuttle handle cylinder holes scaled down

### FIG. 29B

306 shaft caves scaled down

307 group shaft caves

308 shaft cave, full scale

### FIG. 30

309 asymmetrical shuttles

310 reinforced shuttle frame side

### FIG. 30A

311 asymmetrical shaft caves

### FIG. 31

312 fixing-cylinders of handle cylinder in shuttle bar hole

### FIG. 31A

313 fixing-cylinders of hinge of shuttle

### FIG. 32

341 Additive Manufacturing Machine I

342 Fixing the solder-dispenser into location column

343 Heating Device I

344 Additive Manufacturing Machine II

345 Fixing the device-dispenser into location column

346 Heating Device II

347 Assembly procedure

348 Immersion into fluid and curing with light for EMI insulation

349 Immersion into fluid and curing with light for conductive insulation

350 Multi-tier circuits in final stage before housing

351 Outer loop for production platform—from cutting off procedure to be re-inserted into additive manufacturing machine

### FIG. 33A

352 Specific solder-dispenser for dispensing solder material to top of female snap locks

353 Returning assembled stack of tiers to heating device for second session

We claim:

1. A detachable and accurately replaceable production platform for additive manufacturing machines, comprising
a. a production platform basically constructed by a platform on a column, said column being divided into two parts, an upper column and a base column, said base column having a diameter slightly larger than the diameter of the lower part of said upper column, said base column having a hollow part uppermost, said base column furthermore having opposing vertical slits from the top edge of said hollow part and a certain part of the way down, at which point the slits make a right-angled turn and become horizontal slits, stretching a certain length round said hollow part, and
b. at least one conoid shaped locking screw, and
c. said horizontal slits having a circular widening at a certain distance from the right-angled turn, and
d. said upper column having said platform at the upper edge, and said upper column having two opposing knobs at a certain distance from the lower edge, and
e. said upper column having a conoid shaped hollowness next to at least one of said knobs,
whereby the locking screw by being inserted into at least one of the widenings of the horizontal slits and into the corresponding aligned conoid shaped hollowness of the upper column can be screwed tight (by a rotation of approximately 360 degrees) to fixate the knob at the end of the horizontal slit, and whereby said platform can be detached from an additive manufacturing machine by unscrewing the locking screw, and rotating said platform horizontally to the end of said horizontal slits, where-after said platform can be lifted vertically out of said additive manufacturing machine, and whereby said platform later can be re-inserted by being lowered vertically until said knobs reach the bottom of said vertical slits, where-after a horizontal rotation, in the opposite direction of the rotation for detaching the platform, will bring said platform back in the exact position from where it was detached, and the locking screw can be re-inserted and screwed into position.

2. The production platform of claim 1, wherein
a. said upper column is divided in two parts, both equipped with threads for reassembling, the top part of said parts being hollow, and a certain part of the production platform also being hollow and at a certain point, well above the level to which said upper column will be inserted into said base column, having two openings the diameter of electrical wires, and
b. an electro-magnet is fitted into the hollow parts of said top part and of said production platform, having its connecting wires pass out through said two openings the diameter of electrical wires,
whereby magnetic forces can be added to the gravity force of magnetic metal powder, as e.g. nickel, and thus enhance both the surface structure and the density of the material of the item under construction, and furthermore counteract van der Waals forces, that by making the particles agglomerate and by giving them reduced fluidity have until now made it difficult to produce details as fine as needed in further miniaturizing of conductive circuits.

3. A method for creating multi-tier conductive circuits free of supporting substrate with intermediary devices soldered on a plurality of tiers comprising
a. providing means for production of three-dimensional conductive circuit lines organized in a plurality of unities of an identical certain dimension, a certain number of said unities of an identical certain dimension designed to carry electronic devices, and for production of means for containing solder material on predetermined positions on the unities designed to carry electronic devices, and for production of means for establishing vertical conductive connections on predetermined positions on said three-dimensional conductive circuit lines, and for production of means for receiving signals and data from external sources, and
b. providing means for said plurality of unities to have solder material applied to said means for containing solder material, and providing means for said plurality of unities to have devices positioned and soldered on said predetermined positions, and
c. providing means to cut off one at a time said plurality of unities with devices, and
d. providing means for the separated unities to be stacked one on top of the other in a specific sequence forming a final unity, and
e. using said means to cut off one at a time said plurality of unities with devices to cut off said final unity, and
f. providing baths of specific fluid substances into which to immerse said final unity, and
g. providing means for said fluid substances to be cured, and
h. providing housing into which to fit said final unity,
whereby a fully functional multi-tiered three-dimensional conductive circuit free of supporting substrate with a maximally miniaturized extension is established.

4. The method of claim 3 wherein the conductive lines are electronically conductive lines.

5. The method of claim 3 wherein the conductive lines are electro-magnetically conductive lines.

6. The method of claim 3 wherein the conductive lines are optically conductive lines.

7. The method of claim 3 for multi-tier three-dimensional conductive circuits, wherein the construction of the circuits is to be realized by means of an additive manufacturing machine for metal powder, with a removable production platform, and wherein
a. the plurality of unities of claim 3 are to be arranged to be printed on a production platform of an additive manufacturing machine for metal powder in a single printing procedure
b. supporting structures are to be built at first, with outlines identical to the conductive circuit lines of claim 3,
c. cutting structures, constructed to facilitate the final cutting off, are to be built on top of said supporting structures, with outlines identical to the conductive circuit lines of claim 3, and
d. said three-dimensional conductive circuit lines are to be built on top of said cutting structures, and
e. at the procedure of cutting loose said plurality of unities with devices, said cutting structures will get pulverized, and said supporting structures will be left on said production platform, to be re-used for repeated building of three-dimensional conductive circuit lines of identical design.

8. The method of claim 3 wherein the means for containing solder material on predetermined positions are equipped with means for guiding solder material and eventually devices to exact predetermined positions on said unities designed to carry electronic devices.

9. The method of claim 3 being applied to produce an alternative embodiment, wherein a detachable building platform of an additive manufacturing machine equipped with an electro-magnet is being provided, and
a. employing said electro-magnet to obtain a packing of metal particles more densely than otherwise possible, and employing conductive and magnetic metal micro-particles to be sintered selectively by laser beams to build the conductive circuit of claim 3, and
b. at a certain point of the printing procedure providing solder material by employing conductive and magnetic metal nano-particles to be sintered by a lower power of laser beams than for metal micro-particles, to fill up the means of claim 3 for containing solder material,
whereby the solder material is provided all over the conductive circuits of claim 3 during the building procedure, rendering the circuits ready for having devices positioned and soldered.

10. The method of claim 3 being applied to produce a second alternative embodiment, wherein the means for containing solder material on predetermined positions are made solid, and where the laser beams of said additive manufacturing machine are used to attach the devices to these solid means for containing solder material.

11. Solder-dispensers to accommodate to the multi-tier conductive circuits free of supporting substrate, comprising
a. a top-level solder-dispenser prepared to being fixed in surroundings of said conductive circuit on the detachable building platform of an additive manufacturing machine, said top-level solder-dispenser being of circular design, and having a central platform, said central platform being underlined by a supporting pillar, and said supporting pillar descending from underlining said central platform into a narrow column, fitting into a location column in the surroundings of said conductive circuit on said detachable building platform, said central platform comprising a solder receptacle with openings along the sides, said openings having open and closed positions, handled by a handle on the side of said solder receptacle, and said central platform being limited by a wall, and said central platform forming a peripheral slope towards said wall, said slope being perforated by openings towards pipes going downwards to a lower-level of solder-dispensers from said top-level solder-dispenser, and
b. said lower-level solder-dispensers prepared to be fixed in location columns in said surroundings of said conductive circuit on said building platform, said lower-level solder-dispensers being of circular design, comprising a central platform and a slope in the periphery of said central platform towards a surrounding wall, and said central platform being underlined by a supporting pillar, said supporting pillar descending from underlining said central platform into a narrow column, and said slope being perforated by openings towards pipes going downwards from said lower-level solder-dispensers, and said pipes reaching from said openings in said slope to each their predetermined solder pad box of said conductive circuits,
whereby solder material can flow all the way, from said top-level solder-dispenser to the destinations, as the solder-dispensers are forced into correct positions by the columns of the supporting pillars fitting into openings of location columns, and solder material can be dispensed to said conductive circuits on said detached building platform of an additive manufacturing machine all at the same time by use of only the gravitational force, eventually reinforced by electro-magnetic bursts.

12. The solder-dispensers of claim 11 wherein the top-level solder-dispenser has a shape of a part of a circle, and wherein
a. the central platform of said top-level solder-dispenser having said shape of a part of a circle, and the solder-dispenser supporting pillar underlining said central platform having said shape of a part of a circle, and said supporting pillar descending from underlining said central platform into a narrow column, of a shape dictated by said shape of a part of a circle to a location column opening, shaped according to said shape of a part of a circle, and said central platform comprising a solder receptacle, and said solder receptacle having said shape of a part of a circle,
whereby said top-level solder-dispenser is forced into correct position by the column of the supporting pillar fitting into the opening of said location column to supply solder material through correctly positioned lower-level solder-dispensers only to device-carrying tiers of said conductive circuit on said building platform of an additive manufacturing machine.

13. A method of dispensing solder material to multi-tier conductive circuits free of supporting substrate, comprising
a. providing a 2-level solder-dispenser, designed to be fixed in location columns in surroundings of a conductive circuit on a detachable building platform of an additive manufacturing machine, and
b. detaching said building platform, and
c. providing solid solder-material to a receptacle on the top-level of said 2-level solder-dispenser, and placing said building platform including said conductive circuits and said solder-dispenser in a heating device,
whereby, having obtained a fluid consistency, and having assured that the openings of the receptacle of the top-level solder-dispenser are put in the open position, said solder-material will by the gravitational force flow from said top-level solder-dispenser via said lower-level solder-dispensers to the solder-material destinations of the conductive circuit.

14. A device-dispenser for dispensing devices to conductive circuits comprising
a. a cartridge of a design according to the conductive circuit for which it is conceived, to contain all devices for said conductive circuit, said cartridge dimensioned to contain said devices for a multitude of identical conductive circuits, and said cartridge equipped with locking mechanism to attach to a base unit of said device-dispenser, and
b. a plurality of levels for said base unit of said design, said plurality of levels equipped with locking mechanisms and being joined to create said base unit, and further having said cartridge joined to upper side at an assembling procedure involving locking mechanism, and
c. device shafts going through the totality of said assembled base unit and cartridge, said device shafts each equipped with a shaft cave in one particular level of said base unit, and
d. said shaft caves being open to the surface of the individual levels of said base unit until said assembling procedure, and
e. an algorithm for analytical software to group devices into as few height groups as possible, and
f. said shaft caves being of certain heights according to said analytical software and according to the heights of the device to be dispensed from each said device shaft, and
g. said shaft caves sized horizontally according to said devices, and
h. said shaft caves designed with shelves and grooves to support shuttles and shuttle movements, and
i. said shaft caves having partial ceilings provided by another level of said base unit superposed at said assembly procedure, and
j. each of said shuttles comprising a shuttle frame, hinges, and a shuttle handle ending in a handle cylinder, all sized according to the device to be handled by each of said shuttles, and
k. said shaft caves containing each one of said shuttles designed to enclose one of said devices, said shuttle being placed at a specific level in said shaft cave, one hinge being attached to a corner of said shuttle frame, said shuttle handle having the function as second part of the hinges, and from said hinges said shuttle handle extruding horizontally, ending in said handle cylinder, and
l. said shuttle handle being placed in grooves extending from said shaft cave on the surface of one particular level of said base unit, and
m. said hinges initially being kept together by fixing-cylinders, and said handle cylinder initially being stabilized by fixing-cylinders in a shuttle bar outside said particular level of said base unit, and
n. the lengths of said shuttle handles deciding the necessary distance between said base unit and said shuttle bars, making said distance identical for all shuttle bars, and
o. panels fitted along the sides of the assembled base levels to encompass said shuttle bars.

15. The shuttle bars of claim 14, wherein
a. each said shuttle bar is stretching along one side of one particular level of said base unit at said distance, and
b. said shuttle bar having a plurality of holes for said handle cylinders, and
c. said holes holding said handle cylinders for shuttle handles extruding at a specific side of said particular level of said base unit, and
d. said holes each sized and designed according to the device to be handled by said shuttle in the specific shaft cave from which each specific handle extrudes, and
e. said holes being cylindrical for handle cylinders of said shuttles of full size, and
f. said holes for handle cylinders of smaller sizes of said shuttles having the shape of cuboids whose short sides on the horizontal plane are half-cylindrical, and
g. said half-cylinders having the specific diameter of the handle cylinder of the smaller sized shuttle to be working in this particular shaft cave.

16. The fixing-cylinders of claim 14, whereof
a. said hinges have at least two of said fixing-cylinders, and
b. each of said handle cylinders is equipped with at least two of said fixing-cylinders,
whereby said hinges are fixed together and said handle cylinder is fixed in said shuttle bar during creation and assembling, to be broken at first device-dispensing session and eventually letting said hinges move relatively to each other and letting said handle cylinder move in said hole of said shuttle bar.

17. The panels of claim 14, comprising
a. a wall with a handle on the outwards side of said wall, and
b. shelves for shuttle bars on the side of said wall turning towards said base levels, and
c. an extra shelf uppermost of said wall, and
d. pins the height of the walls fitting into holes in said uppermost shelf, and in said shelves for shuttle bars and in said shuttle bars,
whereby a specific number of said panels can be placed and fixed to support the shuttle bars along said base level sides at the moment of assembling, and whereby, by means of said handles, all shuttle bars can be moved at the same time.

18. The assembly process of claim 14, wherein
a. said handle cylinders are being enclosed in said shuttle bars, all of said cylinders of smaller sized shuttles situated in the half-cylinder of their shuttle bar holes closest to said device-dispenser base unit, and
b said shuttles are being positioned in said shaft caves, and one of said levels for a base unit at a time is being positioned on top of another of the levels, and said levels for a base unit are being joined by said locking mechanisms, thereby providing the levels below with ceilings for said shaft caves, and finishing the assembly by placing said cartridge on the assembled base unit, making said locking mechanisms lock together.

19. A method for changing a force moving in a straight line in one direction to split into two directions, comprising
a. by making use of the shuttles of the device-dispenser, and
b. by applying force to the shuttle panels of said device-dispenser, said force is getting transferred through the shuttle bars to the handle cylinders of said shuttles, and through the shuttle handles and the hinges of said shuttles, to reach the corner of the shuttle frames, and getting split into two directions, and
c. said two directions translating into a movement 45 degrees apart from the original direction of said force,
whereby the direction of the force is changed from being straight to being diagonal, pushing the shuttle frame of said shuttle across to the furthest corner of the shaft cave, thus blocking the passage of the device shaft.

20. A method of claim 19 comprising
a. applying means for pushing said panels towards said device-dispenser base with equal force, and
b. said pushing making all said panels move the same distance to said device-dispenser base, and
c. said pushing accomplishing said diagonal movement of said shuttle frames, and making said shuttle frames move to the furthest corner of said shaft caves, and
d. as an effect of the design of the specific holes in said shuttle bars the smaller of said handle cylinders first moving from one end of the rectangular hole with half-cylindrical short sides to the opposite end of said hole, making the movement towards said base unit shorter for all of said shuttle,
whereby all said shuttle frames, although some have moved further than others, end in the furthest corners of said shaft caves, blocking the device shafts all at the same time, and keeping all devices staying in the device-dispenser.

21. A method of claim 19 comprising
a. applying means for pulling said shuttle bars to their outer distance from said device-dispenser base, and
b. said pulling making the shuttle frames of said shuttles move diagonally back across said passages of said device shafts, and
c. the diagonal movement opening the passages of said device shafts,
whereby the devices in the shuttle frames are being released and will pass through to their destinations, all destinations of the entire circuit receiving one device at the same time.

22. A method of claim 19 comprising
a. alternately applying said means for pushing and for pulling said shuttle bars, and
b. accomplishing alternate closings and openings of said device shafts
whereby said device-dispenser temporarily, and repeatedly, will be closing in all devices in the blocked position and releasing one device from each of said device shafts in the open position.
